(19) United States
(12) Patent Application Publication
(10) Pub. No.: US 2024/0334796 A1
(43) Pub. Date: Oct. 3, 2024

(54) DISPLAY DEVICE, METHOD FOR MANUFACTURING DISPLAY DEVICE, DISPLAY MODULE, AND ELECTRONIC DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Ryota HODO, Atsugi (JP); Yasuhiro JINBO, Isehara (JP); Chisato KATO, Isehara (JP)

(21) Appl. No.: 18/575,404

(22) PCT Filed: Jun. 28, 2022
(86) PCT No.: PCT/IB2022/055966

§ 371 Date: Dec. 29, 2023

(30) Foreign Application Priority Data
Jul. 8, 2021 (JP) 2021-113413

(51) Int. Cl. H10K 59/80; H10K 59/12; H10K 59/122

(52) U.S. Cl. CPC H10K 59/8792; H10K 59/1201; H10K 59/122

(57) ABSTRACT

A highly reliable display device is provided. The display device includes a first light-emitting element, a second light-emitting element adjacent to the first light-emitting element, a first insulating layer provided between the first light-emitting element and the second light-emitting element, a light-blocking layer over the first insulating layer, and a second insulating layer over the light-blocking layer. The first light-emitting element includes a first pixel electrode, a first EL layer over the first pixel electrode, and a common electrode over the first EL layer; and the second light-emitting element includes a second pixel electrode, a second EL layer over the second pixel electrode, and the common electrode over the second EL layer. The common electrode is placed over the second insulating layer.

### TECHNICAL FIELD

One embodiment of the present invention relates to a display device. One embodiment of the present invention relates to a method for manufacturing a display device. One embodiment of the present invention relates to a display module. One embodiment of the present invention relates to an electronic device.

Note that one embodiment of the present invention is not limited to the above technical field. Examples of a technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, higher-resolution display panels have been required. Examples of devices that require high-resolution display panels include a smartphone, a tablet terminal, and a laptop computer. Furthermore, higher resolution has been required for a stationary display device such as a television device or a monitor device along with a higher definition. An example of a device required to have the highest resolution is a device for virtual reality (VR) or augmented reality (AR).

Examples of a display device that can be used for a display panel include a light-emitting apparatus including a light-emitting element such as an organic EL (Electro Luminescence) element or a light-emitting diode (LED).

For example, the basic structure of an organic EL element is a structure in which a layer containing a light-emitting organic compound is provided between a pair of electrodes. By applying voltage to this element, light emission can be obtained from the light-emitting organic compound. A display device using such an organic EL element does not need a backlight that is necessary for a liquid crystal display device, for example; thus, a thin, lightweight, high-contrast, and low-power display device can be achieved. Patent Document 1, for example, discloses an example of a display device using an organic EL element.

Patent Document 2 discloses a display device using an organic EL element for VR.

Non-Patent Document 1 discloses a method for manufacturing an organic optoelectronic device using standard UV photolithography.

### REFERENCES

### Patent Documents

[Patent Document 1] Japanese Published Patent Application No. 2002-324673
[Patent Document 2] PCT International Publication No. 2018/087625

### Non-Patent Document

[Non-Patent Document 1] B. Lamprecht et al., “Organic optoelectronic device fabrication using standard UV photolithography” phys. stat. sol. (RRL) 2, No. 1, p. 16-18 (2008)

### SUMMARY OF THE INVENTION

### Problems to be Solved by the Invention

For example, when a light-emitting apparatus that is one kind of a display device is manufactured using UV photolithography, a light-emitting layer is irradiated with UV (ultraviolet light) and the light-emitting layer is damaged in some cases. Accordingly, the reliability of a light-emitting element is lowered in some cases.

An object of one embodiment of the present invention is to provide a highly reliable display device. An object of one embodiment of the present invention is to provide a display device with high display quality. An object of one embodiment of the present invention is to provide a high-resolution display device. An object of one embodiment of the present invention is to provide a display device with a high aperture ratio. An object of one embodiment of the present invention is to provide a display device with low power consumption.

An object of one embodiment of the present invention is to provide a display device having a novel structure or a method for manufacturing a display device. An object of one embodiment of the present invention is to provide a method for manufacturing the above-described display device with high yield. An object of one embodiment of the present invention is to at least reduce at least one of problems of the conventional technique.

Note that the description of these objects does not preclude the existence of other objects. Note that one embodiment of the present invention does not have to achieve all these objects. Note that other objects can be derived from the description of the specification, the drawings, the claims, and the like.

### Means for Solving the Problems

One embodiment of the present invention is a display device including a first light-emitting element, a second light-emitting element adjacent to the first light-emitting element, a first insulating layer provided between the first light-emitting element and the second light-emitting element, a light-blocking layer over the first insulating layer, and a second insulating layer over the light-blocking layer. The first light-emitting element includes a first pixel electrode, a first EL layer over the first pixel electrode, and a common electrode over the first EL layer. The second light-emitting element includes a second pixel electrode, a second EL layer over the second pixel electrode, the common electrode over the second EL layer. The common electrode is placed over the second insulating layer.

Alternatively, in the above embodiment, the first insulating layer may contain an inorganic material, and the second insulating layer may contain an organic material.

Alternatively, in the above embodiment, the first insulating layer may contain aluminum oxide.

Alternatively, in the above embodiment, the second insulating layer may contain an acrylic resin.

Alternatively, in the above embodiment, a side surface of the first pixel electrode and a side surface of the second pixel electrode may each have a tapered shape in a cross-sectional view of the display device. The first EL layer may cover the side surface of the first pixel electrode. The second EL layer may cover the side surface of the second pixel electrode. The first EL layer may include a first tapered portion between the side surface of the first pixel electrode and the first insulating layer. The second EL layer may include a second tapered portion between the side surface of the second pixel electrode and the first insulating layer.

Alternatively, in the above embodiment, a taper angle of the first tapered portion and a taper angle of the second tapered portion may each be less than 90°.

Alternatively, in the above embodiment, the first insulating layer may include a region in contact with the first EL layer and the second EL layer.

Alternatively, in the above embodiment, the first light-emitting element may include a common layer placed between the first EL layer and the common electrode. The second light-emitting element may include the common layer placed between the second EL layer and the common electrode. The common layer may be placed between the second insulating layer and the common electrode. The common layer may include at least one of a hole-injection layer, a hole-transport layer, a hole-blocking layer, an electron-blocking layer, an electron-transport layer, and an electron-injection layer.

A display module including the display device of one embodiment of the present invention and at least one of a connector and an integrated circuit is also one embodiment of the present invention.

An electronic device including the display module of one embodiment of the present invention and at least one of a battery, a camera, a speaker, and a microphone is also one embodiment of the present invention.

Alternatively, one embodiment of the present invention is a method for manufacturing a display device, in which a first pixel electrode and a second pixel electrode are formed; a first EL film is formed to cover the first pixel electrode and the second pixel electrode; a first mask film is formed over the first EL film; a first EL layer over the first pixel electrode and a first mask layer over the first EL layer are formed by processing the first EL film and the first mask film; a second EL film is formed to cover the first mask layer and the second pixel electrode; a second mask film is formed over the second EL film; a second EL layer over the second pixel electrode and a second mask layer over the second EL layer are formed by processing the second EL film and the second mask film; an inorganic insulating film is formed to cover the first EL layer, the second EL layer, the first mask layer, and the second mask layer; a light-blocking film is formed over the inorganic insulating film, a photosensitive organic insulating film is applied over the light-blocking film; part of the organic insulating film is irradiated with light; an organic insulating layer is formed between the first EL layer and the second EL layer by removing the part of the organic insulating film; a light-blocking layer is formed under the organic insulating layer by removing part of the light-blocking film; an inorganic insulating layer is formed under the light-blocking layer by removing part of the inorganic insulating film; and a common electrode is formed over the first EL layer, the second EL layer, and the organic insulating layer.

Alternatively, in the above embodiment, the light may include ultraviolet light.

Alternatively, in the above embodiment, each of the first pixel electrode and the second pixel electrode may be formed to include a side surface with a tapered shape in a cross-sectional view of the display device. The first EL layer may be formed to cover the side surface of the first pixel electrode and include a first tapered portion between the side surface of the first pixel electrode and the first mask layer. The second EL layer may be formed to cover the side surface of the second pixel electrode and include a second tapered portion between the side surface of the second pixel electrode and the second mask layer.

Alternatively, in the above embodiment, the first EL layer may be formed to have a taper angle of the first tapered portion of less than 90°, and the second EL layer may be formed to have a taper angle of the second tapered portion of less than 90°.

Alternatively, in the above embodiment, the first EL layer and the second EL layer may be formed by a photolithography method.

Alternatively, in the above embodiment, a distance of a region between the first EL layer and the second EL layer may be less than or equal to 8 μm.

Alternatively, in the above embodiment, the inorganic insulating film may be formed by an ALD method.

Alternatively, in the above embodiment, the organic insulating film may be formed using a photosensitive acrylic resin.

Alternatively, in the above embodiment, the inorganic insulating layer may be formed to include a region in contact with the first EL layer and the second EL layer.

Alternatively, in the above embodiment, a common layer including at least one of a hole-injection layer, a hole-transport layer, a hole-blocking layer, an electron-blocking layer, an electron-transport layer, and an electron-injection layer may be formed after forming the inorganic insulating layer and before forming the common electrode. The common electrode may be formed over the common layer.

### Effect of the Invention

According to one embodiment of the present invention, a highly reliable display device can be provided. A display device with high display quality can be provided. A high-resolution display device can be provided. A display device with a high aperture ratio can be provided. A display device with low power consumption can be provided.

According to one embodiment of the present invention, a display device having a novel structure or a method for manufacturing a display device can be provided. A method for manufacturing the above-described display device with high yield can be provided. According to one embodiment of the present invention, at least one of problems of the conventional technique can be at least reduced.

Note that the description of these effects does not preclude the existence of other effects. Note that one embodiment of the present invention does not need to have all these effects. Other effects can be derived from the description of the specification, the drawings, the claims, or the like.

### BRIEF DESCRIPTION OF THE DRAWINGS

FIG. 1 is a top view illustrating an example of a display device.

FIG. 2A, FIG. 2B1, and FIG. 2B2 are cross-sectional views each illustrating an example of a display device.

FIG. 3A and FIG. 3B are cross-sectional views illustrating an example of a display device.

FIG. 4A, FIG. 4B1, and FIG. 4B2 are cross-sectional views each illustrating an example of a display device.

FIG. 5A and FIG. 5B are cross-sectional views illustrating an example of a display device.

FIG. 6A and FIG. 6B are cross-sectional views each illustrating an example of a display device.

FIG. 7A and FIG. 7B are cross-sectional views each illustrating an example of a display device.

FIG. 8A to FIG. 8C are cross-sectional views illustrating an example of a method for manufacturing a display device.

FIG. 9A to FIG. 9C are cross-sectional views illustrating an example of a method for manufacturing a display device.

FIG. 10A to FIG. 10C are cross-sectional views illustrating an example of a method for manufacturing a display device.

FIG. 11A to FIG. 11C are cross-sectional views illustrating an example of a method for manufacturing a display device.

FIG. 12A to FIG. 12C are cross-sectional views illustrating an example of a method for manufacturing a display device.

FIG. 13A and FIG. 13B are cross-sectional views illustrating an example of a method for manufacturing a display device.

FIG. 14A and FIG. 14B are cross-sectional views illustrating an example of a method for manufacturing a display device.

FIG. 15A and FIG. 15B are cross-sectional views illustrating an example of a method for manufacturing a display device.

FIG. 16A to FIG. 16C are cross-sectional views illustrating an example of a method for manufacturing a display device.

FIG. 17A and FIG. 17B are cross-sectional views illustrating an example of a method for manufacturing a display device.

FIG. 18A to FIG. 18F are diagrams each illustrating a structure example of a pixel.

FIG. 19A and FIG. 19B are diagrams illustrating a structure example of a display device.

FIG. 20 is a diagram illustrating a structure example of a display device.

FIG. 21 is a diagram illustrating a structure example of a display device.

FIG. 22 is a diagram illustrating a structure example of a display device.

FIG. 23 is a diagram illustrating a structure example of a display device.

FIG. 24 is a diagram illustrating a structure example of a display device.

FIG. 25 is a diagram illustrating a structure example of a display device.

FIG. 26 is a diagram illustrating a structure example of a display device.

FIG. 27A and FIG. 27B are diagrams each illustrating a structure example of a display device.

FIG. 28A to FIG. 28F are diagrams each illustrating a structure example of a light-emitting element.

FIG. 29A to FIG. 29D are diagrams each illustrating a structure example of an electronic device.

FIG. 30A to FIG. 30F are diagrams each illustrating a structure example of an electronic device.

FIG. 31A to FIG. 31G are diagrams each illustrating a structure example of an electronic device.

### MODE FOR CARRYING OUT THE INVENTION

Embodiments will be described below with reference to the drawings. Note that the embodiments can be implemented in many different modes, and it will be readily understood by those skilled in the art that modes and details thereof can be changed in various ways without departing from the spirit and scope thereof. Thus, the present invention should not be interpreted as being limited to the following description of the embodiments.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

In each drawing described in this specification, the size, the layer thickness, or the region of each component is exaggerated for clarity in some cases. Therefore, the size, the layer thickness, or the region is not necessarily limited to the illustrated scale.

In this specification and the like, the ordinal numbers such as “first” and “second” are used in order to avoid confusion among components and do not limit the number.

In this specification and the like, a display device may be rephrased as an electronic device.

In this specification and the like, a display panel that is one embodiment of a display device has a function of displaying (outputting) an image on (to) a display surface. Therefore, the display panel is one embodiment of an output device.

In this specification and the like, a structure in which a connector such as an FPC (Flexible Printed Circuit) or a TCP (Tape Carrier Package) is attached to a substrate of a display panel, or a structure in which an IC is mounted on a substrate by a COG (Chip On Glass) method or the like is referred to as a display panel module or a display module, or simply referred to as a display panel or the like in some cases. In this specification and the like, a display panel module, a display module, or a display panel is referred to as a display device.

In this specification and the like, the term “film” and the term “layer” can be interchanged with each other depending on the case or depending on circumstances. For example, in some cases, the term “conductive layer” or “insulating layer” can be interchanged with the term “conductive film” or “insulating film.”

In addition, in this specification and the like, the term “end portion” and the term “side surface” can be interchanged with each other in some cases. For example, when the term “end portion” means an end portion of a side surface, the term “end portion” can be replaced with the term “side surface” in some cases.

Note that in this specification and the like, an EL layer means a layer containing at least a light-emitting substance (also referred to as a light-emitting layer) or a stack including the light-emitting layer provided between a pair of electrodes of a light-emitting element.

In this specification and the like, the term “element” can be replaced with the term “device” in some cases. For example, “light-emitting element” can be replaced with “light-emitting device.”

In this specification and the like, a device formed using a metal mask or an FMM (a fine metal mask, a high-resolution metal mask) may be referred to as a device having an MM (a metal mask) structure. In this specification and the like, a device formed without using a metal mask or an FMM is sometimes referred to as a device having an MML (metal maskless) structure.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the above-described carrier-injection layer, carrier-transport layer, and carrier-blocking layer cannot be distinguished from each other depending on the cross-sectional shape, properties, or the like. One layer may have two or three functions of the carrier-injection layer, the carrier-transport layer, and the carrier-blocking layer in some cases.

### Embodiment 1

In this embodiment, a display device of one embodiment of the present invention is described.

One embodiment of the present invention is a display device including a display portion capable of full-color display. The display portion includes a first subpixel and a second subpixel that emit light of different colors. The first subpixel includes a first light-emitting element that emits blue light and the second subpixel includes a second light-emitting element that emits light of a color different from the color of light emitted by the first light-emitting element. The first light-emitting element and the second light-emitting element contains at least one material that is different between each other; for example, a light-emitting substance is different between each other. That is, light-emitting elements separately formed for respective emission colors are used in the display device of one embodiment of the present invention.

A structure in which light-emitting layers in light-emitting elements of respective colors (e.g., blue (B), green (G), and red (R)) are separately formed or the light-emitting layers are separately patterned is sometimes referred to as an SBS (Side By Side) structure. The SBS structure can optimize materials and structures of light-emitting elements and thus can increase the freedom of choices of the materials and the structures, so that the luminance and the reliability can be easily improved. A light-emitting element capable of emitting white light is referred to as a white-light-emitting element in some cases. Note that a combination of a white-light-emitting element with a coloring layer (e.g., a color filter) can provide a full-color display device.

In the case of manufacturing a display device including a plurality of light-emitting elements emitting light of different colors, light-emitting layers emitting light of different colors each need to be formed into an island shape. Note that in this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

For example, an island-shaped light-emitting layer can be formed by a vacuum evaporation method using a metal mask (also referred to as a shadow mask). However, this method causes a deviation from the designed shape and position of an island-shaped light-emitting layer due to various influences such as the accuracy of the metal mask, the positional deviation between the metal mask and a substrate, a warp of the metal mask, and the vapor-scattering-induced expansion of outline of the deposited film, for example; accordingly, it is difficult to achieve high resolution and high aperture ratio. In addition, the outline of the layer may blur during vapor deposition, whereby the thickness of an end portion may be reduced. That is, the thickness of the island-shaped light-emitting layer may vary from area to area. In the case of manufacturing a display device with a large size, high definition, or high resolution, the manufacturing yield might be reduced because of low dimensional accuracy of the metal mask and deformation due to heat or the like.

In a method for manufacturing a display device of one embodiment of the present invention, a first EL film that includes a light-emitting film emitting light of a first color is formed over the entire surface, and then a mask film is formed over the first EL film. Then, a resist mask is formed over the mask film, and the mask film is processed using the resist mask. Accordingly, a first mask layer can be formed. Next, the first EL film is processed using the first mask layer as a hard mask. Accordingly, the first EL layer that includes a light-emitting layer emitting light of the first color can be formed in an island shape. After that, a second EL film that includes a light-emitting film emitting light of a second color is formed over the entire surface, and then the second EL film is processed in a manner similar to the processing of the first EL film; accordingly, a second EL layer that includes a light-emitting layer emitting light of the second color is formed in an island shape. Note that a second mask layer is formed over the second EL layer. The mask film and the mask layer have a function of protecting an EL layer in the manufacturing process of the display device.

In this specification and the like, processing a film to form a layer means, for example, partly removing a film. For example, a layer can be formed by performing patterning on a film. Partly removing a layer is referred to as processing a layer in some cases.

In this specification and the like, a mask layer may be referred to as a sacrificial layer, and a mask film may be referred to as a sacrificial film.

In the case of processing the light-emitting film into an island shape, a possible structure is that the light-emitting film is processed by a photolithography method directly over the light-emitting film. In the case of this structure, damage to the light-emitting film (e.g., processing damage) might significantly degrade the reliability. In view of the above, in the manufacture of the display device of one embodiment of the present invention, for example, a mask film is preferably formed over a layer above the light-emitting film (e.g., a carrier-transport layer or a carrier-injection layer, specifically an electron-transport layer or an electron-injection layer), followed by the processing of the light-emitting film into an island shape. Such a method provides a highly reliable display device.

As described above, the island-shaped EL layers formed in the method for manufacturing a display device of one embodiment of the present invention are formed not by using a metal mask having a fine pattern but by processing an EL film deposited over the entire surface. Accordingly, a high-resolution display device or a display device with a high aperture ratio, which has been difficult to achieve, can be manufactured. Moreover, EL layers can be formed separately for the respective colors, enabling the display device to perform extremely clear display with high contrast and high display quality. In addition, a mask film provided over an EL film can reduce damage to the EL film in the manufacturing process of the display device, increasing the reliability of the light-emitting element.

It is difficult to set the distance between adjacent light-emitting elements to less than 10 μm with a formation method using a metal mask, for example; however, with the above method, the distance can be decreased to less than 10 μm, less than or equal to 8 μm, less than or equal to 5 μm, less than or equal to 3 μm, less than or equal to 2 μm, or less than or equal to 1 μm. With the use of a light exposure apparatus for LSI, for example, the distance between adjacent light-emitting elements can be decreased to less than or equal to 500 nm, less than or equal to 200 nm, less than or equal to 100 nm, or even less than or equal to 50 nm. Accordingly, the area of a non-light-emitting region that may exist between two light-emitting elements can be significantly reduced, and the aperture ratio can be close to 100%. For example, the aperture ratio is higher than or equal to 50%, higher than or equal to 60%, higher than or equal to 70%, higher than or equal to 80%, or higher than or equal to 90%; that is, an aperture ratio lower than 100% can be achieved.

Furthermore, a pattern of the EL layer itself can be made much smaller than that in the case of using a metal mask. For example, in the case of using a metal mask for forming EL layers separately, a variation in the thickness of the pattern occurs between the center and the edge of the pattern, causing a reduction in effective area that can be used for a light-emitting region with respect to the entire pattern area. In contrast, in the above manufacturing method, a film deposited to have a uniform thickness is processed, so that island-shaped EL layers can be formed to have a uniform thickness. Accordingly, even in a fine pattern, almost the whole area can be used as a light-emitting region. Thus, a display device having both high resolution and a high aperture ratio can be manufactured.

In the method for manufacturing the display device of one embodiment of the present invention, it is preferable that an EL film be formed over the entire surface and then a mask film be formed over the EL film. Then, it is preferable that a resist mask be formed over the mask film, the EL film and the mask film be processed using the resist mask, and an island-shaped EL layer be thereby formed.

The mask film provided over the EL film can reduce damage to the EL layer in the manufacturing process of the display device, increasing the reliability of the light-emitting element.

Here, each of the first EL layer and the second EL layer includes at least a light-emitting layer and preferably is composed of a plurality of layers. Specifically, one or more layers are preferably formed over the light-emitting layer. A layer between the light-emitting layer and the mask layer can inhibit the light-emitting layer from being exposed on the outermost surface during the manufacturing process of the display device and can reduce damage to the light-emitting layer. As a result, the reliability of the light-emitting element can be increased. Thus, each of the first EL layer and the second EL layer preferably includes the light-emitting layer and a carrier-transport layer (an electron-transport layer or a hole-transport layer) over the light-emitting layer.

Note that it is not necessary to form all layers included in EL layers separately between light-emitting elements that exhibit different colors, and some layers of the EL layers can be formed in the same step. Examples of layers in the EL layer include a light-emitting layer, carrier-injection layers (a hole-injection layer and an electron-injection layer), carrier-transport layers (a hole-transport layer and an electron-transport layer), carrier-blocking layers (a hole-blocking layer and an electron-blocking layer), and the like. In the method for manufacturing a display device of one embodiment of the present invention, after some layers included in the EL layer are formed into an island shape separately for each color, at least part of the mask layer is removed; then, the other layers included in the EL layers (sometimes referred to as common layers) and a common electrode (also referred to as an upper electrode) are formed (as a single film) so as to be shared by the light-emitting elements of different colors. For example, a carrier-injection layer and the common electrode can be formed so as to be shared by the light-emitting elements of different colors.

In contrast, the carrier-injection layer is often a layer having relatively high conductivity in the EL layer. Therefore, when the carrier-injection layer is in contact with a side surface of any layer of the EL layer formed into an island shape or a side surface of the pixel electrode, the light-emitting element might be short-circuited. Note that also in the case where the carrier-injection layer is provided in an island shape and the common electrode is formed so as to be shared by the light-emitting elements of different colors, the light-emitting element might be short-circuited when the common electrode is in contact with the side surface of the EL layer or the side surface of the pixel electrode.

Thus, the display device of one embodiment of the present invention includes an insulating layer covering at least a side surface of the island-shaped light-emitting layer. The insulating layer may cover part of a top surface of the island-shaped light-emitting layer. Note that here, the side surface of the island-shaped light-emitting layer refers to a surface that is not parallel to the substrate (or the surface where the light-emitting layer is formed) among the interfaces between the island-shaped light-emitting layer and other layers.

Thus, at least some layers in the island-shaped EL layer and the pixel electrode can be inhibited from being in contact with the carrier-injection layer or the common electrode. Thus, a short circuit in the light-emitting element can be inhibited, leading to an increase in the reliability of the light-emitting element.

The insulating layer preferably has a function of a barrier insulating layer against at least one of water and oxygen. Alternatively, the insulating layer preferably has a function of inhibiting the diffusion of at least one of water and oxygen. Alternatively, the insulating layer preferably has a function of capturing or fixing (also referred to as gettering) at least one of water and oxygen.

Note that in this specification and the like, a barrier insulating layer refers to an insulating layer having a barrier property. A barrier property in this specification and the like means a function of inhibiting diffusion of a targeted substance (also referred to as having low permeability). Alternatively, a barrier property means a function of capturing or fixing (also referred to as gettering) a particular substance.

With the use of an insulating layer having a function of the barrier insulating layer or a gettering function, entry of impurities (typically, at least one of water and oxygen) that might diffuse into the light-emitting element from the outside can be inhibited. With this structure, a highly reliable light-emitting element and a highly reliable display device can be provided.

The display device of one embodiment of the present invention includes a pixel electrode functioning as an anode; an island-shaped hole-injection layer, an island-shaped hole-transport layer, an island-shaped light-emitting layer, and an island-shaped electron-transport layer that are provided in this order over the pixel electrode; an insulating layer provided to cover side surfaces of the hole-injection layer, the hole-transport layer, the light-emitting layer, and the electron-transport layer; an electron-injection layer provided over the electron-transport layer; and a common electrode that is provided over the electron-injection layer and functions as a cathode.

Alternatively, the display device of one embodiment of the present invention includes a pixel electrode functioning as a cathode; an island-shaped electron-injection layer, an island-shaped electron-transport layer, an island-shaped light-emitting layer, and an island-shaped hole-transport layer that are provided in this order over the pixel electrode; an insulating layer provided to cover side surfaces of the electron-injection layer, the electron-transport layer, the light-emitting layer, and the hole-transport layer; a hole-injection layer provided over the hole-transport layer; and a common electrode that is provided over the hole-injection layer and functions as an anode.

The hole-injection layer or the electron-injection layer, for example, often have relatively high conductivity in the EL layer. Since the side surfaces of these layers are covered with the insulating layer in the display device of one embodiment of the present invention, these layers can be inhibited from being in contact with the common electrode, for example. Thus, a short circuit in the light-emitting element can be inhibited, leading to an increase in the reliability of the light-emitting element.

The insulating layer covering the side surface of the island-shaped EL layer can have a stacked-layer structure of a first insulating layer containing an inorganic material (also referred to as an inorganic insulating layer) and a second insulating layer containing an organic material (also referred to as an organic insulating layer). The first insulating layer can be provided to be in contact with the EL layer. The second insulating layer can be provided to planarize a depressed portion provided in the first insulating layer.

The first insulating layer and the second insulating layer can be formed in the following manner: for example, after the first EL layer and the second EL layer are formed, the first insulating film (also referred to as an inorganic insulating film) and the second insulating film (also referred to as an organic insulating film) are deposited and processed. Here, when a photosensitive organic insulating film is used as the second insulating film, the second insulating layer can be formed by processing the second insulating film in light exposure and development steps. Therefore, the second insulating film can be processed without using, for example, a dry etching method, and thus damage to the EL layer can be reduced.

When a photosensitive organic insulating film is used as the second insulating film, the second insulating film is irradiated with ultraviolet light in the light exposure step in some cases. Therefore, the EL layer is also irradiated with ultraviolet light, and the EL layer is damaged in some cases.

In view of the above, in one embodiment of the present invention, a light-blocking film is provided between the first insulating film and the second insulating film. Accordingly, even in the case where a photosensitive organic insulating film is used as the second insulating film and the second insulating film is irradiated with ultraviolet light in the light exposure step, it is possible to inhibit the EL layer from being irradiated with ultraviolet light and damaged. Therefore, the display device of one embodiment of the present invention can be a highly reliable display device.

In one embodiment of the present invention, after the second insulating layer is formed by processing the second insulating film, a light-blocking layer is formed by processing the light-blocking film. Next, the first insulating layer is formed by processing the first insulating film. After that, the common layer and the common electrode are formed, whereby the display device of one embodiment of the present invention can be manufactured. Note that when the light-blocking layer is provided over the first insulating layer that can be an inorganic insulating layer, the light-blocking layer can be prevented from being in contact with the EL layer. Therefore, provision of the first insulating layer can expand the range of choices for the material of the light-blocking layer. For example, a material that might damage the EL layer when in contact with the EL layer can be used for the light-blocking layer. Furthermore, a method that might damage the EL layer exposed at the time of formation of the light-blocking layer can be employed for the formation of the light-blocking layer.

In the display device of one embodiment of the present invention, the EL layer can be provided to cover the side surface of the pixel electrode. Here, in a cross-sectional view of the display device, when the side surface of the pixel electrode has a tapered shape, the EL layer is also formed to have a tapered shape. Specifically, the EL layer is formed to have a tapered portion between the side surface of the pixel electrode and the first insulating layer. Therefore, the side surface of the pixel electrode preferably has a tapered shape, in which case coverage of the pixel electrode with the EL layer can be improved. The side surface of the pixel electrode preferably has a tapered shape, in which case foreign matters (e.g., also referred to as dust or particles) in the manufacturing process of the display device of one embodiment of the present invention can be suitably removed by, for example, cleaning.

Meanwhile, in the case where the EL layer is formed to have a tapered portion, the portion is easily irradiated with ultraviolet light in the light exposure step on the second insulating film that can be a photosensitive organic insulating film compared with, for example, the case where the portion of the EL layer is formed to be perpendicular in a cross-sectional view of the display device. Therefore, the light-blocking film is provided between the first insulating film and the second insulating film as describe above, whereby irradiation of, for example, ultraviolet light can be inhibited also in the tapered portion of the EL layer, and the EL layer can be inhibited from being damaged. From the above, in the display device of one embodiment of the present invention, coverage of the pixel electrode with the EL layer can be improved and the EL layer can be inhibited from being damaged in the manufacturing process. Therefore, the display device of one embodiment of the present invention can be a highly reliable display device.

Note that in the display device of one embodiment of the present invention, it is not necessary to provide an insulating layer covering an end portion of the pixel electrode between the pixel electrode and the EL layer. Thus, the distance between adjacent light-emitting elements can be extremely small. Therefore, a display device with higher resolution or higher definition can be achieved. In addition, a mask for forming the insulating layer is not needed, which leads to a reduction in manufacturing cost of the display device.

Furthermore, light emitted from the EL layer can be extracted efficiently with a structure where an insulating layer covering the end portion of the pixel electrode is not provided between the pixel electrode and the EL layer, i.e., a structure where an insulating layer is not provided between the pixel electrode and the EL layer. Therefore, the display device of one embodiment of the present invention can significantly reduce the viewing angle dependence. A reduction in the viewing angle dependence leads to an increase in visibility of an image on the display device. For example, in the display device of one embodiment of the present invention, the viewing angle (the maximum angle with a certain contrast ratio maintained when the screen is seen from an oblique direction) can be more than or equal to 100° and less than 180°, preferably more than or equal to 1500 and less than or equal to 170°. Note that the viewing angle refers to that in both the vertical direction and the horizontal direction.

### [Structure Example_1 of Display Device]

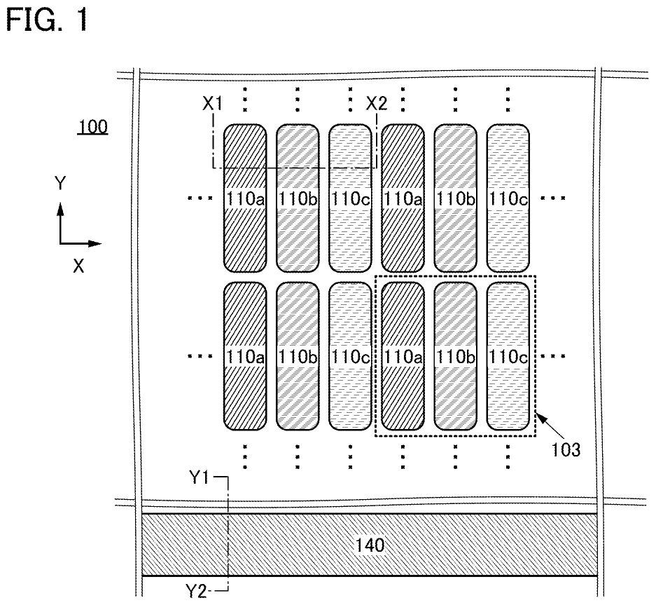

FIG. 1 is a top view of a display device 100. The display device 100 includes a display portion in which a plurality of pixels 103 are arranged, and a connection portion 140 outside the display portion. A plurality of subpixels are arranged in matrix in the display portion. FIG. 1 illustrates subpixels arranged in two rows and six columns, which form pixels in two rows and two columns. The connection portion 140 can also be referred to as a cathode contact portion.

The pixel 103 illustrated in FIG. 1 employs stripe arrangement. The pixel 103 illustrated in FIG. 1 consists of three subpixels: a subpixel 110a, a subpixel 110b, and a subpixel 110c. The subpixel 110a, the subpixel 110b, and the subpixel 110c include light-emitting elements emitting light of different colors. The subpixel 110a, the subpixel 110b, and the subpixel 110c can be subpixels of three colors of red (R), green (G), and blue (B) or subpixels of three colors of yellow (Y), cyan (C), and magenta (M), for example. The number of types of subpixels is not limited to three, and four or more types of subpixels may be used. As the four subpixels, subpixels of four colors of R, G, B, and white (W), subpixels of four colors of R, G, B, and Y, or four subpixels of R, G, B, and infrared light (IR) can be given, for example.

In this specification and the like, the row direction is referred to as X direction and the column direction is referred to as Y direction in some cases. The X direction and the Y direction intersect with each other and are, for example, orthogonal to each other (see FIG. 1).

FIG. 1 illustrates an example where subpixels of different colors are arranged in the X direction and subpixels of the same color are arranged in the Y direction.

Although FIG. 1 illustrates an example where the connection portion 140 is positioned on the lower side of the display portion in the top view, one embodiment of the present invention is not particularly limited. The connection portion 140 may be provided in at least one of the upper side, the right side, the left side, and the lower side of the display portion in the top view, and may be provided so as to surround the four sides of the display portion. The top surface shape of the connection portion 140 can be a belt-like shape, an L shape, a U shape, a frame-like shape, or the like. The number of the connection portions 140 can be one or more.

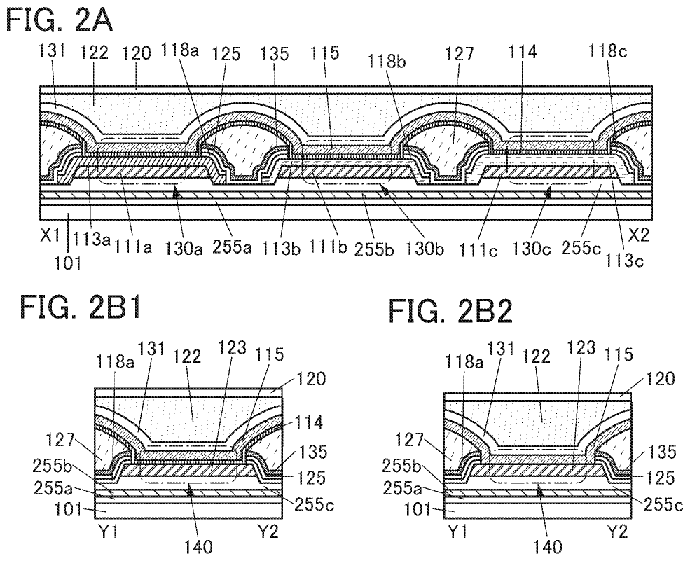

FIG. 2A is a cross-sectional view taken along the dashed-dotted line X1-X2 in FIG. 1. As illustrated in FIG. 2A, in the display device 100, an insulating layer is provided over a layer 101 including a transistor, a light-emitting element 130a, a light-emitting element 130b, and a light-emitting element 130c are provided over the insulating layer, and a protective layer 131 is provided to cover these light-emitting elements. A substrate 120 is bonded to the protective layer 131 with an adhesive layer 122. An insulating layer 125, a light-blocking layer 135 over the insulating layer 125, and an insulating layer 127 over the light-blocking layer 135 are provided between adjacent light-emitting elements 130.

In this specification and the like, the term “light-emitting element 130” is sometimes used to describe matters common to the light-emitting element 130a, the light-emitting element 130b, and the light-emitting element 130c, for example. As for other components that are distinguished from each other using letters of the alphabet, matters common to the components are sometimes described using reference numerals excluding the letters of the alphabet.

For example, although in FIG. 2A, a plurality of cross sections of the insulating layers 125, a plurality of cross sections of the light-blocking layers 135, and a plurality of cross sections of the insulating layers 127 are illustrated, the insulating layers 125, the light-blocking layers 135, and the insulating layers 127 are each a continuous layer when the display device 100 is seen from above. In other words, the display device 100 can have a structure such that one insulating layer 125, one light-blocking layer 135, and one insulating layer 127 are provided, for example. Note that the display device 100 may include a plurality of insulating layers 125 that are separated from each other, a plurality of light-blocking layers 135 that are separated from each other, and a plurality of insulating layers 127 that are separated from each other.

The display device of one embodiment of the present invention can have any of the following structures: a top-emission structure in which light is emitted in a direction opposite to a substrate where a light-emitting element is formed, a bottom-emission structure in which light is emitted toward a substrate where a light-emitting element is formed, and a dual-emission structure in which light is emitted toward both surfaces.

The layer 101 including a transistor can employ a stacked-layer structure in which a plurality of transistors are provided over a substrate and an insulating layer is provided to cover these transistors, for example. The insulating layer over the transistors may have a single-layer structure or a stacked-layer structure. In FIG. 2A, an insulating layer 255a, an insulating layer 255b over the insulating layer 255a, and an insulating layer 255c over the insulating layer 255b are illustrated as the insulating layer over the transistors, for example. The insulating layers may have a depressed portion between the adjacent light-emitting elements 130. For example, in FIG. 2A, the insulating layer 255c has a depressed portion.

As each of the insulating layer 255a, the insulating layer 255b, and the insulating layer 255c, a variety of inorganic insulating films such as an oxide insulating film, a nitride insulating film, an oxynitride insulating film, and a nitride oxide insulating film can be suitably used. As each of the insulating layer 255a and the insulating layer 255c, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferred that a silicon oxide film be used as each of the insulating layer 255a and the insulating layer 255c, and a silicon nitride film be used as the insulating layer 255b. The insulating layer 255b preferably has a function of an etching protective film.

Note that in this specification and the like, oxynitride refers to a material that contains more oxygen than nitrogen, and nitride oxide refers to a material that contains more nitrogen than oxygen. For example, silicon oxynitride refers to a material which contains oxygen at a higher proportion than nitrogen, and silicon nitride oxide refers to a material which contains nitrogen at a higher proportion than oxygen.

Each of the light-emitting element 130a, the light-emitting element 130b, and the light-emitting element 130c emits light of different colors. The light-emitting element 130a, the light-emitting element 130b, and the light-emitting element 130c preferably emit light of three colors, red (R), green (G), and blue (B), for example.

As the light-emitting element 130a, the light-emitting element 130b, and the light-emitting element 130c, EL elements such as OLEDs (Organic Light Emitting Diodes) or QLEDs (Quantum-dot Light Emitting Diodes) are preferably used. Examples of a light-emitting substance contained in the EL element include a substance that emits fluorescent light (a fluorescent material), a substance that emits phosphorescent light (a phosphorescent material), an inorganic compound (e.g., a quantum dot material), and a substance that exhibits thermally activated delayed fluorescence (a TADF material). As the TADF material, a material in which the singlet and triplet excited states are in thermal equilibrium may be used. Since such a TADF material enables a short emission lifetime (excitation lifetime), an emission efficiency decrease of a light-emitting element in a high-luminance region can be inhibited.

The light-emitting element includes an EL layer between a pair of electrodes. The EL layer includes at least a light-emitting layer. In this specification and the like, one of the pair of electrodes may be referred to as a pixel electrode and the other may be referred to as a common electrode.

One electrode of the pair of electrodes included in the light-emitting element functions as an anode, and the other electrode functions as a cathode. The case where the pixel electrode functions as an anode and the common electrode functions as a cathode is sometimes described below as an example.

Side surfaces of a pixel electrode 111a, a pixel electrode 111b, and a pixel electrode 111c preferably have tapered shapes, in which case foreign matters (e.g., also referred to as dust or particles) in the manufacturing process of the display device can be easily removed by, for example, cleaning.

The light-emitting element 130a includes the pixel electrode 111a over the insulating layer 255c, an EL layer 113a over the pixel electrode 111a, a common layer 114 over the EL layer 113a, and a common electrode 115 over the common layer 114. Note that the EL layer 113a and the common layer 114 can be collectively referred to as an EL layer.

The light-emitting element 130b includes the pixel electrode 111b over the insulating layer 255c, an EL layer 113b over the pixel electrode 111b, the common layer 114 over the EL layer 113b, and the common electrode 115 over the common layer 114. Note that the EL layer 113b and the common layer 114 can be collectively referred to as an EL layer.

The light-emitting element 130c includes the pixel electrode 111c over the insulating layer 255c, an EL layer 113c over the pixel electrode 111c, the common layer 114 over the EL layer 113c, and the common electrode 115 over the common layer 114. Note that the EL layer 113c and the common layer 114 can be collectively referred to as an EL layer.

The EL layer 113a, the EL layer 113b, and the EL layer 113c can each be provided to have an island shape. Meanwhile, the common layer 114 and the common electrode 115 can be shared by a plurality of light-emitting elements 130.

There is no particular limitation on the structure of the light-emitting element in this embodiment, and the light-emitting element can have a single structure or a tandem structure.

Each of the EL layer 113a, the EL layer 113b, and the EL layer 113c includes at least a light-emitting layer. Preferably, the EL layer 113a, the EL layer 113b, and the EL layer 113c include a red-light-emitting layer, a green-light-emitting layer, and a blue-light-emitting layer, respectively, for example.

The EL layer 113a, the EL layer 113b, and the EL layer 113c may each include one or more of a hole-injection layer, a hole-transport layer, a hole-blocking layer, an charge-generation layer, an electron-blocking layer, an electron-transport layer, and an electron-injection layer.

The EL layer 113a, the EL layer 113b, and the EL layer 113c may include a hole-injection layer, a hole-transport layer, a light-emitting layer, and an electron-transport layer, for example. In addition, an electron-blocking layer may be provided between the hole-transport layer and the light-emitting layer. Furthermore, an electron-injection layer may be provided over the electron-transport layer.

The EL layer 113a, the EL layer 113b, and the EL layer 113c may include an electron-injection layer, an electron-transport layer, a light-emitting layer, and a hole-transport layer in this order, for example. In addition, a hole-blocking layer may be provided between the electron-transport layer and the light-emitting layer. Furthermore, a hole-injection layer may be provided over the hole-transport layer.

The EL layer 113a, the EL layer 113b, and the EL layer 113c each preferably include a light-emitting layer and a carrier-transport layer (an electron-transport layer or a hole-transport layer) over the light-emitting layer. Since surfaces of the EL layer 113a, the EL layer 113b, and the EL layer 113c are exposed in the manufacturing process of the display device, providing the carrier-transport layer over the light-emitting layer prevents the light-emitting layer from being exposed on the outermost surface, so that damage to the light-emitting layer can be reduced. Thus, the reliability of the light-emitting element 130 can be increased.

The EL layer 113a, the EL layer 113b, and the EL layer 113c each include a first light-emitting unit, a charge-generation layer, and a second light-emitting unit in some cases. Preferably, the EL layer 113a, the EL layer 113b, and the EL layer 113c include two or more light-emitting units that emit red light, two or more light-emitting units that emit green light, and two or more light-emitting units that emit blue light, respectively, for example.

It is preferable that the second light-emitting unit include a light-emitting layer and a carrier-transport layer (an electron-transport layer or a hole-transport layer) over the light-emitting layer. Since the surface of the second light-emitting unit is exposed in the manufacturing process of the display device, providing the carrier-transport layer over the light-emitting layer prevents the light-emitting layer from being exposed on the outermost surface, so that damage to the light-emitting layer can be reduced. Thus, the reliability of the light-emitting element 130 can be increased.

The thickness of the EL layer 113a, the thickness of the EL layer 113b, and the thickness of the EL layer 113c can be different from each other. Specifically, the thickness can be set to have an optical path length for intensifying light emitted from each of the EL layer 113a to EL layer 113c. In such a manner, a micro optical resonator (microcavity) structure can be achieved, and color purity in the light-emitting element 130a, the light-emitting element 130b, and the light-emitting element 130c can be improved.

The common layer 114 includes, for example, an electron-injection layer or a hole-injection layer. Alternatively, the common layer 114 may be a stack of an electron-transport layer and an electron-injection layer, and may be a stack of a hole-transport layer and a hole-injection layer. As described above, the common layer 114 is shared by the light-emitting element 130a, the light-emitting element 130b, and the light-emitting element 130c.

In the display device of one embodiment of the present invention, the distance between the light-emitting elements can be narrowed. Specifically, the distance between the light-emitting elements, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display device of one embodiment of the present invention includes a region where a distance between two island-shaped EL layers adjacent to each other is less than or equal to 1 μm, preferably less than or equal to 0.5 μm (500 nm), further preferably less than or equal to 100 nm.

The protective layer 131 is preferably included over the light-emitting element 130a, the light-emitting element 130b, and the light-emitting element 130c. Providing the protective layer 131 can increase the reliability of the light-emitting element 130. The protective layer 131 may have a single-layer structure or a stacked-layer structure of two or more layers.

There is no limitation on the conductivity of the protective layer 131. As the protective layer 131, at least one type of an insulating film, a semiconductor film, and a conductive film can be used.

The protective layer 131 including an inorganic film can inhibit deterioration of the light-emitting element by preventing oxidation of the common electrode 115 and inhibiting entry of impurities (e.g., water and oxygen) into the light-emitting element, for example; thus, the reliability of the display device can be improved.

As the protective layer 131, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, a tantalum oxide film, and the like. Examples of the nitride insulating film include a silicon nitride film and an aluminum nitride film. Examples of the oxynitride insulating film include a silicon oxynitride film, an aluminum oxynitride film, and the like. Examples of the nitride oxide insulating film include a silicon nitride oxide film, an aluminum nitride oxide film, and the like. In particular, the protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting element 130 is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can be, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layers.

Furthermore, the protective layer 131 may include an organic film. For example, the protective layer 131 may include both an organic film and an inorganic film. Examples of an organic material that can be used for the protective layer 131 include organic insulating materials that can be used for the insulating layer 127 described later.

The protective layer 131 may have a stacked-layer structure of two layers which are formed by different deposition methods. Specifically, a first layer of the protective layer 131 and a second layer of the protective layer 131 may be formed by an atomic layer deposition (ALD) method and a sputtering method, respectively.

For example, in FIG. 2A, an insulating layer covering an end portion of a top surface of the pixel electrode 111a is not provided between the pixel electrode 111a and the EL layer 113a.

For example, an insulating layer covering an end portion of a top surface of the pixel electrode 111b is not provided between the pixel electrode 111b and the EL layer 113b. For example, an insulating layer covering an end portion of a top surface of the pixel electrode 111c is not provided between the pixel electrode 111c and the EL layer 113c. Thus, the distance between adjacent light-emitting elements 130 can be extremely small. Accordingly, the display device can have high resolution or high definition.

For example, in FIG. 2A, a mask layer 118a is positioned over the EL layer 113a included in the light-emitting element 130a, a mask layer 118b is positioned over the EL layer 113b included in the light-emitting element 130b, and a mask layer 118c is positioned over the EL layer 113c included in the light-emitting element 130c. Details will be described later, and the mask layer 118a is the remainder of a mask layer that can be used as a hard mask for processing an EL film to form the island-shaped EL layer 113a. Similarly, the mask layer 118b is the remainder of a mask layer provided at the time of forming the EL layer 113b, and the mask layer 118c is the remainder of a mask layer provided at the time of forming the EL layer 113c. In such a manner, the mask layer used to protect the EL layer in formation of the EL layer may partly remain in the display device of one embodiment of the present invention. For any two or all of the mask layer 118a to the mask layer 118c, the same or different materials may be used.

In FIG. 2A, one end portion of the mask layer 118a is aligned or substantially aligned with the end portion of the EL layer 113a, and the other end portion of the mask layer 118a is positioned over the EL layer 113a. Here, the other end portion of the mask layer 118a preferably overlaps with the EL layer 113a and the pixel electrode 111a. In that case, the other end portion of the mask layer 118a is likely to be formed on a substantially flat surface of the EL layer 113a. The same applies to the mask layer 118b and the mask layer 118c. The mask layer 118 remains between the top surface of an EL layer 113 processed into an island shape and the insulating layer 125, for example.

As the mask layer 118, one or more kinds of a metal film, an alloy film, a metal oxide film, a semiconductor film, an organic insulating film, and an inorganic insulating film can be used, for example. As the mask layer, a variety of inorganic insulating films that can be used as the protective layer 131 can be used. For example, an inorganic insulating material such as aluminum oxide, hafnium oxide, or silicon oxide can be used.

As illustrated in FIG. 2A, the insulating layer 125, the light-blocking layer 135, and the insulating layer 127 preferably cover part of a top surface of the EL layer 113 processed into an island shape. When the insulating layer 125, the light-blocking layer 135, and the insulating layer 127 cover not only a side surface of the EL layer 113 processed into an island shape but also the top surface thereof, peeling of the EL layer 113 can be prevented more suitably and the reliability of the light-emitting element 130 can be improved. In addition, the manufacturing yield of the light-emitting element 130 can be further increased. In the example illustrated in FIG. 2A, the EL layer 113a, the mask layer 118a, the insulating layer 125, the light-blocking layer 135, and the insulating layer 127 are stacked and positioned over the end portion of the pixel electrode 111a. Similarly, the EL layer 113b, the mask layer 118b, the insulating layer 125, the light-blocking layer 135, and the insulating layer 127 are stacked and positioned over the end portion of the pixel electrode 111b; and the EL layer 113c, the mask layer 118c, the insulating layer 125, the light-blocking layer 135, and the insulating layer 127 are stacked and positioned over the end portion of the pixel electrode 111c.

For example, FIG. 2A illustrates an example where the end portion of the EL layer 113a is positioned outward from the end portion of the pixel electrode 111a, an end portion of the EL layer 113b is positioned outward from the end portion of the pixel electrode 111b, and an end portion of the EL layer 113c is positioned outward from the end portion of the pixel electrode 111c.

For example, in FIG. 2A, the EL layer 113 is formed to cover the end portion of the pixel electrode 111. Such a structure can increase the aperture ratio compared with the structure in which the end portion of the island-shaped EL layer 113 is positioned inward from the end portion of the pixel electrode 111.

Covering the side surface of the pixel electrode 111 with the EL layer 113 inhibits contact between the pixel electrode 111 and the common electrode 115, thereby inhibiting a short circuit in the light-emitting element 130. Furthermore, the distance between the light-emitting region (i.e., the region overlapping with the pixel electrode 111) in the EL layer 113 and the end portion of the EL layer 113 can be increased, resulting in higher reliability of the light-emitting element 130.

The side surface of the EL layer 113 is covered at least with the insulating layer 125. The side surface of the EL layer 113 may be covered with the light-blocking layer 135. Furthermore, the side surface of the EL layer 113 may be covered with the light-blocking layer 135 and the insulating layer 127. Moreover, part of the top surface of the EL layer 113 is covered with the insulating layer 127, the light-blocking layer 135, the insulating layer 125, and the mask layer 118. Thus, the common layer 114 or the common electrode 115 can be inhibited from being in contact with the side surface of the pixel electrode 111 and the side surface of the EL layer 113, so that a short-circuit of light-emitting element 130 can be inhibited. Thus, the reliability of the light-emitting element 130 can be increased.

In the cross-sectional view, the insulating layer 125 preferably covers at least one of the side surfaces of the island-shaped EL layers 113, and further preferably covers both of the side surfaces of the island-shaped EL layers 113. The insulating layer 125 can be in contact with each side surface of the island-shaped EL layers 113.

For example, FIG. 2A illustrates a structure in which the end portion of the pixel electrode 111a is covered with the EL layer 113a and the insulating layer 125 is in contact with the side surface of the EL layer 113a. Similarly, the end portion of the pixel electrode 111b is covered with the EL layer 113b, the end portion of the pixel electrode 111c is covered with the EL layer 113c, and the insulating layer 125 is in contact with the side surface of the EL layer 113b and the side surface of the EL layer 113c.

The light-blocking layer 135 can be provided over the insulating layer 125; for example, the light-blocking layer 135 can be provided to be in contact with a top surface of the insulating layer 125. An end portion of the light-blocking layer 135 can be aligned or substantially aligned with an end portion of the insulating layer 125.

The insulating layer 127 is provided over the insulating layer 125 to fill a depressed portion formed in the light-blocking layer 135. The insulating layer 127 can overlap with part of the top and side surfaces of the EL layer 113 with the insulating layer 125 and the light-blocking layer 135 therebetween.

Moreover, providing the insulating layer 127 can fill the space between adjacent island-shaped layers; hence, the formation surface of a layer (e.g., a carrier-injection layer and a common electrode) provided over the island-shaped layer can reduce unevenness having a large height difference and can be flatter. Thus, the coverage with the carrier-injecting layer, the common electrode, and the like can be increased and disconnection of the common electrode can be prevented.

In this specification and the like, disconnection refers to a phenomenon in which a layer, a film, or an electrode is split because of the shape of the formation surface (e.g., a level difference).

The thickness of the light-blocking layer 135 is preferably greater than or equal to 3 nm or greater than or equal to 5 nm, and less than or equal to 200 nm, less than or equal to 150 nm, less than or equal to 100 nm, less than or equal to 50 nm, or less than or equal to 10 nm.

The common layer 114 and the common electrode 115 are provided over the EL layer 113 and the insulating layer 127. Before the insulating layer 127 is provided, there is a level difference due to a region where the pixel electrode 111 and the EL layer 113 are provided and a region where neither the pixel electrode 111 nor the EL layer 113 is provided (a region between the light-emitting elements 130). In the display device of one embodiment of the present invention, the level difference can be planarized with the insulating layer 127, and the coverage with the common layer 114 and the common electrode 115 can be improved. Consequently, it is possible to inhibit a connection defect due to disconnection. Alternatively, an increase in electrical resistance, which is caused by a reduction in thickness locally of the common electrode 115 due to level difference, can be inhibited.

For example, FIG. 2A illustrates a structure in which a top surface of the insulating layer 127 has a projecting portion. The top surface of the insulating layer 127 preferably has a smooth convex shape with high flatness. Note that it is further preferable that the top surface of the insulating layer 127 be flat. The top surface of the insulating layer 127 may have a depressed portion.

The insulating layer 125 can be provided in contact with the island-shaped EL layer 113. Thus, peeling of the island-shaped EL layer 113 can be prevented. When the insulating layer 125 and the EL layer 113 are in close contact with each other, an effect of fixing the adjacent island-shaped EL layers 113 by or attaching the adjacent island-shaped EL layers 113 to the insulating layer 125 can be attained. Thus, the reliability of the light-emitting element 130 can be increased. The manufacturing yield of the light-emitting element 130 can be increased.

Here, the insulating layer 125 includes a region in contact with the side surface of the island-shaped EL layer 113 and functions as a protective insulating layer of the EL layer 113. Providing the insulating layer 125 can inhibit impurities (e.g., oxygen and moisture) from entering the island-shaped EL layer 113 through their side surfaces, resulting in a highly reliable display device.

Next, examples of materials and formation methods of the insulating layer 125, the light-blocking layer 135, and the insulating layer 127 are described.

The insulating layer 125 can be formed using an inorganic material. Therefore, the insulating layer 125 can be referred to as an inorganic insulating layer or simply an inorganic layer. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium-gallium-zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferably used because it has high selectivity with respect to the EL layer in etching and has a function of protecting the EL layer when the insulating layer 127 to be described later is formed. An inorganic insulating film such as an aluminum oxide film, a hafnium oxide film, or a silicon oxide film is formed by an ALD method as the insulating layer 125, whereby the insulating layer 125 can have few pinholes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. Alternatively, the insulating layer 125 preferably has a function of inhibiting the diffusion of at least one of water and oxygen. Alternatively, the insulating layer 125 preferably has a function of capturing or fixing (also referred to as gettering) at least one of water and oxygen.

When the insulating layer 125 has a function of a barrier insulating layer or a gettering function, entry of impurities (typically, at least one of water and oxygen) that might diffuse into the light-emitting element from the outside can be inhibited. With this structure, a highly reliable light-emitting element and a highly reliable display device can be provided.

The insulating layer 125 preferably has a low impurity concentration. In this case, deterioration of the EL layer due to entry of impurities from the insulating layer 125 into the EL layer can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

As the formation method of the insulating layer 125, an ALD method, an evaporation method, a sputtering method, a chemical vapor deposition (CVD) method, a pulsed laser deposition (PLD) method, and the like can be given. The insulating layer 125 is preferably formed by an ALD method achieving good coverage.

When the substrate temperature at the time when the insulating layer 125 is formed is increased, the formed insulating layer 125, even with a small thickness, can have a low impurity concentration and a high barrier property against at least one of water and oxygen. Therefore, the substrate temperature is preferably higher than or equal to 60° C., further preferably higher than or equal to 80° C., still further preferably higher than or equal to 100° C., yet still further preferably higher than or equal to 120° C. Meanwhile, the insulating layer 125 is formed after formation of an island-shaped EL layer, and thus is preferably formed at a temperature lower than the upper temperature limit of the EL layer. Therefore, the substrate temperature is preferably lower than or equal to 200° C., further preferably lower than or equal to 180° C., still further preferably lower than or equal to 160° C., still further preferably lower than or equal to 150° C., yet still further preferably lower than or equal to 140° C.

Examples of indicators of the upper temperature limit are the glass transition point, the softening point, the melting point, the thermal decomposition temperature, and the 5% weight loss temperature. The upper temperature limit of the EL layer can be, for example, any of the above temperatures, preferably the lowest temperature thereof.

The thickness of the insulating layer 125 is preferably greater than or equal to 3 nm, greater than or equal to 5 nm, or greater than or equal to 10 nm and less than or equal to 200 nm, less than or equal to 150 nm, less than or equal to 100 nm, or less than or equal to 50 nm, for example.

As the insulating layer 127, an insulating layer containing an organic material can be suitably used. Therefore, the insulating layer 127 can be referred to as an organic insulating layer or simply an organic layer. As the organic material, a photosensitive organic resin is preferably used; for example, a photosensitive acrylic resin is used. The viscosity of the material of the insulating layer 127 is greater than or equal to 1 cP and less than or equal to 1500 cP, and is preferably greater than or equal to 1 cP and less than or equal to 12 cP. By setting the viscosity of the material of the insulating layer 127 in the above range, the insulating layer 127 having a tapered shape, which is to be described later, can be formed relatively easily. Note that in this specification and the like, an acrylic resin refers to not only a polymethacrylic acid ester or a methacrylic resin, but also all the acrylic polymer in a broad sense in some cases.

Note that the organic material usable for the insulating layer 127 is not limited to the above description as long as the insulating layer 127 has a side surface with a tapered shape as described later. For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like can be used in some cases, for example. Alternatively, an organic material such as polyvinyl alcohol (PVA), polyvinylbutyral, polyvinylpyrrolidone, polyethylene glycol, polyglycerin, pullulan, water-soluble cellulose, an alcohol-soluble polyamide resin, or the like can be employed for the insulating layer 127 in some cases. As the photosensitive resin, a photoresist can be used in some cases. As the photosensitive resin, a positive photosensitive material or a negative photosensitive material can be used in some cases.

The insulating layer 127 may be formed using a material absorbing visible light. When the insulating layer 127 absorbs light emitted from the light-emitting element 130, leakage of light (stray light) from the light-emitting element 130 to the adjacent light-emitting element 130 through the insulating layer 127 can be inhibited. Thus, the display quality of the display device can be improved. Since no polarizing plate is required to improve the display quality of the display device, the weight and thickness of the display device can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two or three or more colors is particularly preferable to enhance the effect of blocking visible light. In particular, mixing color filter materials of three or more colors enables the formation of a black or nearly black resin layer.

The insulating layer 127 can be formed by depositing and processing an organic insulating film, for example. In this case, for example, the insulating film to be the insulating layer 127 can be deposited by a wet process such as spin coating, dipping, spray coating, ink-jetting, dispensing, screen printing, offset printing, doctor blade coating, slit coating, roll coating, curtain coating, or knife coating. Specifically, an organic insulating film that is to be the insulating layer 127 is preferably formed by spin coating.

When a photosensitive organic insulating film is used as the insulating film to be the insulating layer 127, the insulating film to be the insulating layer 127 can be processed by light exposure and development steps. Therefore, the insulating film to be the insulating layer 127 can be processed without, for example, a dry etching method and thus damage on the EL layer 113 can be reduced.

When a photosensitive organic insulating film is used as the insulating film to be the insulating layer 127, the insulating film to be the insulating layer 127 is irradiated with ultraviolet light in the light exposure step in some cases. Therefore, in some cases, the EL layer 113 is also irradiated with ultraviolet light, and the EL layer 113 is damaged.

In view of the above, for example, providing a light-blocking film having an ultraviolet-light-blocking property can inhibit the EL layer 113 from being irradiated with ultraviolet light and damaged even when a photosensitive organic insulating film is used as the insulating film to be the insulating layer 127 and ultraviolet light irradiation is performed in the light exposure step. Therefore, the display device of one embodiment of the present invention can be a highly reliable display device. Note that in the case where the insulating film to be the insulating layer 127 is irradiated with visible light in the light exposure step on the insulating film to be the insulating layer 127, the light-blocking film has a visible-light-blocking property. Specifically, in the light exposure step on the insulating film to be the insulating layer 127, the light-blocking film has a light-blocking property with respect to light with a wavelength with which the insulating film to be the insulating layer 127 is irradiated.

In this specification and the like, ultraviolet light refers to light in a wavelength region greater than or equal to 10 nm and less than 400 nm, and visible light refers to light in a wavelength region greater than or equal to 400 nm and less than 700 nm.

For example, the light-blocking film has a function of absorbing or reflecting light with at least a certain wavelength in light with which the insulating film to be the insulating layer 127 is irradiated in the light exposure step on the insulating film to be the insulating layer 127. For example, the transmittance of the light-blocking film with respect to light with at least a certain wavelength in light with which the insulating film to be the insulating layer 127 is irradiated in the light exposure step on the insulating film to be the insulating layer 127 is less than or equal to 10%, preferably less than or equal to 1%, further preferably less than or equal to 0.1%.

The light-blocking layer 135 can be formed between the adjacent light-emitting elements 130 by processing the light-blocking film by, for example, an etching method after forming the insulating layer 127. The light-blocking layer 135 preferably has a function of absorbing or reflecting light with at least a certain wavelength in light that is emitted from the light-emitting element 130. Accordingly, stray light of the light that is emitted from the light-emitting element 130 can be inhibited, and display quality of the display device can be increased.

An insulating layer can be used as the light-blocking layer 135, but one embodiment of the present invention is not limited thereto: a conductive layer or a semiconductor layer may be used. As described above, when the light-blocking film is processed by, for example, an etching method the light-blocking layer 135 can be formed. Thus, the light-blocking layer 135 preferably has a high processing property by, for example, an etching method.

For example, for the light-blocking layer 135, a material containing a Group 14 element such as carbon, germanium, or silicon such as amorphous silicon can be used. For example, a metal may be used for the light-blocking layer 135: molybdenum, titanium, tantalum, tungsten, aluminum, copper, chromium, neodymium, scandium, or an alloy containing any of these metals can be used, for example. Furthermore, for the light-blocking layer 135, it is possible to use a nitride containing any of the above metals as a component (e.g., titanium nitride, chromium nitride, molybdenum nitride, or tungsten nitride) or an oxide containing any of the above metals as a component (e.g., titanium oxide, chromium oxide, molybdenum oxide, or tungsten oxide).

Here, in the display device of one embodiment of the present invention, the light-blocking layer 135 is provided over the insulating layer 125. Thus, the light-blocking layer 135 can be prevented from being in contact with the EL layer 113. Therefore, the range of choices for the material of the light-blocking layer 135 can be expanded more than that in the case where the insulating layer 125 is not provided. For example, a material that might damage the EL layer 113 when in contact with the EL layer 113 can be used for the light-blocking layer 135. Furthermore, a method that might damage the EL layer 113 exposed at the time of formation of the light-blocking layer 135 can be employed for the formation of the light-blocking layer 135. Moreover, a material having a conductive property such as metal can be used for the light-blocking layer 135. Note that in the case where an insulating material that does not damage the EL layer 113 even when in contact with the EL layer 113 is used for the light-blocking layer 135, the display device of one embodiment of the present invention can have a structure in which the insulating layer 125 is not included.

Note that the insulating layer 127 is formed at a temperature lower than the upper temperature limit of the EL layer 113. The typical substrate temperature in formation of the insulating layer 127 is lower than or equal to 200° C., preferably lower than or equal to 180° C., further preferably lower than or equal to 160° C., still further preferably lower than or equal to 150° C., yet still further preferably lower than or equal to 140° C.

A light-blocking layer may be provided on the surface of the substrate 120 on the adhesive layer 122 side. Moreover, a variety of optical members can be provided on the outer side of the substrate 120. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film suppressing the attachment of stain, a hard coat film inhibiting generation of a scratch caused by the use, an impact-absorbing layer, or the like may be provided as a surface protective layer on the outer surface of the substrate 120. For example, it is preferable to provide, as the surface protective layer, a glass layer or a silica layer (SiOₓ layer) because the surface contamination or damage can be inhibited from being generated. The surface protective layer may be formed using DLC (diamond like carbon), aluminum oxide (AlOₓ), a polyester-based material, a polycarbonate-based material, or the like. For the surface protective layer, a material having a high visible-light transmittance is preferably used. The surface protective layer is preferably formed using a material with high hardness.

For the substrate 120, glass, quartz, ceramics, sapphire, a resin, a metal, an alloy, a semiconductor, or the like can be used. The substrate on the side from which light from the light-emitting element is extracted is formed using a material which transmits the light. When a flexible material is used for the substrate 120, the flexibility of the display device can be increased.

Furthermore, a polarizing plate may be used as the substrate 120. For the substrate 120, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 120.

In the case where a circularly polarizing plate overlaps with the display devices, a highly optically isotropic substrate is preferably used as the substrate included in the display devices. A highly optically isotropic substrate can be said to have a low birefringence (a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of films having high optical isotropy include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of the display device might be changed, e.g., creases are generated. Thus, as the substrate, a film with a low water absorption rate is preferably used. For example, the water absorption rate of the film is preferably 1% or lower, further preferably 0.1% or lower, still further preferably 0.01% or lower.

For the adhesive layer 122, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. A two-component-mixture-type resin may be used. An adhesive sheet may be used, for example.

FIG. 2B1 is a cross-sectional view taken along the dashed-dotted line Y1-Y2 in FIG. 1. FIG. 2B1 illustrates a structure example of the connection portion 140.

A conductive layer 123 is provided over the insulating layer 255c in the connection portion 140. The conductive layer 123 is electrically connected to the common electrode 115. As the conductive layer 123, a conductive layer formed using the same material in the same step as the pixel electrode 111a, the pixel electrode 111b, and the pixel electrode 111c are preferably used.

Note that FIG. 2B1 illustrates an example in which the common layer 114 is provided over the conductive layer 123 and the conductive layer 123 and the common electrode 115 are electrically connected to each other through the common layer 114. The common layer 114 is not necessarily provided in the connection portion 140. In FIG. 2B2, the conductive layer 123 and the common electrode 115 are directly connected to each other. For example, by using a mask for specifying a deposition area (also referred to as an area mask or a rough metal mask to distinguish from a fine metal mask), the common layer 114 can be formed in a region different from a region where the common electrode 115 is formed.

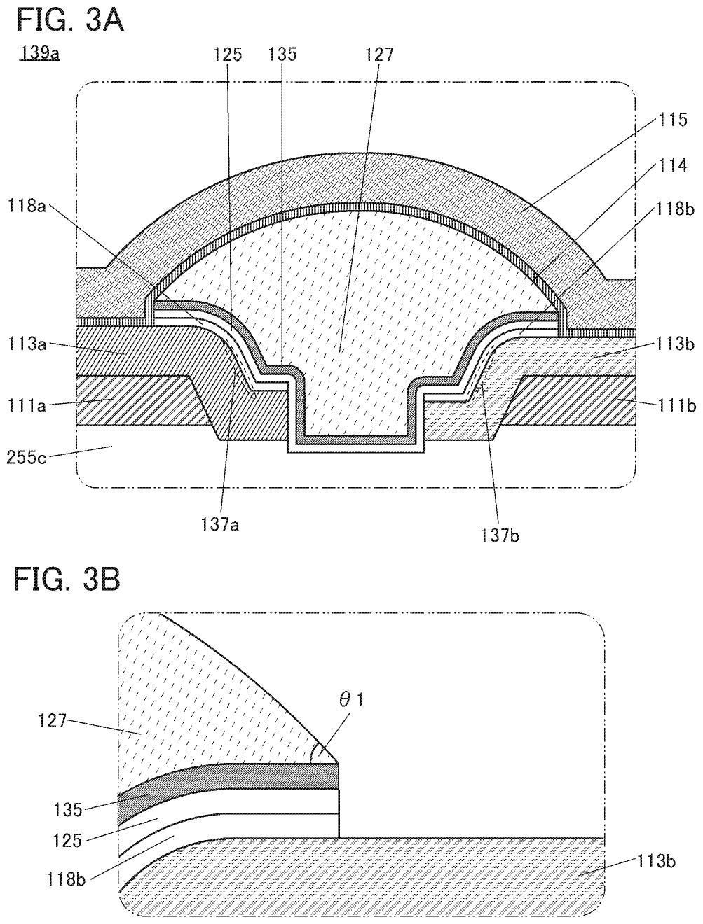

Here, a structure of the insulating layer 127 and its vicinity will be described with reference to FIGS. 3A and 3B. FIG. 3A is an enlarged cross-sectional view of a region 139a including the insulating layer 127 and its vicinity between the light-emitting element 130a and the light-emitting element 130b. Although the insulating layer 127 between the light-emitting element 130a and the light-emitting element 130b is described below as an example, the same applies to the insulating layer 127 between the light-emitting element 130b and the light-emitting element 130c, the insulating layer 127 between the light-emitting element 130c and the light-emitting element 130a, and the like. FIG. 3B is an enlarged view of the vicinity of an end portion of the insulating layer 127 over the EL layer 113b illustrated in FIG. 3A. Although the description is sometimes made below using the end portion of the insulating layer 127 over the EL layer 113b as an example, the same applies to the end portion of the insulating layer 127 over the EL layer 113a and the end portion of the insulating layer 127 over the EL layer 113c.

As illustrated in FIG. 3A, in the region 139a, the EL layer 113a is provided to cover the pixel electrode 111a and the EL layer 113b is provided to cover the pixel electrode 111b. The mask layer 118a is provided in contact with part of the top surface of the EL layer 113a, and the mask layer 118b is provided in contact with part of the top surface of the EL layer 113b. The insulating layer 125 is provided in contact with a top surface and a side surface of the mask layer 118a, the side surface of the EL layer 113a, a top surface of the insulating layer 255c, a top surface and a side surface of the mask layer 118b, and the side surface of the EL layer 113b. The light-blocking layer 135 is provided over the insulating layer 125 and the insulating layer 127 is provided over the light-blocking layer 135. The common layer 114 is provided to cover the EL layer 113a, the mask layer 118a, the EL layer 113b, the mask layer 118b, the insulating layer 125, the light-blocking layer 135, and the insulating layer 127, and the common electrode 115 is provided over the common layer 114.

As described above, the side surface of the pixel electrode 111 preferably has a tapered shape. In this case, the EL layer 113 can have a tapered portion 137 in the cross-sectional view of the display device. Specifically, the EL layer 113 can include the tapered portion 137 between the side surface of the pixel electrode 111 and the insulating layer 125. In FIG. 3A, the EL layer 113a includes a tapered portion 137a between the side surface of the pixel electrode 111a and the mask layer 118a, and the EL layer 113b includes a tapered portion 137b between the side surface of the pixel electrode 111b and the mask layer 118b.

The taper angle of the side surface of the pixel electrode 111 is less than 90°, preferably less than or equal to 60°, and further preferably less than or equal to 45°. The side surface of the pixel electrode 111 has such a forward tapered shape, whereby disconnection, local thinning, or the like is inhibited from being generated in the EL layer 113 provided to cover the side surface of the pixel electrode 111, and the EL layer 113 can be formed with excellent coverage. Therefore, the display device of one embodiment of the present invention can be a highly reliable display device.

The size of the taper angle of the tapered portion 137 can be the size corresponding to the taper angle of the side surface of the pixel electrode 111. For example, the smaller the taper angle of the side surface of the pixel electrode 111 is, the smaller the taper angle of the tapered portion 137 can be. The taper angle of the tapered portion 137 is less than 90°, preferably less than or equal to 60°, and further preferably less than or equal to 45°.

Meanwhile, in the case where the angle of the tapered portion 137 is less than 90°, the tapered portion is more easily irradiated with ultraviolet light in the light exposure step on the insulating film to be the insulating layer 127 than in the case where the angle of the tapered portion 137 is greater than or equal to 90°. In the display device of one embodiment of the present invention, the light-blocking film to be the light-blocking layer 135 is provided, whereby the tapered portion 137 of the EL layer 113 can also be inhibited from being irradiated with, for example, ultraviolet light and damage on the EL layer 113 can be inhibited. From the above, in the display device of one embodiment of the present invention, coverage of the pixel electrode 111 with the EL layer 113 can be increased and the EL layer 113 can be inhibited from being damaged in the manufacturing process. Therefore, the display device of one embodiment of the present invention can be a highly reliable display device.

As illustrated in FIG. 3B, the end portion of the insulating layer 127 preferably has a tapered shape with a taper angle θ1 on the side surface in the cross-sectional view of the display device. The taper angle θ1 is an angle formed by the side surface of the insulating layer 127 and the substrate surface. Alternatively, the taper angle θ1 may be an angle formed by the side surface of the insulating layer 127 and, instead of the substrate surface, the top surface of a flat portion of the insulating layer 125, the top surface of a flat portion of the EL layer 113b, or the top surface of a flat portion of the pixel electrode 111b.

The taper angle θ1 of the insulating layer 127 is less than 90°, preferably less than or equal to 60°, and further preferably less than or equal to 45°. Such a forward tapered shape of the end portion of the side surface of the insulating layer 127 can prevent disconnection, local thinning, or the like from being generated in the common layer 114 and the common electrode 115 that are provided over the end portion of the side surface of the insulating layer 127, and the common layer 114 and the common electrode 115 can be formed with good coverage. Accordingly, the common layer 114 and the common electrode 115 can be formed with favorable in-plane uniformity, which enables the display quality of the display device to be improved.

As illustrated in FIG. 3A, in the cross-sectional view of the display device, the top surface of the insulating layer 127 preferably has a convex shape. The convex top surface of the insulating layer 127 preferably has a shape that expands gradually toward the center. The insulating layer 127 preferably has a shape such that the convex portion at the center portion of the top surface is connected smoothly to the tapered portion of the end portion of the side surface. When the insulating layer 127 has such a shape, the common layer 114 and the common electrode 115 can be formed with good coverage over the whole insulating layer 127.

As illustrated in FIG. 3A, one end portion of the insulating layer 127 preferably overlaps with the pixel electrode 111a and the other end portion of the insulating layer 127 preferably overlaps with the pixel electrode 111b. With such a structure, the end portion of the insulating layer 127 can be formed over a substantially flat region of the EL layer 113a (the EL layer 113b). Therefore, as described above, the tapered shape of the insulating layer 127 is relatively easily formed by processing.

In the region 139a, by forming the insulating layer 127 in the above manner, for example, a disconnected portion and a locally thinned portion can be prevented from being formed in the common layer 114 and the common electrode 115 from a substantially flat region in the EL layer 113a to a substantially flat region in the EL layer 113b. Thus, between the light-emitting elements, a connection defect caused by the disconnected portion and an increase in electric resistance caused by the locally thinned portion can be inhibited from occurring in the common layer 114 and the common electrode 115. Therefore, the display device of one embodiment of the present invention can have high display quality.

### [Structure Example_2 of Display Device]

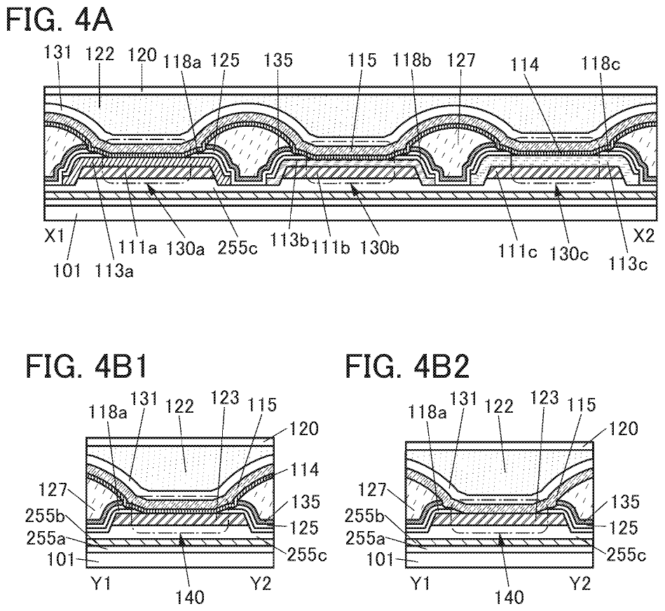

FIG. 4A, FIG. 4B1, and FIG. 4B2 are modification examples of the structure illustrated in FIG. 2A, FIG. 2B1, and FIG. 2B2, respectively. The display device illustrated in FIG. 4A, FIG. 4B1, and FIG. 4B2 is different from the display device illustrated in FIG. 2A, FIG. 2B1, and FIG. 2B2 in including a region where the end portion of the mask layer 118 and the end portion of the insulating layer 125 are not aligned with or substantially aligned with the end portion of the insulating layer 127 and the end portion of the light-blocking layer 135. Specifically, in the cross-sectional view of the display device, the display device illustrated in FIG. 4A, FIG. 4B1, and FIG. 4B2 includes a region where the end portion of the mask layer 118 and the end portion of the insulating layer 125 are closer to a center portion of the EL layer 113 and closer to a center portion of the conductive layer 123 than the end portion of the insulating layer 127 and the end portion of the light-blocking layer 135 are.

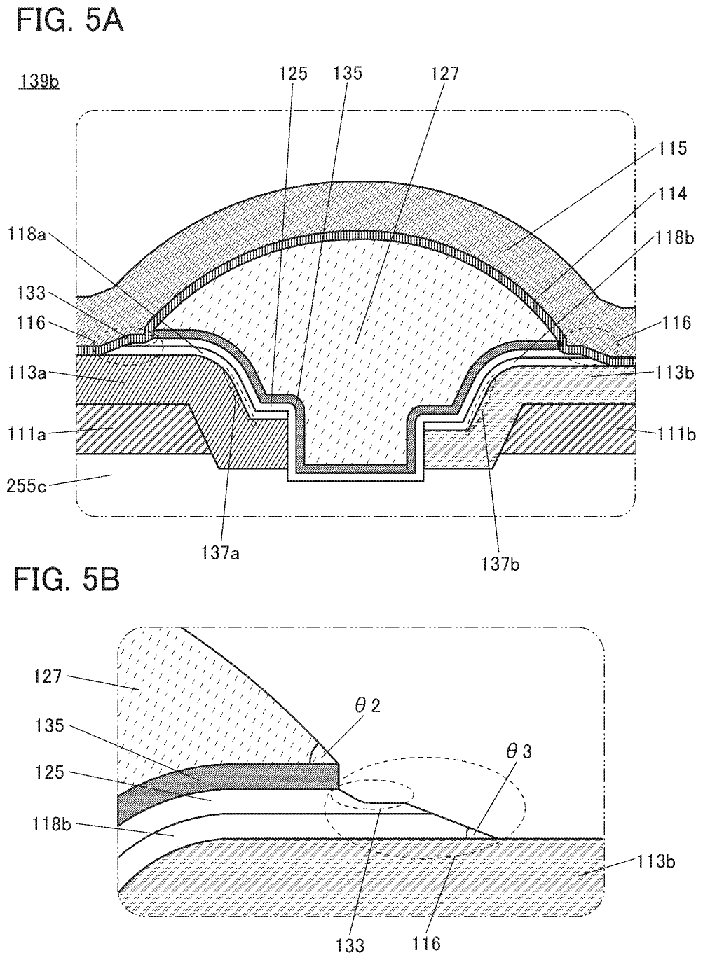

FIG. 5A is an enlarged cross-sectional view of a region 139b including the insulating layer 127 and its vicinity between the light-emitting element 130a and the light-emitting element 130b illustrated in FIG. 4A. FIG. 5B is an enlarged view of the vicinity of the end portion of the insulating layer 127 over the EL layer 113b illustrated in FIG. 5A. A structure different from the structure of FIG. 3A and FIG. 3B is mainly described below.

As illustrated in FIG. 5A and FIG. 5B, the mask layer 118b and the insulating layer 125 include a protruding portion 116 over the pixel electrode 111b. In the cross-sectional view of the display device, the protruding portion 116 is positioned closer to the center portion of, for example, the EL layer 113b than the end portion of the insulating layer 127 and the end portion of the light-blocking layer 135 are. Furthermore, the mask layer 118a and the insulating layer 125 also include a similar protruding portion 116 over the pixel electrode 111a.

As illustrated in FIG. 5B, the protruding portion 116 preferably has a tapered-shaped side surface with a taper angle θ3 in the cross-sectional view of the display device. The taper angle θ3 is an angle formed by the side surface of the mask layer 118b and the substrate surface. Note that the taper angle θ3 may be an angle formed by the side surface of the mask layer 118b and the top surface of the flat portion of the EL layer 113b, the top surface of the flat portion of the pixel electrode 111b, or the like, without being limited to the substrate surface. The taper angle θ3 may be an angle formed by the side surface of the insulating layer 125 and the substrate surface, without being limited to the side surface of the mask layer 118b.

The taper angle θ3 of the protruding portion 116 is less than 90°, preferably less than or equal to 60°, further preferably less than or equal to 45°, still further preferably less than or equal to 20°. The taper angle θ3 of the protruding portion 116 is smaller than the taper angle θ2 of the insulating layer 127 in some cases. Such a forward tapered shape of the protruding portion 116 can prevent, for example, disconnection from being generated in the common layer 114 and the common electrode 115 that are provided over the protruding portion 116, and the common layer 114 and the common electrode 115 can be formed with good coverage.

The protruding portion 116 is provided below the end portion of a side surface of the light-blocking layer 135, whereby the vicinity of an interface between the end portion of the side surface of the light-blocking layer 135 and the insulating layer 125 can be inhibited from being side-etched to form a void between the end portion of the side surface of the light-blocking layer 135 and the insulating layer 125. When such a void is formed, disconnection is easily generated in the common layer 114 and the common electrode 115 by level difference due to the void. However, when the insulating layer 125 and the mask layer 118b are provided to provide the protruding portion 116, side etching is inhibited from proceeding deeply below the light-blocking layer 135, and the void can be prevented from being large. Therefore, provision of the protruding portion 116 can prevent generation of, for example, disconnection in the common layer 114 and the common electrode 115 from the insulating layer 127 to the EL layer 113b.

In the protruding portion 116, the insulating layer 125 includes a region thinner than another portion (e.g., a portion with which the light-blocking layer 135 overlaps) (hereinafter, such the region is referred to as a depression portion 133) in some cases. Note that, for example, depending on the thickness of the insulating layer 125, the insulating layer 125 sometimes disappears and the depression portion 133 is sometimes formed also in the mask layer 118b in the protruding portion 116. The insulating layer 125 sometimes includes the depression portion 133 also on, for example, the EL layer 113a side.

### [Structure Example_3 of Display Device]

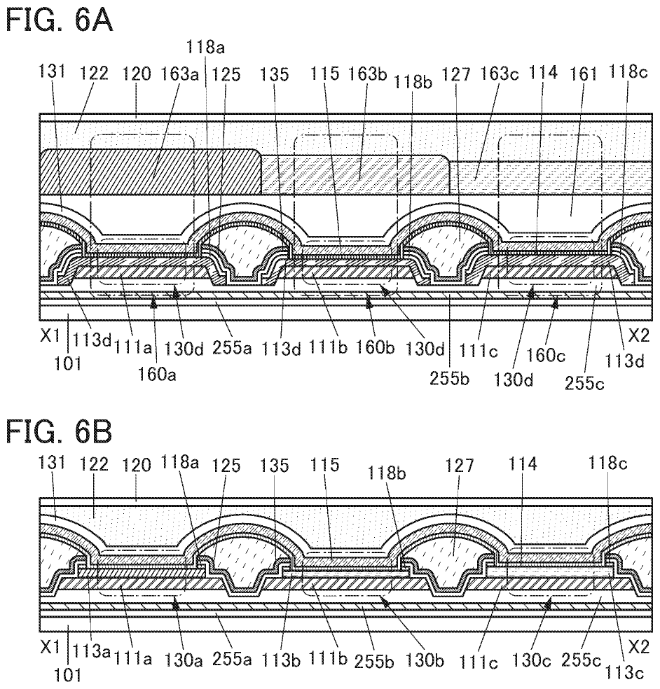

FIG. 6A is a modification example of the structure illustrated in FIG. 2A and is different from the display device illustrated in FIG. 2A in including a light-emitting element 130d instead of the light-emitting element 130a, the light-emitting element 130b, and the light-emitting element 130c. The light-emitting element 130d includes an EL layer 113d as the EL layer 113.

The EL layer 113d emits white light, for example. The protective layer 131 is provided to cover the light-emitting element 130d, and a protective layer 161 is provided over the protective layer 131. The protective layer 161 has a function of a planarization layer.

Each of a coloring layer 163a, a coloring layer 163b, and a coloring layer 163c is provided over the protective layer 161 to include a region overlapping with the light-emitting element 130d. The coloring layer 163a, the coloring layer 163b, and the coloring layer 163c can transmit light of red, green, or blue, for example. For example, the coloring layer 163a can transmit red light, the coloring layer 163b can transmit green light, and the coloring layer 163c can transmit blue light. Here, the light-emitting element 130d and the coloring layer 163a form a light-emitting unit 160a, the light-emitting element 130d and the coloring layer 163b form a light-emitting unit 160b, and the light-emitting element 130d and the coloring layer 163c form a light-emitting unit 160c.

With a coloring layer 163 provided to include a region overlapping with the light-emitting element 130, even when all light-emitting elements 130 included in the display device emit white light, for example, the display device can perform full-color display. The positional alignment of the light-emitting element 130 and the coloring layer 163 is easier in the case where the coloring layer 163 is provided over the protective layer 161 than in the case where a coloring layer is formed over the substrate 120, and then a substrate provided in the layer 101 and the substrate 120 are attached to each other. In that case, the display device with extremely high resolution can be achieved. In addition, the distance between the coloring layer 163 and the light-emitting element 130 can be shortened, which inhibits color mixture and also improves the viewing angle characteristics of luminance and chromaticity. In this manner, a display device with high display quality can be achieved. Note that in the case where there is no need to provide a layer having a function of a planarization layer between the protective layer 161 and the coloring layer 163, the protective layer 161 is not necessarily provided.

Here, the EL layer 113d is divided between different light-emitting elements 130d. This suitably prevents unintentional light emission (also referred to as crosstalk) due to a current flow through the EL layer 113d between adjacent light-emitting elements 130d. As a result, the contrast can be increased to achieve a display device with high display quality.

In the display device illustrated in FIG. 6A, the light-blocking layer 135 is provided between the adjacent light-emitting elements 130d. The light-blocking layer 135 preferably has a function of absorbing or reflecting light with at least a certain wavelength in light that is emitted from the light-emitting element 130d. Accordingly, light emitted from the light-emitting element 130d can be inhibited from entering the coloring layer 163 provided in an adjacent light-emitting unit 160 due to, for example, stray light. For example, light emitted from the light-emitting element 130d provided in the light-emitting unit 160a can be inhibited from entering the coloring layer 163b. This suppresses color mixture and achieves a display device with high display quality.

As illustrated in FIG. 6A, the thickness of the EL layer 113d included in the light-emitting unit 160a, the thickness of the EL layer 113d included in the light-emitting unit 160b, and the thickness of the EL layer 113d included in the light-emitting unit 160c are preferably different from each other. Accordingly, a microcavity structure can be obtained. For example, the light-emitting element 130d included in the light-emitting unit 160a can emit light of red enhanced more than other colors, the light-emitting element 130d included in the light-emitting unit 160b can emit light of green enhanced more than other colors, and the light-emitting element 130d included in the light-emitting unit 160c can emit light of blue enhanced more than other colors. Therefore, color purity in the light-emitting unit 160 can be increased. Note that in the case where the coloring layer 163 sufficiently blocks light of colors other than a desired color, the microcavity structure is not necessarily applied to the display device. For example, the EL layer 113d included in the light-emitting unit 160a, the EL layer 113d included in the light-emitting unit 160b, and the EL layer 113d included in the light-emitting unit 160c may all have the same thickness.

FIG. 6B is a modification example of the structure illustrated in FIG. 2A is different from the display device illustrated in FIG. 2A in that the end portion of the EL layer 113a is positioned inward from the end portion of the pixel electrode 111a, the end portion of the EL layer 113b is positioned inward from the end portion of the pixel electrode 111b, and the end portion of the EL layer 113c is positioned inward from the end portion of the pixel electrode 111c.

In the display device with the structure illustrated in FIG. 6B, since the EL layer 113 does not cover the side surface of the pixel electrode 111, level difference can be inhibited from being generated in the EL layer 113. Therefore, defects such as disconnection can be inhibited from being generated in the EL layer 113.

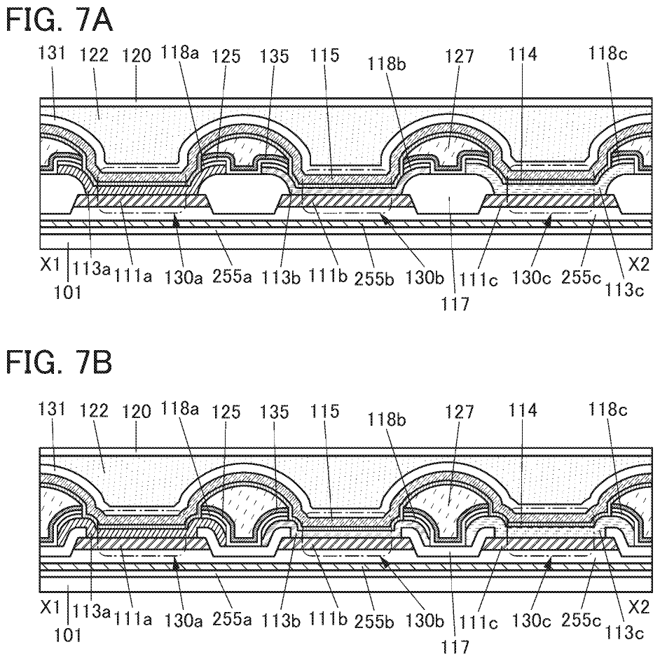

FIG. 7A is a modification example of the structure illustrated in FIG. 2A and is different from the display device illustrated in FIG. 2A in providing an insulating layer 117 between the adjacent light-emitting elements 130. The insulating layer 117 is provided to cover the end portion of the pixel electrode 111.

The EL layer 113 in a region not in contact with the pixel electrode 111 is provided over the insulating layer 117. Therefore, the display device with the structure illustrated in FIG. 7A includes, in the vicinity of the end portion of the pixel electrode 111, a region where the insulating layer 117 is provided between the pixel electrode 111 and the EL layer 113.

Over the EL layer 113, the mask layer 118 is provided to include a region overlapping with the insulating layer 117. The insulating layer 125 is provided over the mask layer 118 and the insulating layer 117, the light-blocking layer 135 is provided over the insulating layer 125, and the insulating layer 127 is provided over the light-blocking layer 135.

Providing the insulating layer 117 to cover the end portion of the pixel electrode 111 can prevent a short circuit between the adjacent pixel electrodes 111. Here, when an organic material, e.g., an organic resin is used for the insulating layer 117, the surface of the end portion can have a moderate curve. Thus, coverage with a layer provided over the insulating layer 117 can be improved. Furthermore, a top surface of the insulating layer 117 can be planarized.

Examples of an organic material that can be used for the insulating layer 117 include an acrylic resin, an epoxy resin, a polyimide resin, a polyamide resin, a polyimide-amide resin, a polysiloxane resin, a benzocyclobutene-based resin, and a phenol resin.

FIG. 7B is a modification example of the structure illustrated in FIG. 7A and is different from the display device illustrated in FIG. 7A in that an end portion of the insulating layer 117 has an angular shape and the top surface of the insulating layer 117 is not planarized. For the insulating layer 117 illustrated in FIG. 7B, an inorganic material can be used, for example.

Examples of an inorganic material that can be used for the insulating layer 117 include silicon oxide, aluminum oxide, gallium oxide, germanium oxide, yttrium oxide, zirconium oxide, lanthanum oxide, neodymium oxide, hafnium oxide, tantalum oxide, silicon nitride, aluminum nitride, silicon oxynitride, aluminum oxynitride, silicon nitride oxide, and aluminum nitride oxide.

Next, materials that can be used for the light-emitting element are described.

A conductive film that transmits visible light is used as the electrode through which light is extracted, which is either the pixel electrode or the common electrode. A conductive film that reflects visible light is preferably used as the electrode through which light is not extracted. In the case where a display device includes a light-emitting element emitting infrared light, a conductive film that transmits visible light and infrared light is used as the electrode through which light is extracted, and a conductive film that reflects visible light and infrared light is preferably used as the electrode through which light is not extracted.

A conductive film that transmits visible light may also be used as the electrode through which light is not extracted. In that case, this electrode is preferably provided between a reflective layer and the EL layer. In other words, light emitted from the EL layer may be reflected by the reflective layer to be extracted from the display device.

As a material that forms the pair of electrodes (the pixel electrode and the common electrode) of the light-emitting element, a metal, an alloy, an electrically conductive compound, a mixture thereof, and the like can be used as appropriate. Specific examples include an indium tin oxide (In—Sn oxide, also referred to as ITO), an In—Si—Sn oxide (also referred to as ITSO), an indium zinc oxide (In—Zn oxide), an In—W—Zn oxide, an alloy containing aluminum (an aluminum alloy) such as an alloy of aluminum, nickel, and lanthanum (Al—Ni—La), and an alloy containing silver such as an alloy of silver and magnesium and an alloy of silver, palladium, and copper (Ag—Pd—Cu, also referred to as APC). In addition, it is possible to use a metal such as aluminum (Al), magnesium (Mg), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use an element belonging to Group 1 or Group 2 of the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these, graphene, or the like.

In addition, the light-emitting element preferably also employs a microcavity structure. Therefore, one of the pair of electrodes of the light-emitting element preferably includes an electrode having properties of transmitting and reflecting visible light (a transflective electrode), and the other preferably includes an electrode having a property of reflecting visible light (a reflective electrode). When the light-emitting element has a microcavity structure, light obtained from the light-emitting layer can be resonated between the electrodes, whereby light emitted from the light-emitting element can be intensified.

The light-emitting layer is a layer containing a light-emitting substance. The light-emitting layer can include one or more kinds of light-emitting substances. As the light-emitting substance, a substance that exhibits an emission color of blue, violet, bluish violet, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (a host material, an assist material, or the like) in addition to the light-emitting substance (a guest material). As one or more kinds of organic compounds, one or both of the hole-transport material and the electron-transport material can be used. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer 113a, the EL layer 113b, and the EL layer 113c may further include layers containing a substance with a high hole-injection property, a substance with a high hole-transport property, a hole-blocking material, a substance with a high electron-transport property, a substance with a high electron-injection property, an electron-blocking material, a substance with a bipolar property (a substance with a high electron-transport property and a high hole-transport property), and the like.

Either a low molecular compound or a high molecular compound can be used for the light-emitting element, and an inorganic compound may also be contained. Each of the layers included in the light-emitting element can be formed by an evaporation method (including a vacuum evaporation method), a transfer method, a printing method, an inkjet method, a coating method, or the like.

For example, the EL layer 113a, the EL layer 113b, and the EL layer 113c may each include one or more of a hole-injection layer, a hole-transport layer, a hole-blocking layer, an electron-blocking layer, an electron-transport layer, and an electron-injection layer.

As the common layer 114, one or more of a hole-injection layer, a hole-transport layer, a hole-blocking layer, an electron-blocking layer, an electron-transport layer, and an electron-injection layer can be used. For example, a carrier-injection layer (a hole-injection layer or an electron-injection layer) may be formed as the common layer 114. Note that the light-emitting element does not necessarily include the common layer 114.

The EL layer 113a, the EL layer 113b, and the EL layer 113c each preferably include a light-emitting layer and a carrier-transport layer over the light-emitting layer. Accordingly, the light-emitting layer is inhibited from being exposed on the outermost surface in the process of manufacturing the display device 100, so that damage to the light-emitting layer can be reduced. As a result, the reliability of the light-emitting element can be increased.

The hole-injection layer is a layer injecting holes from an anode to a hole-transport layer and containing a material with a high hole-injection property. Examples of the material with a high hole-injection property include an aromatic amine compound, a composite material containing a hole-transport material and an acceptor material (an electron-accepting material), and the like.

The hole-transport layer is a layer transporting holes, which are injected from the anode by the hole-injection layer, to the light-emitting layer. The hole-transport layer is a layer containing a hole-transport material. The hole-transport material preferably has a hole mobility of 1×10⁻⁶ cm²/Vs or higher. Note that other substances can also be used as long as the substances have a hole-transport property higher than an electron-transport property. As the hole-transport material, a material with a high hole-transport property, such as a π-electron rich heteroaromatic compound (e.g., a carbazole derivative, a thiophene derivative, a furan derivative, or the like) or an aromatic amine (a compound having an aromatic amine skeleton), is preferable.

The electron-transport layer is a layer transporting electrons, which are injected from a cathode by the electron-injection layer, to the light-emitting layer. The electron-transport layer contains an electron-transport material. The electron-transport material preferably has an electron mobility of 1×10⁻⁶ cm²/Vs or higher. Note that other substances can also be used as long as the substances have an electron-transport property higher than a hole-transport property. As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The electron-injection layer is a layer injecting electrons from a cathode to the electron-transport layer and containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

For the electron-injection layer, it is possible to use, for example, an alkali metal, an alkaline earth metal, or a compound thereof, such as lithium, cesium, ytterbium, lithium fluoride (LiF), cesium fluoride (CsF), calcium fluoride (CaF_{X}, where X is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOx), or cesium carbonate. The electron-injection layer may have a stacked-layer structure of two or more layers. In the stacked-layer structure, for example, lithium fluoride can be used for the first layer and ytterbium can be used for the second layer.

Alternatively, for the electron-injection layer, an electron-transport material may be used. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, and a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′, 3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition temperature (Tg) than BPhen and thus has high heat resistance.

In the case of manufacturing a tandem light-emitting element, a charge-generation layer (also referred to as an intermediate layer) is provided between two light-emitting units. The intermediate layer has a function of injecting electrons into one of the two light-emitting units and injecting holes to the other when voltage is applied between the pair of electrodes.

For example, the charge-generation layer can be suitably formed using a material that can be used for the electron-injection layer, such as lithium. As another example, the charge-generation layer can be suitably formed using a material that can be used for the hole-injection layer. Moreover, the charge-generation layer can be a layer containing a hole-transport material and an acceptor material (electron-accepting material). The charge-generation layer can be a layer containing an electron-transport material and a donor material. Forming such a charge-generation layer can inhibit an increase in the driving voltage in the case of stacking light-emitting units.

### [Manufacturing Method Example_1 of Display Device]

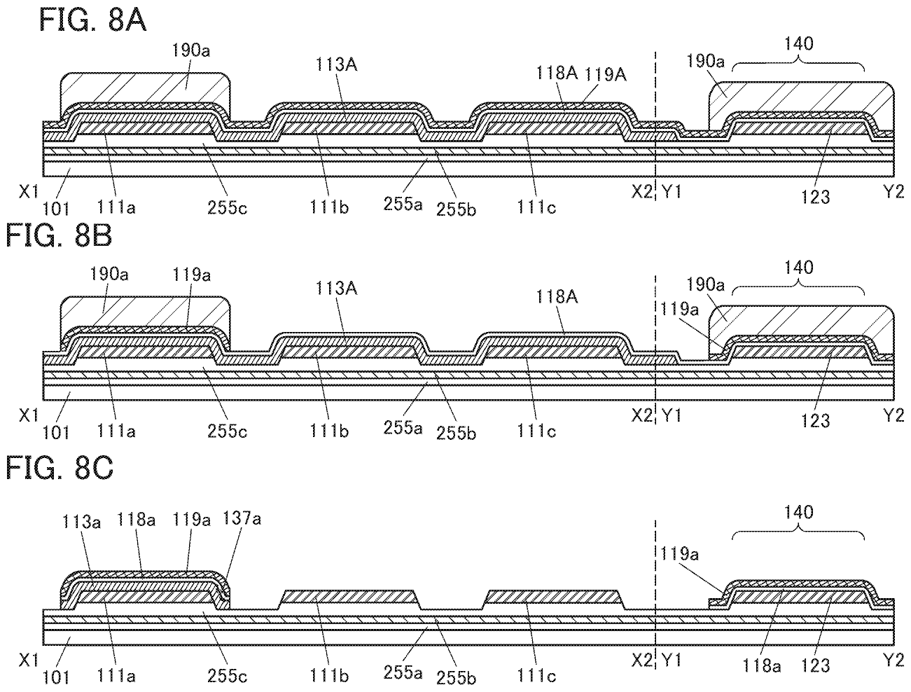

An example of a method for manufacturing the display device illustrated in FIG. 2A, FIG. 2B2, and the like is described with reference to FIG. 8A to FIG. 12C. FIG. 8A to FIG. 12C each illustrate a cross-sectional view along the dashed-dotted line X1-X2 and a cross-sectional view along the dashed-dotted line Y1-Y2 in FIG. 1 side by side.

Thin films included in the display device (e.g., insulating films, semiconductor films, and conductive films) can be formed by a sputtering method, a CVD method, a vacuum evaporation method, a PLD method, an ALD method, or the like. Examples of the CVD method include a plasma-enhanced chemical vapor deposition (PECVD: Plasma Enhanced CVD) method and a thermal CVD method. An example of a thermal CVD method is a metal organic chemical vapor deposition (MOCVD: Metal Organic CVD) method.

Alternatively, the thin films included in the display device (insulating films, semiconductor films, conductive films, and the like) can be formed by a method such as spin coating, dipping, spray coating, ink-jetting, dispensing, screen printing, offset printing, doctor blade coating, slit coating, roll coating, curtain coating, or knife coating.

In particular, for fabrication of the light-emitting element, a vacuum process such as an evaporation method or a solution process such as a spin coating method or an ink-jet method can be used. As the evaporation method, a physical vapor deposition method (PVD method) such as a sputtering method, an ion plating method, an ion beam evaporation method, a molecular beam evaporation method, or a vacuum evaporation method, a chemical vapor deposition method (CVD method), and the like can be given. In particular, functional layers (e.g., a hole-injection layer, a hole-transport layer, a light-emitting layer, an electron-transport layer, and an electron-injection layer) included in the EL layer can be formed by an evaporation method (e.g., a vacuum evaporation method), a coating method (e.g., a dip coating method, a die coating method, a bar coating method, a spin coating method, or a spray coating method), a printing method (e.g., an inkjet method, a screen printing (stencil) method, an offset printing (planography) method, a flexography (relief printing) method, a gravure printing method, or a micro-contact printing method), or the like.

When the thin films that form the display device are processed, a photolithography method can be used for the processing, for example. Alternatively, a nanoimprinting method, a sandblasting method, a lift-off method, or the like may be used for the processing of the thin films. An island-shaped thin film may be directly formed by a deposition method using a shielding mask such as a metal mask.

There are two typical methods in a photolithography method. In one of the methods, a resist mask is formed over a thin film that is to be processed, the thin film is processed by etching or the like, and the resist mask is removed. In the other method, a photosensitive thin film is deposited and then processed into a desired shape by light exposure and development.

For light used for light exposure in a photolithography method, for example, an i-line (with a wavelength of 365 nm), a g-line (with a wavelength of 436 nm), an h-line (with a wavelength of 405 nm), or light in which these lines are mixed can be used. For the light used for light exposure in a photolithography method, ultraviolet light, KrF laser light (with a wavelength of 248 nm), or ArF laser light (with a wavelength of 193 nm) may be used in addition to the above structure. Light exposure may be performed by liquid immersion exposure technique. For the light used for light exposure, extreme ultraviolet (EUV) light or X-rays may be used. Instead of the light used for light exposure, an electron beam can be used. Extreme ultraviolet light, X-rays, or an electron beam is preferably used, in which case extremely minute processing can be performed. Note that when light exposure is performed by scanning of abeam such as an electron beam, a photomask is not needed.

For etching of the thin films, a dry etching method, a wet etching method, a sandblasting method, or the like can be used.

First, as illustrated in FIG. 8A, the insulating layer 255a, the insulating layer 255b, and the insulating layer 255c are formed in this order over the layer 101 including transistors. Next, as illustrated in FIG. 8A, the pixel electrode 111a, the pixel electrode 111b, the pixel electrode 111c, and the conductive layer 123 are formed over the insulating layer 255c; an EL film 113A is formed over the pixel electrode 111a, the pixel electrode 111b, and the pixel electrode 111c; a mask film 118A is formed over the EL film 113A; and a mask film 119A is formed over the mask film 118A.

As illustrated in FIG. 8A, an end portion of the EL film 113A on the connection portion 140 side is positioned inward from an end portion of the mask film 118A in the cross-sectional view along Y1-Y2. For example, by using a mask for specifying a deposition area (also referred to as an area mask, a rough metal mask, or the like to be distinguished from a fine metal mask), the EL film 113A can be deposited in a region different from a region where the mask film 118A and the mask film 119A are deposited. In one embodiment of the present invention, the light-emitting element is formed using a resist mask; by using a combination of a resist mask and an area mask as described above, the light-emitting element can be fabricated in a relatively simple process.

The pixel electrode 111a, the pixel electrode 111b, and the pixel electrode 111c can be formed by a sputtering method or a vacuum evaporation method, for example.

The side surfaces of the pixel electrode 111a, the pixel electrode 111b, and the pixel electrode 111c each preferably have a tapered shape. This can improve the coverage with the layers formed over the pixel electrode 111a, the pixel electrode 111b, and the pixel electrode 111c and improve the manufacturing yield of the light-emitting elements.

The EL film 113A is a layer to be the EL layer 113a later and includes at least a film containing a light-emitting compound (a light-emitting film). The EL film 113A preferably includes a light-emitting film and a film functioning as a carrier-transport layer over the light-emitting film. Accordingly, the light-emitting film is inhibited from being exposed on the outermost surface during the manufacturing process of the display device, so that damage to the light-emitting film can be reduced. In this way, the reliability of the display device can be increased.

The EL film 113A may have a structure in which one or more of films functioning as a hole-injection layer, a hole-transport layer, a hole-blocking layer, an electron-blocking layer, an electron-transport layer, and an electron-injection layer are stacked. For example, the EL film 113A can have a structure in which a film functioning as a hole-injection layer, a film functioning as a hole-transport layer, the light-emitting film, and a film functioning as an electron-transport layer are stacked in this order. Alternatively, the EL film 113A can have a structure in which a film functioning as an electron-injection layer, a film functioning as an electron-transport layer, the light-emitting film, and a film functioning as a hole-transport layer are stacked in this order.

The EL film 113A can be formed by an evaporation method (including a vacuum evaporation method), a transfer method, a printing method, an inkjet method, a coating method, or the like. The EL film 113A is preferably formed by an evaporation method. A premix material may be used in the deposition by an evaporation method. Note that in this specification and the like, a premix material is a composite material in which a plurality of materials are combined or mixed in advance.

As each of the mask film 118A and the mask film 119A, a film that is highly resistant to the processing conditions for the EL film 113A and the EL film 113B, the EL film 113C, and the like that are formed in a later step, specifically, a film having high etching selectivity with the EL films is used.

The mask film 118A and the mask film 119A can be formed by a sputtering method, an ALD method (including a thermal ALD method or a PEALD method), a CVD method, or a vacuum evaporation method, for example. The mask film 118A, which is formed over and in contact with the EL layer, is preferably formed by a formation method that causes less damage to the EL layer than a formation method for the mask film 119A. For example, the mask film 118A is preferably formed by an ALD method or a vacuum evaporation method rather than a sputtering method. The mask film 118A and the mask film 119A are formed at a temperature lower than the upper temperature limit of the EL layer. The typical substrate temperatures in formation of the mask film 118A and the mask film 119A are each lower than or equal to 200° C., preferably lower than or equal to 150° C., further preferably lower than or equal to 120° C., still further preferably lower than or equal to 100° C., yet still further preferably lower than or equal to 80° C.

The mask film 118A and the mask film 119A are preferably films that can be removed by a wet etching method. Using a wet etching method can reduce damage to the EL film 113A in processing the mask film 118A and the mask film 119A, as compared to the case of using a dry etching method.

The mask film 118A is preferably a film having high etching selectivity with the mask film 119A.

In the method for fabricating the display device of one embodiment of the present invention, it is desirable that the layers (e.g., the hole-injection layer, the hole-transport layer, the light-emitting layer, and the electron-transport layer) included in the EL layer not be easily processed in the step of processing the mask layers, and that the mask layers not be easily processed in the steps of processing the layers included in the EL layer. In consideration of the above, the materials and a processing method for the mask layers and processing methods for the EL layer are desirably selected.

Although an example in which the mask film with a two-layer structure is formed is shown in this embodiment, the mask film may have a single-layer structure or a stacked-layer structure of three or more layers.

As the mask film 118A and the mask film 119A, it is preferable to use an inorganic film such as a metal film, an alloy film, a metal oxide film, a semiconductor film, or an inorganic insulating film, for example.

For the mask film 118A and the mask film 119A, it is preferable to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. The use of a metal material capable of blocking ultraviolet light for one or both of the mask film 118A and the mask film 119A is preferable, in which case the EL layer can be inhibited from being irradiated with ultraviolet light and deteriorating.

For the mask film 118A and the mask film 119A, a metal oxide such as In—Ga—Zn oxide can be used. As the mask film 118A or the mask film 119A, an In—Ga—Zn oxide film can be formed by a sputtering method, for example. Furthermore, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like can be used. Alternatively, for example, an indium tin oxide containing silicon can also be used.

In addition, in place of gallium described above, an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, magnesium, and the like) may be used. Specifically, M is preferably one or more kinds selected from gallium, aluminum, and yttrium.

As the mask film 118A and the mask film 119A, a variety of inorganic insulating films that can be used as the protective layer 131 can be used. In particular, an oxide insulating film is preferable because its adhesion to the EL layer is higher than that of a nitride insulating film. For example, an inorganic insulating material such as aluminum oxide, hafnium oxide, or silicon oxide can be used for the mask film 118A and the mask film 119A. As the mask film 118A or the mask film 119A, an aluminum oxide film can be formed by an ALD method, for example. The use of an ALD method is preferable, in which case damage to a base (in particular, the EL layer or the like) can be reduced.

For example, an inorganic insulating film (e.g., an aluminum oxide film) formed by an ALD method can be used as the mask film 118A, and an inorganic film (e.g., an In—Ga—Zn oxide film, an aluminum film, or a tungsten film) formed by a sputtering method can be used as the mask film 119A.

Note that the same inorganic insulating film can be used for both the mask film 118A and the insulating layer 125 that is to be formed later. For example, an aluminum oxide film formed by an ALD method can be used for both the mask film 118A and the insulating layer 125. Here, the same deposition conditions may be used for the mask film 118A and the insulating layer 125. For example, when the mask film 118A is deposited under conditions similar to those of the insulating layer 125, the mask film 118A can be an insulating layer having a high barrier property against at least one of water and oxygen. Note that without limited to the above, different deposition conditions may be used for the mask film 118A and the insulating layer 125.

A material dissolvable in a solvent that is chemically stable may be used for one or both of the mask film 118A and the mask film 119A. Specifically, a material that will be dissolved in water or alcohol can be suitably used. In depositing a film of such a material, it is preferable to apply the material dissolved in a solvent such as water or alcohol by a wet process and then perform heat treatment for evaporating the solvent. At this time, the heat treatment is preferably performed in a reduced-pressure atmosphere, in which case the solvent can be removed at a low temperature in a short time and thermal damage to the EL layer can be reduced accordingly.

The mask film 118A and the mask film 119A may be formed by a wet process such as spin coating, dipping, spray coating, ink-jetting, dispensing, screen printing, offset printing, doctor blade coating, slit coating, roll coating, curtain coating, or knife coating.

The mask film 118A and the mask film 119A may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin.

Next, a resist mask 190a is formed over the mask film 119A as illustrated in FIG. 8A. The resist mask can be formed by application of a photosensitive resin (photoresist), light exposure, and development.

The resist mask may be formed using either a positive resist material or a negative resist material.

The resist mask 190a is provided at a position overlapping with the pixel electrode 111a. One island-shaped pattern is preferably provided for one subpixel 110a as the resist mask 190a. Alternatively, one band-like pattern for a plurality of subpixels 110a aligned in one column (aligned in the Y direction in FIG. 1A) may be formed as the resist mask 190a.

Here, when the resist mask 190a is formed such that an end portion of the resist mask 190a is positioned outward from the end portion of the pixel electrode 111a, the end portion of the EL layer 113a to be formed later can be provided outward from the end portion of the pixel electrode 111a.

Note that the resist mask 190a is preferably provided also at a position overlapping with the connection portion 140. This can inhibit the conductive layer 123 from being damaged during the fabrication process of the display device.

Then, as illustrated in FIG. 8B, the mask film 119A is processed using the resist mask 190a, so that a mask layer 119a is formed. The mask layer 119a remains over the pixel electrode 111a and the conductive layer 123.

In the etching of the mask film 119A, an etching condition with high selectivity is preferably employed so that the mask film 118A is not processed by the etching. Since the EL film 113A is not exposed in processing the mask film 119A, the range of choices of the processing method is wider than that for processing the mask film 118A. Specifically, deterioration of the EL film 113A can be further inhibited even when a gas containing oxygen is used as an etching gas in processing the mask film 119A.

After that, the resist mask 190a is removed. The resist mask 190a can be removed by ashing using oxygen plasma or the like, for example. Alternatively, an oxygen gas and any of CF₄, C₄F₈, SF₆, CHF₃, Cl₂, H₂O, BCl₃, or a noble gas (also referred to as a rare gas) may be used.

As the noble gas, He can be used, for example. Alternatively, the resist mask 190a may be removed by wet etching. At this time, the mask film 118A is positioned on the outermost surface and the EL film 113A is not exposed; thus, the EL film 113A can be inhibited from being damaged in the step of removing the resist mask 190a. In addition, the range of choices of the method for removing the resist mask 190a can be widened.

Next, as illustrated in FIG. 8C, the mask film 118A is processed using the mask layer 119a as a mask (also referred to as a hard mask), so that the mask layer 118a is formed.

The mask film 118A and the mask film 119A can be processed by a wet etching method or a dry etching method. The mask film 118A and the mask film 119A are preferably processed by anisotropic etching.

Using a wet etching method can reduce damage to the EL film 113A in processing the mask film 118A and the mask film 119A, as compared to the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, a chemical solution containing a mixed solution thereof, or the like, for example.

In the case of using a dry etching method, deterioration of the EL film 113A can be inhibited by not using a gas containing oxygen as the etching gas. In the case of using a dry etching method, it is preferable to use a gas containing CF₄, C₄F₈, SF₆, CHF₃, Cl₂, H₂O, or BCl₃ or a noble gas as the etching gas, for example. For example, He is given as the noble gas.

For example, when an aluminum oxide film formed by an ALD method is used as the mask film 118A, the mask film 118A can be processed by a dry etching method using CHF₃ and He. In the case where an In—Ga—Zn oxide film formed by a sputtering method is used as the mask film 119A, the mask film 119A can be processed by a wet etching method using a diluted phosphoric acid. Alternatively, the mask film 119A may be processed by a dry etching method using CH₄ and Ar. Alternatively, the mask film 119A can be processed by a wet etching method using a diluted phosphoric acid. In the case where a tungsten film formed by a sputtering method is used as the mask film 119A, the mask film 119A can be processed by a dry etching method using a combination of CF₄ and O₂, using a combination of CF₆ and O₂, a combination of CF₄, Cl₂, and O₂, or a combination of CF₆, Cl₂, and O₂.

Next, as illustrated in FIG. 8C, the EL film 113A is processed by etching treatment using the mask layer 119a and the mask layer 118a as a hard mask, so that the EL layer 113a is formed. Here, when the side surface of the pixel electrode 11a has a tapered shape, the tapered portion 137a is formed in the EL layer 113a. The tapered portion 137a is formed between, for example, the side surface of the pixel electrode 11a and the mask layer 118a. As described above, the taper angle of the tapered portion 137a can be less than 90°.

Thus, as illustrated in FIG. 8C, a stacked-layer structure of the EL layer 113a, the mask layer 118a, and the mask layer 119a remains over the pixel electrode 111a. In the region corresponding to the connection portion 140, a stacked-layer structure of the mask layer 118a and the mask layer 119a remains over the conductive layer 123.

FIG. 8C illustrates an example where the end portion of the EL layer 113a is positioned outward from the end portion of the pixel electrode 111a. Such a structure can increase the aperture ratio of the pixel. Although not illustrated in FIG. 8C, a depressed portion is sometimes formed by the etching treatment in a region of the insulating layer 255c not overlapping with the EL layer 113a.

The EL layer 113a covers the top surface and the side surface of the pixel electrode 111a and thus, the subsequent steps can be performed without exposure of the pixel electrode 111a. When the end portion of the pixel electrode 111a is exposed, corrosion might occur in the etching step, for example. A product generated by corrosion of the pixel electrode 111a might be unstable; for example, the product might be dissolved in a solution in wet etching and might be diffused in an atmosphere in dry etching. The product dissolved in a solution or scattered in an atmosphere might be attached to a surface to be processed, the side surface of the EL layer 113a, and the like, which adversely affects the characteristics of the light-emitting element or forms a leakage path between the light-emitting element in some cases. In a region where the end portion of the pixel electrode 111a is exposed, adhesion between layers in contact with each other might be lowered, which might be likely to cause peeling of the EL layer 113a or the pixel electrode 111a.

Therefore, with the structure in which the EL layer 113a covers the top surface and the side surface of the pixel electrode 111a, for example, the yield of the light-emitting element can be improved and display quality of the light-emitting element can be improved.

Note that EL film 113A may be processed using the resist mask 190a. Then, the resist mask 190a may be removed.

The EL film 113A is preferably processed by anisotropic etching. In particular, an anisotropic dry etching is preferably used. Alternatively, a wet etching may be used.

In the case of using a dry etching method, deterioration of the EL film 113A can be inhibited by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Thus, damage to the EL film 113A can be suppressed. Furthermore, a defect such as attachment of a reaction product generated at the etching can be inhibited.

In the case of using a dry etching method, it is preferable to use a gas containing at least one of H₂, CF₄, C₄F₈, SF₆, CHF₃, Cl₂, H₂O, BCl₃, and a noble gas such as He and Ar as the etching gas, for example. Alternatively, a gas containing oxygen and at least one of the above is preferably used as the etching gas. Alternatively, an oxygen gas may be used as the etching gas. Specifically, for example, a gas containing H₂ and Ar or a gas containing CF₄ and He can be used as the etching gas. As another example, a gas containing CF₄, He, and oxygen can be used as the etching gas.

Through the above steps, regions of the EL film 113A, the mask film 118A, and the mask film 119A with which the resist mask 190a does not overlap can be removed.

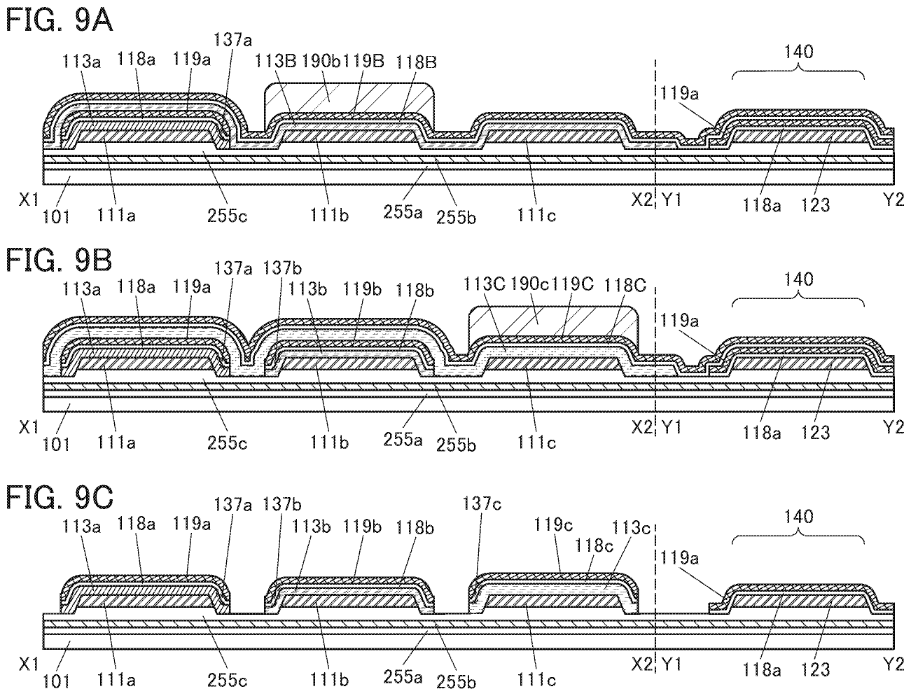

Next, as illustrated in FIG. 9A, the EL film 113B is formed over the mask layer 119a, the pixel electrode 111b, and the pixel electrode 111c; a mask film 118B is formed over the EL film 113B; and a mask film 119B is formed over the mask film 118B.

As illustrated in FIG. 9A, an end portion of the EL film 113B on the connection portion 140 side is positioned inward from an end portion of the mask film 118B in the cross-sectional view along Y1-Y2.

The EL film 113B is a layer to be the EL layer 113b later. The EL layer 113b emits light of a color different from that of light emitted by the EL layer 113a. Structures, materials, and the like that can be used for the EL layer 113b are similar to those of the EL layer 113a. The EL film 113B can be deposited by a method similar to that used for the EL film 113A.

The mask film 118B can be formed using the material that can be used for the mask film 118A. The mask film 119B can be formed using the material that can be used for the mask film 119A.

Next, a resist mask 190b is formed over the mask film 119B as illustrated in FIG. 9A.

The resist mask 190b is provided at a position overlapping with the pixel electrode 111b. The resist mask 190b may be provided also at a position overlapping with the region to be the connection portion 140.

Next, steps similar to those described with reference to FIG. 8B and FIG. 8C are performed to remove regions of the EL film 113B, the mask film 118B, and the mask film 119B with which the resist mask 190b does not overlap.

Accordingly, as illustrated in FIG. 9B, a stacked-layer structure of the EL layer 113b, the mask layer 118b, and the mask layer 119b remains over the pixel electrode 111b. In the region corresponding to the connection portion 140, the stacked-layer structure of the mask layer 118a and the mask layer 119a remains over the conductive layer 123. Here, when the side surface of the pixel electrode 111b has a tapered shape, the tapered portion 137b is formed in the EL layer 113b. The tapered portion 137b is formed between the side surface of the pixel electrode 111b and the mask layer 118b, for example. As described above, the taper angle of the tapered portion 137b can be less than 90°.

Next, as illustrated in FIG. 9B, the EL film 113C is formed over the mask layer 119a, the mask layer 119b, and the pixel electrode 111c, a mask film 118C is formed over the EL film 113C, and a mask film 119C is formed over the mask film 118C.

As illustrated in FIG. 9B, an end portion of the EL film 113C on the connection portion 140 side is positioned inward from an end portion of the mask film 118C in the cross-sectional view along Y1-Y2.

The EL film 113C is a layer to be the EL layer 113c later. The EL layer 113c emits light of a color different from those of light emitted by the EL layer 113a and the EL layer 113b.

Structures, materials, and the like that can be used for the EL layer 113c are similar to those of the EL layer 113a. The EL film 113C can be deposited by a method similar to that used for the EL film 113A.

The mask film 118C can be formed using the material that can be used for the mask film 118A. The mask film 119C can be formed using the material that can be used for the mask film 119A.

Next, a resist mask 190c is formed over the mask film 119C as illustrated in FIG. 9B.

The resist mask 190c is provided at a position overlapping with the pixel electrode 111c. The resist mask 190c may be provided also at a position overlapping with the region to be the connection portion 140 later.

Next, steps similar to those described with reference to FIG. 8B and FIG. 8C are performed to remove regions of the EL film 113C, the mask film 118C, and the mask film 119C with which the resist mask 190c does not overlap.

Accordingly, as illustrated in FIG. 9C, a stacked-layer structure of the EL layer 113c, the mask layer 118c, and the mask layer 119c remains over the pixel electrode 111c. In the region corresponding to the connection portion 140, the stacked-layer structure of the mask layer 118a and the mask layer 119a remains over the conductive layer 123. Here, when the side surface of the pixel electrode 111c has a tapered shape, a tapered portion 137c is formed in the EL layer 113c. The tapered portion 137c is formed between, for example, the side surface of the pixel electrode 111c and the mask layer 118b. The taper angle of the tapered portion 137c can be less than 90° as are the taper angle of the tapered portion 137a and the taper angle of the tapered portion 137b.

Note that the end portions of the side surfaces of the EL layer 113a, the EL layer 113b, and the EL layer 113c are preferably perpendicular or substantially perpendicular to their formation surfaces. For example, the angle between the formation surfaces and these side surfaces is preferably greater than or equal to 60° and less than or equal to 90°.

When the EL films are processed by a photolithography method as described above, the distance between the pixels can be shortened to less than or equal to 8 μm, less than or equal to 5 m, less than or equal to 3 μm, less than or equal to 2 μm, or less than or equal to 1 μm. Here, the distance between the pixels can be specified, for example, by a distance between opposite end portions of two adjacent layers among the EL layer 113a, EL layer 113b, and EL layer 113c. The distance between the pixels is shortened in this manner, whereby a display device with high resolution and a high aperture ratio can be provided.

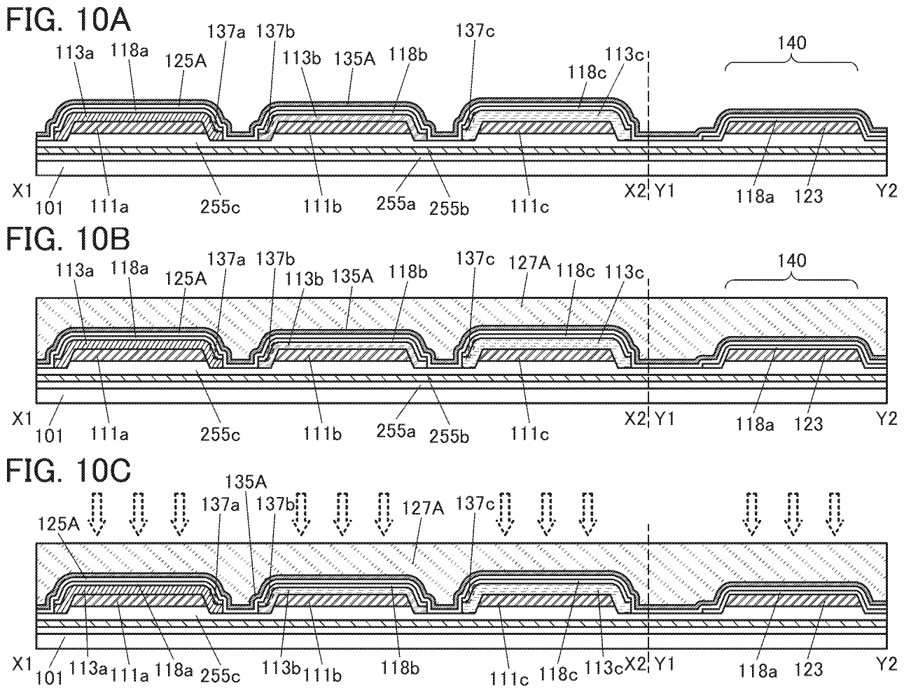

Subsequently, the mask layer 119a, the mask layer 119b, and the mask layer 119c are removed as illustrated in FIG. 10A. Accordingly, the mask layer 118a is exposed over the pixel electrode 111a, the mask layer 118b is exposed over the pixel electrode 111b, and the mask layer 118c is exposed over the pixel electrode 111c. The mask layer 118a is exposed over the conductive layer 123.

Note that a structure may be employed in which the formation step of an insulating film 125A is performed without removing the mask layer 119a, the mask layer 119b, and the mask layer 119c.

The step of removing the mask layers can be performed by a method similar to that for the step of processing the mask films. In particular, using a wet etching method can reduce damage to the EL layer 113a, the EL layer 113b, and the EL layer 113c in removing the mask layers, as compared to the case of using a dry etching method.

The mask layer may be removed by being dissolved in a solvent such as water or alcohol. Examples of alcohol include ethyl alcohol, methyl alcohol, isopropyl alcohol (IPA), and glycerin.

After the mask layers are removed, drying treatment may be performed to remove water included in the EL layer and water adsorbed on the surface of the EL layer. For example, heat treatment in an inert gas atmosphere or a reduced-pressure atmosphere can be performed. The heat treatment can be performed with a substrate temperature higher than or equal to 50° C. and lower than or equal to 200° C., preferably higher than or equal to 60° C. and lower than or equal to 150° C., further preferably higher than or equal to 70° C. and lower than or equal to 120° C. Employing a reduced-pressure atmosphere is preferable, in which case drying at a lower temperature is possible.

Next, as illustrated in FIG. 10A, the insulating film 125A is formed to cover the EL layer 113a, the EL layer 113b, and the EL layer 113c and the mask layer 118a, the mask layer 118b, and the mask layer 118c.

The insulating film 125A is a layer to be the insulating layer 125 later. Thus, the insulating film 125A can be formed using a material that can be used for the insulating layer 125. The thickness of the insulating film 125A is preferably greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125A, which is formed in contact with the side surface of the EL layer 113, is preferably deposited by a formation method that causes less damage to the EL layer 113. In addition, the insulating film 125A is formed at a temperature lower than the upper temperature limit of the EL layer 113. The typical substrate temperature in formation of the insulating film 125A is lower than or equal to 200° C., preferably lower than or equal to 180° C., further preferably lower than or equal to 160° C., still further preferably lower than or equal to 150° C., yet still further preferably lower than or equal to 140° C. Note that the steps after the formation of the insulating film 125A are also performed at temperatures lower than the upper temperature limit of the EL layer 113.

As the insulating film 125A, an inorganic insulating film can be formed by an ALD method, an evaporation method, a sputtering method, a CVD method, or a PLD method, for example. For example, an ALD method is preferably used for the formation of the insulating film 125A. The use of an ALD method is preferable, in which case damage by the deposition is reduced and a film with good coverage can be deposited. Here, the insulating film 125A can be deposited using a material and a method similar to those of the mask layer 118a, the mask layer 118b, and the mask layer 118c. In this case, a boundary between the insulating film 125A and the mask layer 118a, the mask layer 118b, and the mask layer 118c might be unclear.

Next, as illustrated in FIG. 10A, a light-blocking film 135A is formed over the insulating film 125A.

The light-blocking film 135A is a layer to be the light-blocking layer 135 later. Therefore, for the light-blocking film 135A, the material that can be used for the light-blocking layer 135 can be used; for example, silicon can be used. The thickness of the light-blocking film 135A is preferably greater than or equal to 3 nm or greater than or equal to 5 nm and less than or equal to 200 nm, less than or equal to 150 nm, less than or equal to 100 nm, less than or equal to 50 nm, or less than or equal to 10 nm. The light-blocking film 135A can be formed by a method similar to the method that can be used for forming the insulating film 125A.

Next, as illustrated in FIG. 10B, an insulating film 127A is formed over the light-blocking film 135A by a coating method.

The insulating film 127A is a film to be the insulating layer 127 in a later step, and the above organic material can be used for the insulating film 127A. As the organic material, a photosensitive organic resin is preferably used; for example, a photosensitive acrylic resin is used. The viscosity of the insulating film 127A is greater than or equal to 1 cP and less than or equal to 1500 cP, preferably greater than or equal to 1 cP and less than or equal to 12 cP. By setting the viscosity of the insulating film 127A in the above range, the insulating layer 127 having a tapered shape, which is illustrated in FIG. 3A, FIG. 5A, and the like, can be formed relatively easily.

There is no particular limitation on the method of forming the insulating film 127A, and, for example, the insulating film 127A can be formed by a wet process such as spin coating, dipping, spray coating, ink-jetting, dispensing, screen printing, offset printing, doctor blade coating, slit coating, roll coating, curtain coating, or knife coating. Specifically, the insulating film 127A is preferably formed by spin coating.

After the insulating film 127A is formed by a coating method, heat treatment is preferably performed. The heat treatment is performed at a temperature lower than the upper temperature limit of the EL layer. The substrate temperature at the time of the heat treatment is higher than or equal to 50° C. and lower than or equal to 200° C., preferably higher than or equal to 60° C. and lower than or equal to 150° C., further preferably higher than or equal to 70° C. and lower than or equal to 120° C. Accordingly, a solvent contained in the insulating film 127A can be removed.

Next, as illustrated in FIG. 10C, light exposure is performed on part of the insulating film 127A. For example, the part of the insulating film 127A is irradiated with ultraviolet light. The part of the insulating film 127A may be irradiated with visible light. The following description is made on the assumption that ultraviolet light is used for light exposure on the insulating film 127A and a layer formed from the insulating film 127A.

Here, in the case where a positive acrylic resin is used for the insulating film 127A, a region where the insulating layer 127 is not formed in a later step is irradiated with ultraviolet light using a mask. Since the insulating layer 127 is formed in a region interposed between any two of the pixel electrode 111a, the pixel electrode 111b, and the pixel electrode 111c, ultraviolet light irradiation is performed over the pixel electrode 111a, the pixel electrode 111b, and the pixel electrode 111c using a mask.

Although FIG. 10C illustrates an example where a positive photosensitive organic insulating film is used for the insulating film 127A and a region where the insulating layer 127 is not formed is irradiated with ultraviolet light, the present invention is not limited thereto. For example, a negative photosensitive organic insulating film may be used for the insulating film 127A. In this case, a region where the insulating layer 127 is formed is irradiated with ultraviolet light.

Here, in the case where the light-blocking film 135A is not provided, the EL layer 113 is sometimes irradiated with ultraviolet light at the time of light exposure on the insulating film 127A. This might damage the EL layer 113. Meanwhile, in the method for manufacturing the display device of one embodiment of the present invention, ultraviolet light is blocked by the light-blocking film 135A. Therefore, the EL layer 113 is inhibited from being irradiated with ultraviolet light and damaged at the time of light exposure on the insulating film 127A. Thus, a highly reliable display device can be manufactured.

In the case where the EL layer 113 is formed to include the tapered portion 137, the EL layer 113 is more easily irradiated with ultraviolet light at the time of light exposure on the insulating film 127A than in the case where the EL layer 113 is formed so that a portion corresponding to the tapered portion 137 is perpendicular in the cross-sectional view of the display device, for example. In view of the above, the light-blocking film 135A is provided, whereby the tapered portion 137 can also be inhibited from being irradiated with, for example, ultraviolet light and damage on the EL layer 113 can be inhibited. From the above, in the method for manufacturing the display device of one embodiment of the present invention, coverage of the pixel electrode 111 with the EL layer 113 can be increased and the EL layer 113 can be inhibited from being damaged. Thus, a highly reliable display device can be manufactured.

For example, the light-blocking film 135A has a function of absorbing or reflecting light with at least a certain wavelength in light with which the insulating film 127A is irradiated in the light exposure step on the insulating film 127A. For example, the transmittance of the light-blocking film 135A with respect to light with at least a certain wavelength in light with which the insulating film 127A is irradiated in the light exposure step on the insulating film 127A is less than or equal to 10%, preferably less than or equal to 1%, further preferably less than or equal to 0.1

The light-blocking film 135A is formed over the insulating film 125A that can be an inorganic insulating film, whereby the light-blocking film 135A can be prevented from being in contact with the EL layer 113. Therefore, the range of choices for the material of the light-blocking film 135A can be expanded more than that in the case where the insulating film 125A is not formed. For example, a material that might damage the EL layer 113 when in contact with the EL layer 113 can be used for the light-blocking film 135A. Furthermore, a method that might damage the EL layer 113 exposed at the time of formation of the light-blocking film 135A can be employed for the formation of the light-blocking film 135A. Moreover, a material having a conductive property such as metal can be used for the light-blocking film 135A. Note that in the case where the light-blocking film 135A is formed using an insulating material that does not damage the EL layer 113 even when in contact with the EL layer 113, the insulating film 125A is not necessarily formed.

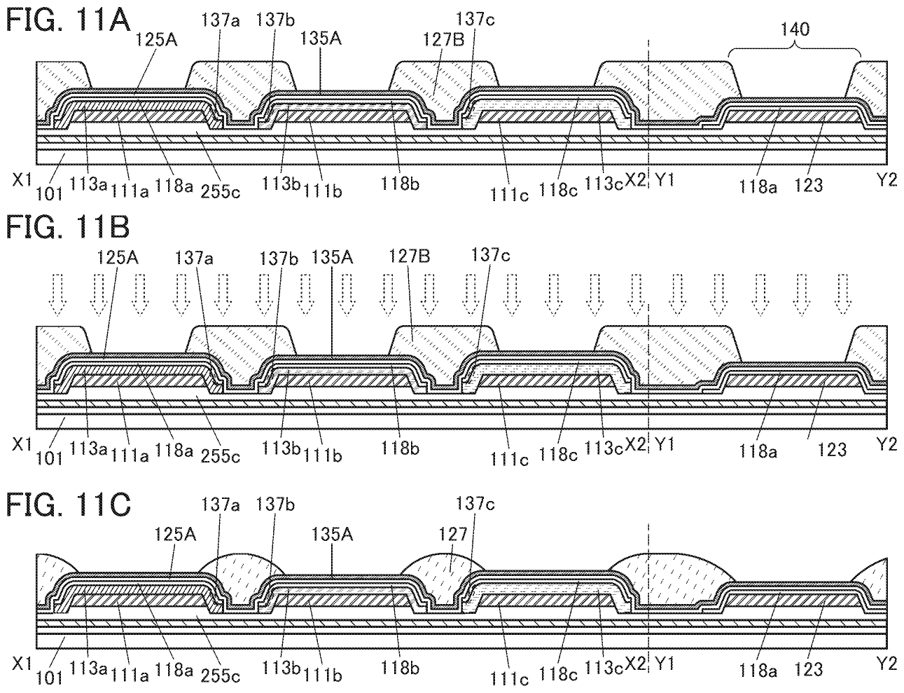

Next, as illustrated in FIG. 11A, development is performed to remove the exposed region of the insulating film 127A, so that an insulating layer 127B is formed. The insulating layer 127B is formed in a region interposed between any two of the pixel electrode 111a, the pixel electrode 111b, and the pixel electrode 111c. Here, in the case where an acrylic resin is used for the insulating film 127A, an alkaline solution is preferably used as a developer, and for example, a tetramethyl ammonium hydroxide (TMAH) solution is used.

Next, as illustrated in FIG. 11B, it is preferable that light exposure be performed on the entire substrate and the insulating layer 127B be irradiated with ultraviolet light. The energy density for the light exposure is greater than 0 mJ/cm² and less than or equal to 800 mJ/cm², preferably greater than 0 mJ/cm² and less than or equal to 500 mJ/cm². Performing such light exposure after the development can sometimes increase the degree of transparency of the insulating layer 127B. In addition, it is sometimes possible to lower the substrate temperature required for subsequent heat treatment for changing a side surface of the insulating layer 127B into a tapered shape. The provision of the light-blocking film 135A can inhibit, also in this step, the EL layer 113 from being irradiated with ultraviolet light and damaged.

Then, as illustrated in FIG. 11C, the heat treatment can change the insulating layer 127B into the insulating layer 127 with a tapered side surface. The heat treatment is performed at a temperature lower than the upper temperature limit of the EL layer. The substrate temperature at the time of the heat treatment is higher than or equal to 50° C. and lower than or equal to 200° C., preferably higher than or equal to 60° C. and lower than or equal to 150° C., further preferably higher than or equal to 70° C. and lower than or equal to 130° C. The substrate temperature in the heat treatment of this step is preferably higher than that in the heat treatment after the application of the insulating layer 127. Accordingly, adhesion between the insulating layer 127 and the insulating film 125A can be improved, and corrosion resistance of the insulating layer 127 can be increased.

As described above, in the cross-sectional view of the display device, the side surface of the insulating layer 127 preferably has a tapered shape with the taper angle θ1. The top surface of the insulating layer 127 preferably has a convex shape in a cross-sectional view of the display device.

Here, the insulating layer 127 is preferably reduced in size such that one end portion overlaps with the pixel electrode 111a and the other end portion overlaps with the pixel electrode 111b. Alternatively, the insulating layer 127 is preferably reduced in size such that one end portion overlaps with the pixel electrode 111b and the other end portion overlaps with the pixel electrode 111c. Alternatively, the insulating layer 127 is preferably reduced in size such that one end portion overlaps with the pixel electrode 111c and the other end portion overlaps with the pixel electrode 111a. With such a structure, the end portion of the insulating layer 127 can be formed over a substantially flat region of the EL layer 113a (the EL layer 113b). Therefore, the tapered shape of the insulating layer 127 is relatively easily formed by the above processing.

Note that in the case where the side surface of the insulating layer 127 can be processed into a tapered shape only by the heat treatment illustrated in FIG. 11C, a structure may be employed in which light exposure illustrated in FIG. 11B is not performed.

It is preferable that heat treatment be further performed after processing the side surface of the insulating layer 127 into a tapered shape. The heat treatment can remove water contained in the EL layer 113, water adsorbed onto the surface of the EL layer, and the like. For example, heat treatment in an inert gas atmosphere or a reduced-pressure atmosphere can be performed.

The heat treatment can be performed at a substrate temperature higher than or equal to 80° C. and lower than or equal to 230° C., preferably higher than or equal to 80° C. and lower than or equal to 200° C., further preferably higher than or equal to 80° C. and lower than or equal to 100° C. Employing a reduced-pressure atmosphere is preferable, in which case dehydration at a lower temperature is possible.

Etching may be performed so that the surface level of the insulating layer 127 is adjusted. The insulating layer 127 may be processed by ashing using oxygen plasma, for example.

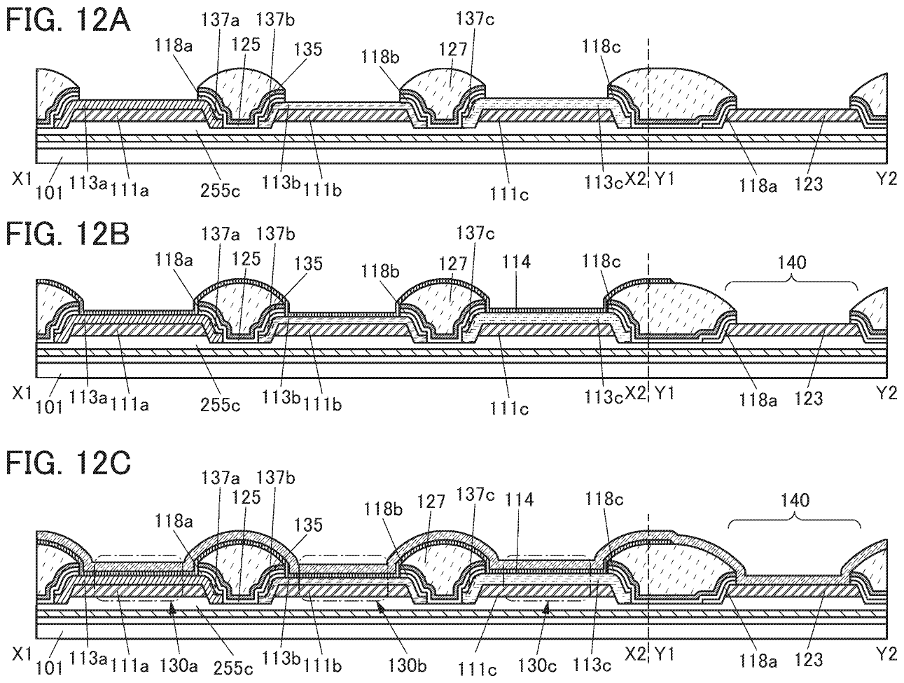

Next, as illustrated in FIG. 12A, the light-blocking film 135A and the insulating film 125A are processed. Furthermore, the mask layer 118a, the mask layer 118b, and the mask layer 118c are processed. Accordingly, the EL layer 113a, the EL layer 113b, the EL layer 113c, and the conductive layer 123 are exposed.

The light-blocking film 135A, the insulating film 125A, and the mask layer 118 can be processed in different steps, specifically with different conditions. For example, the insulating film 125A can be processed by an etching method after the light-blocking film 135A is processed by an etching method, and then the mask layer 118 can be processed by an etching method. For another example, after the light-blocking film 135A is processed by an etching method, the insulating film 125A and the mask layer 118 can be processed by an etching method. That is, the insulating film 125A and the mask layer 118 may be processed in the same step, specifically with the same condition. In the case where the mask layer 118 and the insulating film 125A are films that are formed using the same material, for example, they can be processed in the same step. Note that in the case where the light-blocking film 135A, the insulating film 125A, and the mask layer 118 can be processed with the same condition, for example, the light-blocking film 135A, the insulating film 125A, and the mask layer 118 can be processed in the same step.

The light-blocking film 135A can be processed by a dry etching method, for example. In this case, it is preferable to use a gas containing at least one of SF₆, CF₄, HBr, Cl₂, BCl₃, H₂, O₂, and a noble gas such as Ar and He as the etching gas, for example.

As illustrated in FIG. 12A, regions of the light-blocking film 135A and the insulating film 125A with which the insulating layer 127 overlaps remain as the light-blocking layer 135 and the insulating layer 125. Regions of the mask layer 118a, the mask layer 118b, and the mask layer 118c with which the insulating layer 127 overlaps remain.

For example, the insulating layer 125 is provided to cover the side surface and part of the top surface of each EL layer 113. This inhibits the side surface of the layer from being in contact with a film to be formed later, thereby inhibiting a short circuit in the light-emitting element. Furthermore, damage on the EL layer 113 in a later step can be inhibited.

The processing of the mask layer 118 can be performed by a method similar to the method that can be used for the processing of the mask layer 119. The processing of the insulating film 125A can be performed by a method similar to the method that can be used for the processing of the mask layer 118 or the mask layer 119.

Next, as illustrated in FIG. 12B, the common layer 114 is formed over the EL layer 113 and the insulating layer 127.

In FIG. 12B, the cross-sectional view along Y1-Y2 shows the example in which the common layer 114 is not provided in the connection portion 140. As illustrated in FIG. 12B, an end portion of the common layer 114 on the connection portion 140 side is preferably positioned inward from the connection portion 140. For example, a mask for specifying a deposition area (also referred to as an area mask, a rough metal mask, or the like) is preferably used to form the common layer 114.

Note that the common layer 114 may be provided in the connection portion 140 depending on the level of the conductivity of the common layer 114. With such a structure, the connection portion 140 having the structure illustrated in FIG. 2B2 can be formed in which the conductive layer 123 is electrically connected to the common electrode 115 through the common layer 114.

Materials that can be used for the common layer 114 are as described above. The common layer 114 can be formed by an evaporation method (including a vacuum evaporation method), a transfer method, a printing method, an inkjet method, a coating method, or the like. The common layer 114 may be formed using a premix material.

In the case where the common layer 114 has high conductivity, the light-emitting element might be short-circuited when the common layer 114 is in contact with the side surface of the pixel electrode 111 or the side surface of the EL layer 113. However, in the display device of one embodiment of the present invention, the insulating layer 125, the light-blocking layer 135, and the insulating layer 127 cover the side surface of the EL layer 113, and the EL layer 113 covers the side surface of the pixel electrode 111. This can inhibit the common layer 114 with high conductivity from being in contact with the side surfaces of these layers, and inhibit the light-emitting element from being short-circuited. As a result, the reliability of the light-emitting element can be increased.

Since the space between the EL layer 113a and the EL layer 113b and the space between the EL layer 113b and the EL layer 113c are filled with the insulating layer 125, the light-blocking layer 135, and the insulating layer 127, level difference in the formation surface of the common layer 114 is smaller and flatter than that in the case where the insulating layer 125, the light-blocking layer 135, and the insulating layer 127 are not provided. This can improve the coverage with the common layer 114.

After that, the common electrode 115 is formed over the common layer 114 and the conductive layer 123 as illustrated in FIG. 12C. Accordingly, the conductive layer 123 and the common electrode 115 are in direct contact with each other to be electrically connected to each other. With such a structure, the connection portion 140 having the structure illustrated in FIG. 2B2 can be formed in which a top surface of the conductive layer 123 is in contact with the common electrode 115.

A mask for specifying a deposition area (also referred to as an area mask, a rough metal mask, or the like) may be used in the formation of the common electrode 115. Alternatively, the common electrode 115 may be formed without the mask, and a film to be the common electrode 115 may be processed with, for example, a resist mask after the film to be the common electrode 115 is deposited.

Materials that can be used for the common electrode 115 are as described above. The common electrode 115 can be formed by a sputtering method or a vacuum evaporation method, for example. Alternatively, a film formed by an evaporation method and a film formed by a sputtering method may be stacked.

After that, the protective layer 131 is formed over the common electrode 115. Furthermore, the substrate 120 is bonded onto the protective layer 131 with the adhesive layer 122, whereby the display device 100 illustrated in FIG. 2A and FIG. 2B2 can be manufactured.

Materials and deposition methods that can be used for the protective layer 131 are as described above. Examples of the deposition methods of the protective layer 131 include a vacuum evaporation method, a sputtering method, a CVD method, and an ALD method. The protective layer 131 may have a single-layer structure or a stacked-layer structure.

In the display device of one embodiment of the present invention, each subpixel includes an island-shaped EL layer, which can inhibit generation of leakage current between the subpixels. As described above, the provision of a stacked structure body of an inorganic insulating layer and an organic insulating layer between light-emitting elements can prevent a disconnected portion and a locally thinned portion from being formed in a common layer and a common electrode over the stacked structure body. Thus, a connection defect caused by the disconnected portion and an increase in electric resistance caused by the locally thinned portion can be inhibited from occurring in the common layer and the common electrode. Consequently, the display device of one embodiment of the present invention can achieve both high resolution and high display quality.

### [Manufacturing Method Example_2 of Display Device]

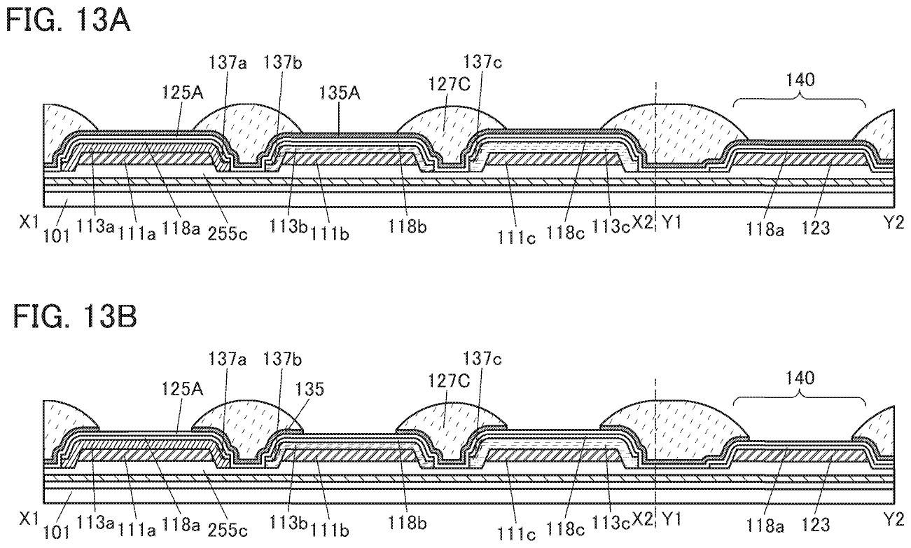

An example of a method for manufacturing the display device illustrated in FIG. 4A, FIG. 4B2, and the like is described with reference to FIG. 13A to FIG. 17B. FIG. 13A to FIG. 17B each illustrate a cross-sectional view along dashed-dotted line X1-X2 and a cross-sectional view along dashed-dotted line Y1-Y2 in FIG. 1 side by side. A process different from the process illustrated in FIG. 13A to FIG. 17B is mainly described below.

First, a process similar to that illustrated in FIG. 8A to FIG. 11C is performed. Accordingly, the structure illustrated in FIG. 13A is manufactured.

Next, as illustrated in FIG. 13B, etching treatment is performed using an insulating layer 127C as a mask to process the light-blocking film 135A. Thus, the light-blocking layer 135 is formed. As described above, the light-blocking film 135A can be processed by a dry etching method, for example.

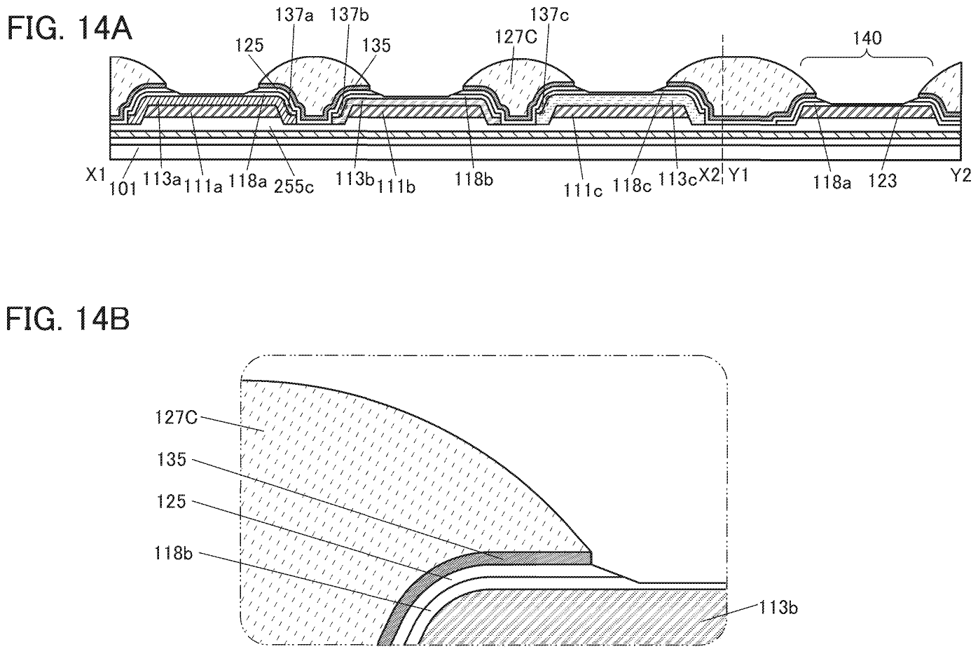

Next, as illustrated in FIG. 14A, etching treatment is performed with the insulating layer 127C as a mask to process the insulating film 125A and reduce the thickness of the mask layer 118a, the mask layer 118b, and the mask layer 118c. Thus, the insulating layer 125 is formed under the insulating layer 127C. FIG. 14B is an enlarged cross-sectional view of the vicinity of the EL layer 113b and the insulating layer 127C in FIG. 14A.

The etching treatment can be performed by dry etching or wet etching. The insulating film 125A is preferably deposited using a material and a method similar to those of the mask film 118A, the mask film 118B, and the mask film 118C, in which case removal of part of the insulating film 125A and reduction in the thickness of the mask film 118A, the mask film 118B, and the mask film 118C can be performed all at once by the etching treatment. In the case where the light-blocking film 135A, the insulating film 125A, and the mask layer 118 can be processed with the same etching condition, for example, the light-blocking film 135A, the insulating film 125A, and the mask layer 118 can be processed in the same step.

For example, by dry etching using the insulating layer 127C with a tapered side surface as a mask as illustrated in FIG. 14B, the side surface of the insulating layer 125 and upper end portions of the side surfaces of the mask layer 118a, the mask layer 118b, and the mask layer 118c can be made to have a tapered shape relatively easily.

In the case of performing dry etching, a chlorine-based gas is preferably used. As the chlorine-based gas, Cl₂, BCl₃, SiCl₄, CCl₄, or the like can be used alone or two or more of the gases can be mixed and used. Moreover, an oxygen gas, a hydrogen gas, a helium gas, an argon gas, or the like or a mixture of two or more of the gases can be added to the chlorine-based gas as appropriate. By the dry etching, the thin regions of the mask layer 118a, the mask layer 118b, and the mask layer 118c can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes.

In the case of performing dry etching, a by-product generated by the dry etching might be deposited on the top surface and the side surface of the insulating layer 127C, for example. Accordingly, a constituent of the etching gas, a constituent of the light-blocking film 135A, a constituent of the insulating film 125A, a constituent of the mask layer 118a, the mask layer 118b, and the mask layer 118c, and the like might be included in the insulating layer 127C.

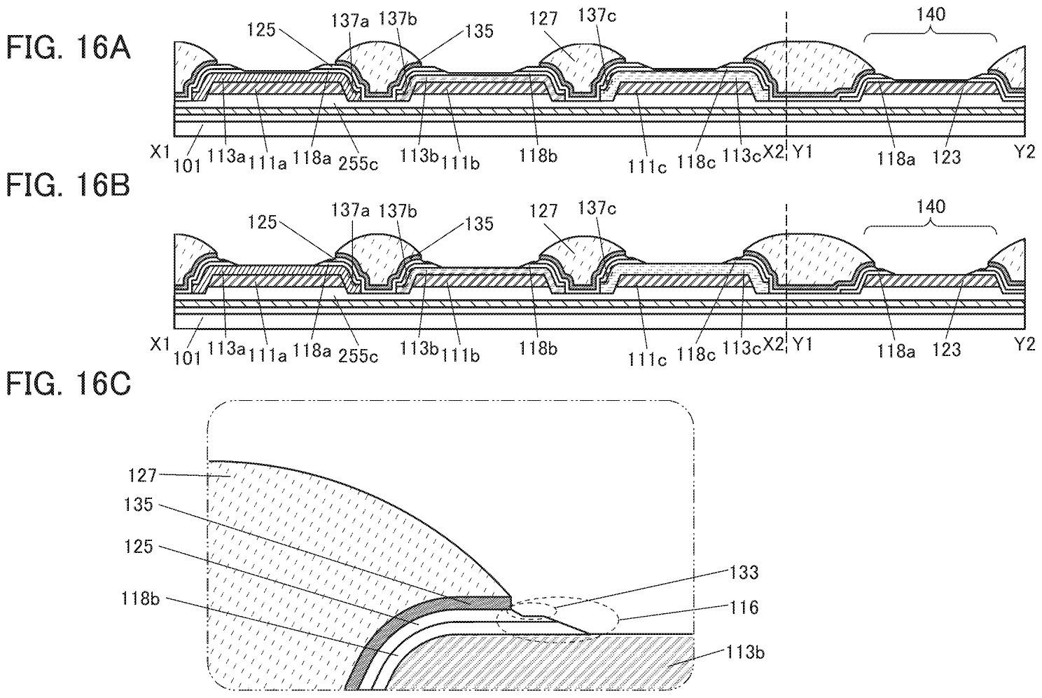

In the case where the etching treatment is performed by wet etching, for example, a method similar to wet etching of FIG. 16B described later can be used.

As illustrated in FIG. 14B, the mask layer 118a, the mask layer 118b, and the mask layer 118c are not removed completely by the etching treatment, and the etching treatment is stopped when the thickness of the mask layer 118a, the thickness of the mask layer 118b, and the thickness of the mask layer 118c is reduced. The corresponding mask layer 118a, the mask layer 118b, and the mask layer 118c are left over the EL layer 113a, the EL layer 113b, and the EL layer 113c in this manner, whereby the EL layer 113a, the EL layer 113b, and the EL layer 113c can be prevented from being damaged by processing in a later step.

Although the thickness of the mask layer 118a, the thickness of the mask layer 118b, and the thickness of the mask layer 118c is reduced in FIG. 14A, for example, the present invention is not limited thereto. For example, depending on the thickness of the mask layer 118a, the thickness of the mask layer 118b, and the thickness of the mask layer 118c, the etching treatment might be stopped before the insulating film 125A is processed into the insulating layer 125. In the case where the insulating film 125A is deposited using a material and a method similar to those of the mask layer 118a, the mask layer 118b, and the mask layer 118c, the boundary between the insulating film 125A and the mask layer 118a, the mask layer 118b, and the mask layer 118c is sometimes unclear, and formation of the insulating layer 125 cannot be determined in some cases.

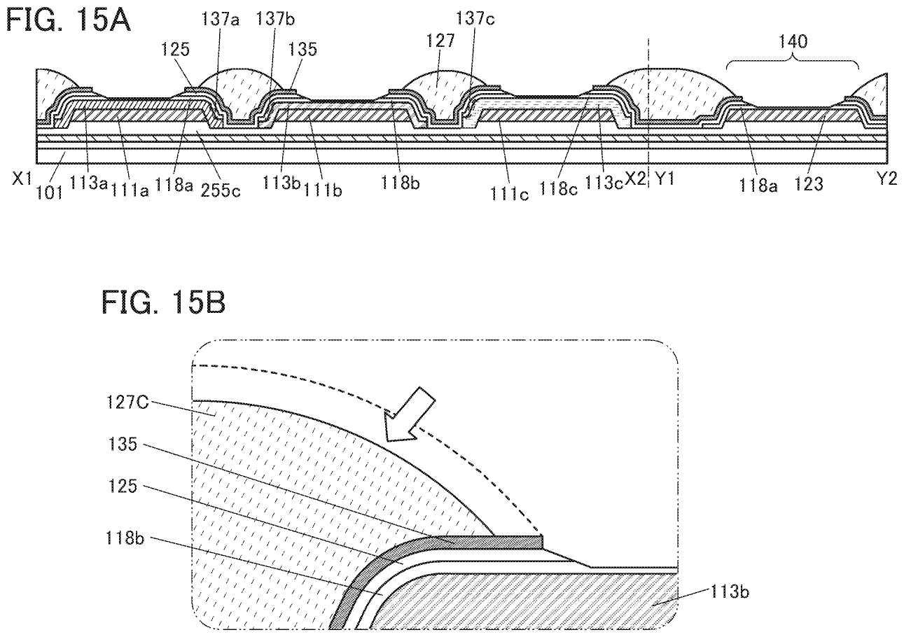

Next, as illustrated in FIG. 15A and FIG. 15B, the insulating layer 127C is reduced in size by plasma treatment to form the insulating layer 127. The plasma treatment can be performed with the dry etching apparatus. In this case, the plasma treatment is performed in an oxygen atmosphere without application of bias voltage. FIG. 15B is an enlarged cross-sectional view of the vicinity of the EL layer 113b and the insulating layer 127 in FIG. 15A.

As illustrated in FIG. 15B, by the plasma treatment, the end portion of the side surface of the insulating layer 127 recedes and a top surface of the light-blocking layer 135 is exposed. The insulating layer 125 is provided such that the light-blocking layer 135 whose top surface is exposed overlaps with the insulating layer 125. Thus, in etching of, for example, the insulating layer 125 performed in a later step, side etching can be inhibited from proceeding deeply below the insulating layer 127.

The insulating layer 127C is reduced in size by the plasma treatment, whereby the height of the insulating layer 127 can also be adjusted.

The insulating layer 127 is reduced in size with a shape substantially similar to the insulating layer 127C; therefore, the insulating layer 127 has the tapered-shaped side surface with the taper angle θ2 as illustrated in FIG. 5B and the convex top surface in the cross-sectional view of the display device. When the insulating layer 127 has such a shape, the common layer 114 and the common electrode 115 can be formed with good coverage over the whole insulating layer 127.

Next, as illustrated in FIG. 16A, etching treatment is performed using the insulating layer 127 as a mask to process the light-blocking film 135A, so that the light-blocking layer 135 is formed. The etching treatment can be performed with a condition similar to that of the processing of the light-blocking film 135A performed in the step illustrated in FIG. 13B, and an etching condition with high selectivity with the insulating layer 125 is preferably used. For example, a gas containing SF₆ can be used as an etching gas.

Next, as illustrated in FIG. 16B and FIG. 16C, etching treatment is performed using the insulating layer 127 as a mask to process the mask layer 118a, the mask layer 118b, the mask layer 118c, and insulating layer 125. Thus, openings are formed in the mask layer 118a, the mask layer 118b, and the mask layer 118c, and the top surfaces of the EL layer 113a, the EL layer 113b, the EL layer 113c, and the conductive layer 123 are exposed. FIG. 16C is an enlarged cross-sectional view of the vicinity of the EL layer 113b and the insulating layer 127 in FIG. 16B.

The etching treatment is preferably performed by wet etching. Using a wet etching method can reduce damage to the EL layer 113a, the EL layer 113b, and the EL layer 113c, as compared to the case of using a dry etching method. The wet etching can be performed using an alkaline solution, for example. When an alkaline solution is used, a tetramethyl ammonium hydroxide (TMAH) solution is preferably used. In that case, puddle wet etching can be performed. The insulating film 125A is preferably deposited using a material and a method similar to those of the mask film 118A, the mask film 118B, and the mask film 118C, in which case removal of part of the mask film 118A, part of the mask film 118B, part of the mask film 118C, and part of the insulating layer 125 can be performed all at once by the etching treatment. In the case where the light-blocking layer 135, the insulating layer 125, and the mask layer 118 can be processed with the same etching condition, for example, the light-blocking layer 135, the insulating layer 125, and the mask layer 118 can be processed in the same step.

As illustrated in FIG. 16C, for example, the protruding portion 116 is formed in the mask layer 118b and the insulating layer 125 and over the EL layer 113b and the pixel electrode 111b by the etching treatment. The protruding portion 116 is positioned outward from the insulating layer 127 in the cross-sectional view. Note that although not illustrated in the enlarged cross-sectional view, the protruding portion 116 is formed also over the EL layer 113a and the pixel electrode 111a, over the EL layer 113c and the pixel electrode 111c, and over the conductive layer 123.

As illustrated in FIG. 5B, the protruding portion 116 preferably has a tapered shape with the taper angle θ3 in the cross-sectional view of the display device. Such a forward tapered shape of the protruding portion 116 can prevent, for example, disconnection from being generated in the common layer 114 and the common electrode 115 that are provided over the protruding portion 116, and the EL layer 113 can be formed with good coverage.

As illustrated in FIG. 5B, the insulating layer 125 includes a portion thinner than the portion with which the insulating layer 127 overlaps, i.e., the depression portion 133 in the protruding portion 116.

By providing the insulating layer 127, the insulating layer 125, the mask layer 118a, the mask layer 118b, and the mask layer 118c in the above manner, a connection defect due to disconnection and an increase in electric resistance due to a locally thinned portion can be inhibited from occurring in the common layer 114 and the common electrode 115 between the light-emitting elements. Thus, the display device of one embodiment of the present invention can have high display quality.

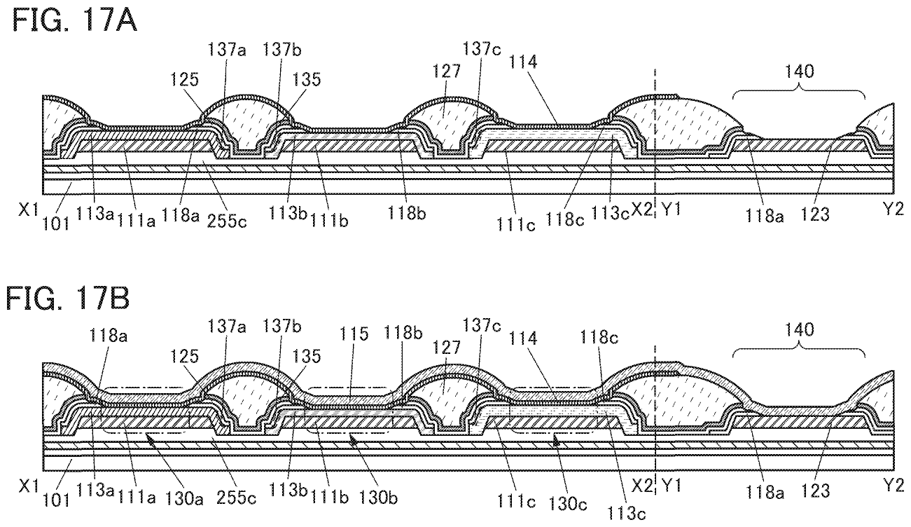

Next, as illustrated in FIG. 17A, the common layer 114 is formed over the EL layer 113 and the insulating layer 127. The common layer 114 can be formed in a manner similar to that illustrated in FIG. 12B.

In FIG. 17A, the cross-sectional view along Y1-Y2 shows the example where the common layer 114 is not provided in the connection portion 140. As described above, the end portion of the common layer 114 on the connection portion 140 side is preferably positioned inward from the connection portion 140.

Depending on the level of the conductivity of the common layer 114, the common layer 114 may be provided in the connection portion 140. With such a structure, the connection portion 140 having the structure illustrated in FIG. 4B1 can be formed in which the conductive layer 123 is electrically connected to the common electrode 115 through the common layer 114.

After that, the common electrode 115 is formed over the common layer 114 and over the conductive layer 123 as illustrated in FIG. 17B. Accordingly, the conductive layer 123 and the common electrode 115 are in direct contact with each other to be electrically connected to each other. With such a structure, the connection portion 140 having the structure illustrated in FIG. 4B2 can be formed in which the top surface of the conductive layer 123 is in contact with the common electrode 115. The common electrode 115 can be formed in a manner similar to that illustrated in FIG. 12C.

After that, the protective layer 131 is formed over the common electrode 115. Furthermore, the substrate 120 is bonded onto the protective layer 131 with the adhesive layer 122, whereby the display device 100 with the structure illustrated in FIG. 4A and FIG. 4B2 can be manufactured.

### [Pixel Layout]

Pixel layouts different from the layout in FIG. 1 will be mainly described below. There is no particular limitation on the arrangement of light-emitting elements (subpixels), and a variety of methods can be employed.

Examples of the top surface shape of the subpixel include polygons such as a triangle, a tetragon (including a rectangle and a square), and a pentagon; polygons with rounded corners; an ellipse; and a circle. Here, the top surface shape of the subpixel corresponds to the top surface shape of a light-emitting region of the light-emitting element.

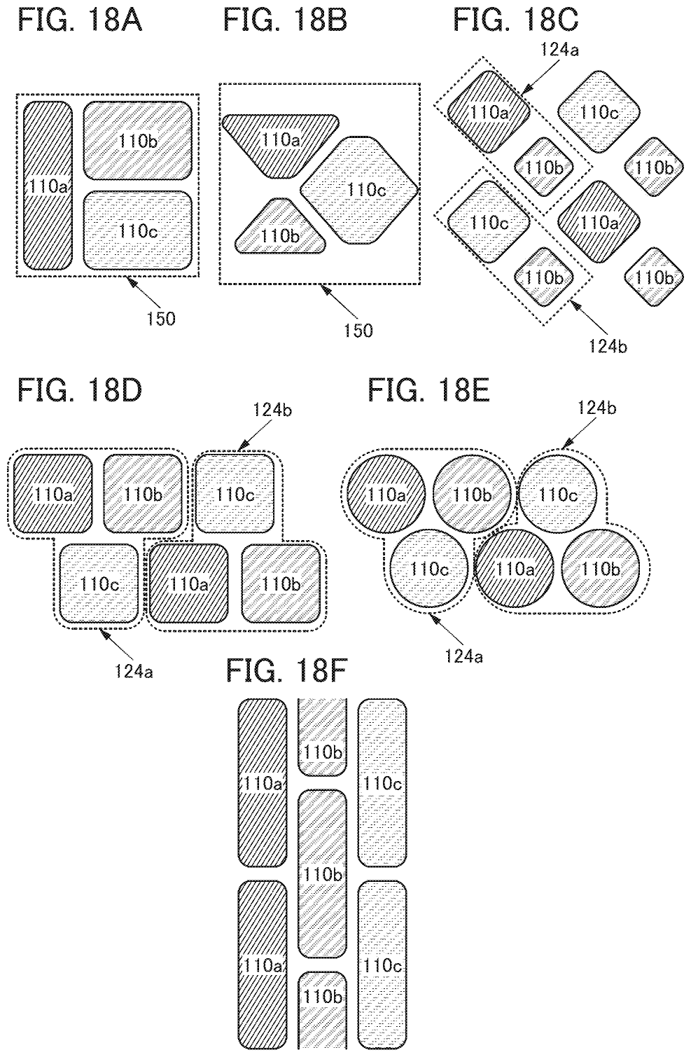

A pixel 150 illustrated in FIG. 18A employs S-stripe arrangement. The pixel 150 illustrated in FIG. 18A consists of the subpixel 110a, the subpixel 110b, and the subpixel 110c. For example, the subpixel 110a can exhibit blue, the subpixel 110b can exhibit red, and the subpixel 110c can exhibit green.

The pixel 150 illustrated in FIG. 18B includes the subpixel 110a whose top surface has a rough trapezoidal shape with rounded corners, the subpixel 110b whose top surface has a rough triangle shape with rounded corners, and the subpixel 110c whose top surface has a rough tetragonal or rough hexagonal shape with rounded corners. The subpixel 110a has a larger light-emitting area than the subpixel 110b. In this manner, the shapes and sizes of the subpixels can be determined independently. For example, the size of a subpixel including a light-emitting element with higher reliability can be smaller. For example, the subpixel 110a can exhibit green, the subpixel 110b can exhibit red, and the subpixel 110c can exhibit blue.

A pixel 124a and a pixel 124b illustrated in FIG. 18C employ PenTile arrangement. FIG. 18C illustrates an example in which the pixels 124a including the subpixels 110a and the subpixels 110b and the pixels 124b including the subpixels 110b and the subpixels 110c are alternately arranged. For example, the subpixel 110a can exhibit red, the subpixel 110b can exhibit green, and the subpixel 110c can exhibit blue.

The pixel 124a and the pixel 124b illustrated in FIG. 18D and FIG. 18E employ delta arrangement. The pixel 124a includes two subpixels 110 (the subpixel 110a and the subpixel 110b) in the upper row (first row) and one subpixel 110 (the subpixel 110c) in the lower row (second row). The pixel 124b includes one subpixel 110 (the subpixel 110c) in the upper row (first row) and two subpixels 110 (the subpixel 110a and the subpixel 110b) in the lower row (second row). For example, the subpixel 110a can exhibit red, the subpixel 110b can exhibit green, and the subpixel 110c can exhibit blue.

FIG. 18D illustrates an example in which the top surface of each subpixel has a rough tetragonal shape with rounded corners, and FIG. 18E illustrates an example in which the top surface of each subpixel is circular.

FIG. 18F illustrates an example in which subpixels 110 of different colors are arranged in a zigzag manner. Specifically, the positions of the top sides of two subpixels 110 arranged in the column direction (e.g., the subpixel 110a and the subpixel 110b or the subpixel 110b and the subpixel 110c) are not aligned in the top view. For example, the subpixel 110a can exhibit red, the subpixel 110b can exhibit green, and the subpixel 110c can exhibit blue.

In a photolithography method, as a pattern to be formed by processing becomes finer, the influence of light diffraction becomes more difficult to ignore; accordingly, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a light-emitting element might have a polygonal shape with rounded corners, an elliptical shape, a circular shape, or the like.

Furthermore, in the method of manufacturing the display device of one embodiment of the present invention, the EL layer is processed into an island shape with the use of a resist mask. A resist film formed over the EL layer needs to be cured at a temperature lower than the upper temperature limit of the EL layer. Thus, the resist film is insufficiently cured in some cases depending on the upper temperature limit of the material of the EL layer and the curing temperature of the resist material. An insufficiently cured resist film may have a shape different from a desired shape by processing. As a result, the top surface of the EL layer may have a polygonal shape with rounded corners, an elliptical shape, a circular shape, or the like. For example, when a resist mask with a square top surface is intended to be formed, a resist mask with a circular top surface may be formed, and the top surface of the EL layer may be circular.

Note that to obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion of a figure on a mask pattern, for example.

The above is the description of the pixel layouts.

At least part of this embodiment can be implemented in appropriate combination with the other embodiments described in this specification.

### Embodiment 2

In this embodiment, a display device of one embodiment of the present invention is described with reference to the drawings.

The display device in this embodiment can be a high-resolution display device. For example, the display device of one embodiment of the present invention can be used for display portions of information terminals (wearable devices) such as watch-type and bracelet-type information terminals and display portions of wearable devices capable of being worn on the head, such as a VR device like a head-mounted display and a glasses-type AR device.

### [Display Module]

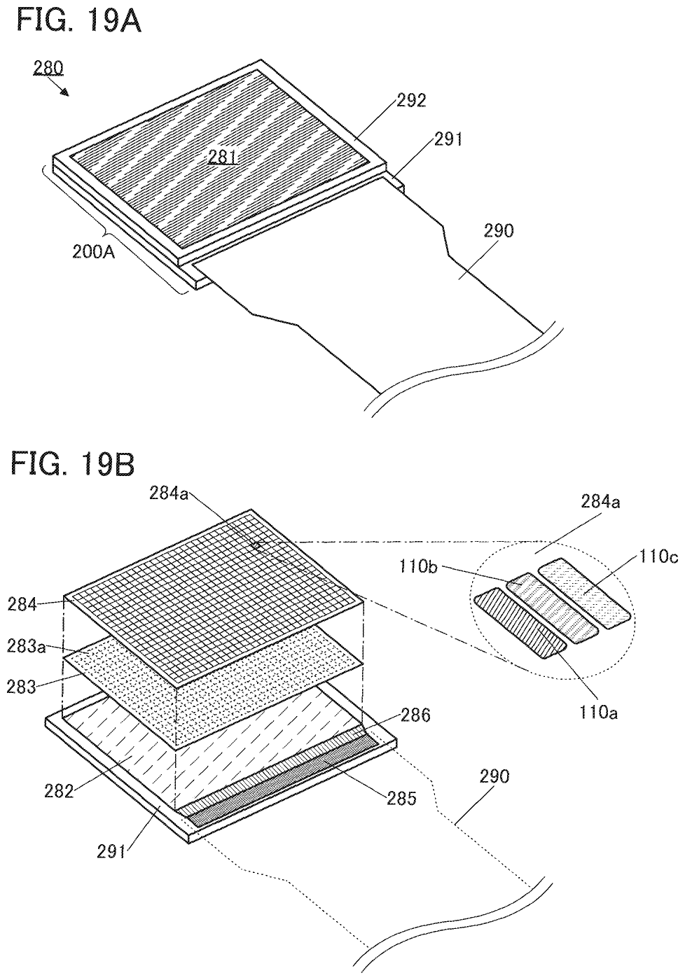

FIG. 19A is a perspective view of a display module 280. The display module 280 includes a display device 200A and an FPC 290. Note that the display device included in the display module 280 is not limited to the display device 200A and may be any of a display device 200B to a display device 200F described later.

The display module 280 includes a substrate 291 and a substrate 292. The display module 280 includes a display portion 281. The display portion 281 is a region where an image is displayed.

FIG. 19B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 with which the pixel portion 284 does not overlap. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 19B. The pixel 284a includes the subpixel 110a exhibiting red, the subpixel 110b exhibiting green, and the subpixel 110c exhibiting blue, for example.

The pixel circuit portion 283 includes a plurality of pixel circuits 283a arranged periodically. One pixel circuit 283a is a circuit that controls light emission of three light-emitting elements included in one pixel 284a. One pixel circuit 283a may be provided with three circuits each of which controls light emission of one light-emitting element. For example, the pixel circuit 283a can include at least one selection transistor, one current control transistor (driving transistor), and a capacitor for one light-emitting element. In this case, a gate signal is input to a gate of the selection transistor, and a video signal is input to one of a source and a drain of the selection transistor. With such a structure, an active-matrix display device is achieved.

The circuit portion 282 includes a circuit for driving the pixel circuits 283a in the pixel circuit portion 283. For example, one or both of a gate line driver circuit and a signal line driver circuit are preferably included. The circuit portion 282 may also include at least one of an arithmetic circuit, a memory circuit, a power supply circuit, and the like. A transistor included in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal, a power supply potential, and the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

Such a display module 280 has extremely high resolution, and thus can be suitably used for a VR device such as a head-mounted display or a glasses-type AR device. For example, even with a structure in which the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be suitably used in a display portion of a wearable electronic device such as a wrist watch.

### [Display Device 200A]

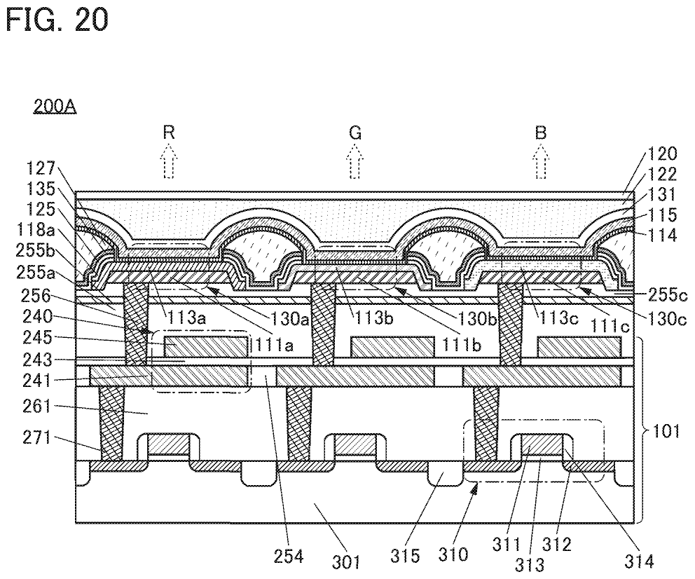

The display device 200A illustrated in FIG. 20 includes a substrate 301, the light-emitting element 130a, the light-emitting element 130b, the light-emitting element 130c, a capacitor 240, and a transistor 310.

The substrate 301 corresponds to the substrate 291 illustrated in FIG. 19A and FIG. 19B.

The transistor 310 includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance regions 312 are regions where the substrate 301 is doped with an impurity, and function as a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layer 241 and the conductive layer 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

The insulating layer 255a is provided to cover the capacitor 240, the insulating layer 255b is provided over the insulating layer 255a, and the insulating layer 255c is provided over the insulating layer 255b.

The light-emitting element 130a, the light-emitting element 130b, and the light-emitting element 130c are provided over the insulating layer 255c. Embodiment 1 can be referred to for the structures of the light-emitting element 130a, the light-emitting element 130b, and the light-emitting element 130c.

In the display device 200A, since the light-emitting elements 130 of different colors are separately formed, the difference between the chromaticity at low luminance emission and that at high luminance emission is small. Furthermore, since the EL layer 113a, the EL layer 113b, and the EL layer 113c are separated from each other, crosstalk generated between adjacent subpixels can be prevented while the display device has high resolution. Accordingly, the display device can have high resolution and high display quality.

Between the adjacent light-emitting elements 130, the mask layer 118, the insulating layer 125, the light-blocking layer 135, and the insulating layer 127 are provided.

The pixel electrode 11a, the pixel electrode 111b, and the pixel electrode 111c of the light-emitting element 130 are each electrically connected to one of the source and the drain of the transistor 310 through a plug 256 embedded in the insulating layer 243, the insulating layer 255a, the insulating layer 255b, and the insulating layer 255c, the conductive layer 241 embedded in the insulating layer 254, and the plug 271 embedded in the insulating layer 261. The top surface of the insulating layer 255c and the top surface of the plug 256 are level with or substantially level with each other. A variety of conductive materials can be used for the plugs.

The protective layer 131 is provided over the light-emitting element 130. The substrate 120 is bonded to the protective layer 131 with the adhesive layer 122.

An insulating layer covering an end portion of the top surface of the pixel electrode 111 is not provided between two adjacent pixel electrodes 111. Thus, the distance between adjacent light-emitting elements 130 can be extremely small. Accordingly, the display device can have high resolution or high definition.

### [Display Device 200B]

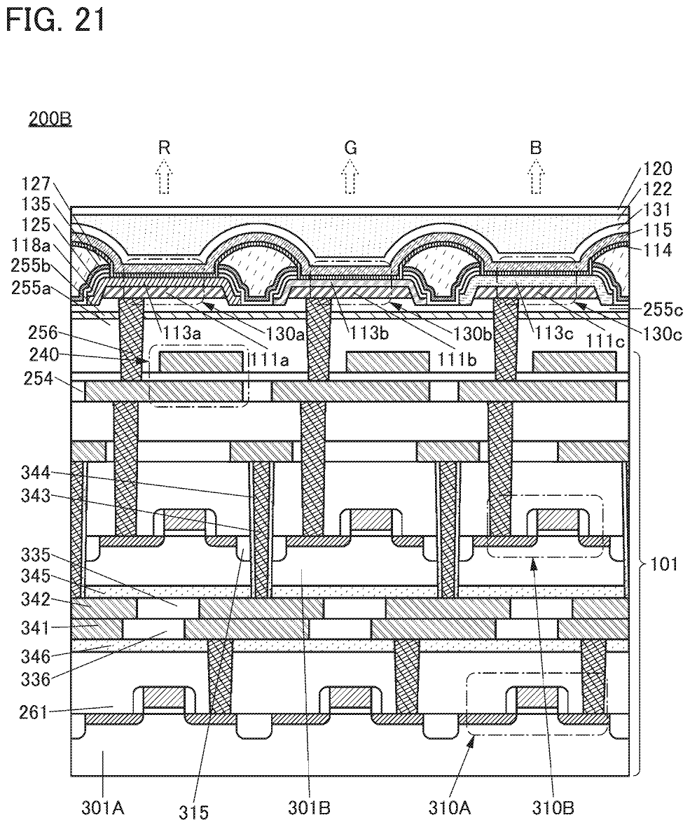

The display device 200B illustrated in FIG. 21 has a structure where a transistor 310A and a transistor 310B in each of which a channel is formed in a semiconductor substrate are stacked. Note that in the description of the display device below, portions similar to those of the above-mentioned display device are not described in some cases.

In the display device 200B, a substrate 301B provided with the transistor 310B, the capacitor 240, and light-emitting elements 130 is bonded to a substrate 301A provided with the transistor 310A.

Here, an insulating layer 345 is provided on a bottom surface of the substrate 301B. An insulating layer 346 is provided over the insulating layer 261 over the substrate 301A. The insulating layer 345 and the insulating layer 346 function as protective layers and can inhibit diffusion of impurities into the substrate 301B and the substrate 301A. As the insulating layer 345 and the insulating layer 346, an inorganic insulating film that can be used as the protective layer 131 can be used.

The substrate 301B is provided with a plug 343 that penetrates the substrate 301B and the insulating layer 345. Here, an insulating layer 344 functioning as a protective layer is preferably provided to cover a side surface of the plug 343.

A conductive layer 342 is provided under the insulating layer 345 on the rear surface of the substrate 301B. The conductive layer 342 is embedded in an insulating layer 335. Bottom surfaces of the conductive layer 342 and the insulating layer 335 are planarized. The conductive layer 342 is electrically connected to the plug 343.

A conductive layer 341 is provided over the insulating layer 346 between the substrate 301A and the substrate 301B. The conductive layer 341 is embedded in an insulating layer 336. Top surfaces of the conductive layer 341 and the insulating layer 336 are planarized.

The conductive layer 341 and the conductive layer 342 are preferably formed using the same conductive material. For example, a metal film containing an element selected from Al, Cr, Cu, Ta, Ti, Mo, and W, a metal nitride film containing the above element as a component (a titanium nitride film, a molybdenum nitride film, or a tungsten nitride film), or the like can be used. Copper is particularly preferably used for the conductive layer 341 and the conductive layer 342. In that case, it is possible to employ a Cu-to-Cu (copper-to-copper) direct bonding technique (a technique for achieving electrical continuity by connecting Cu (copper) pads).

### [Display Device 200C]

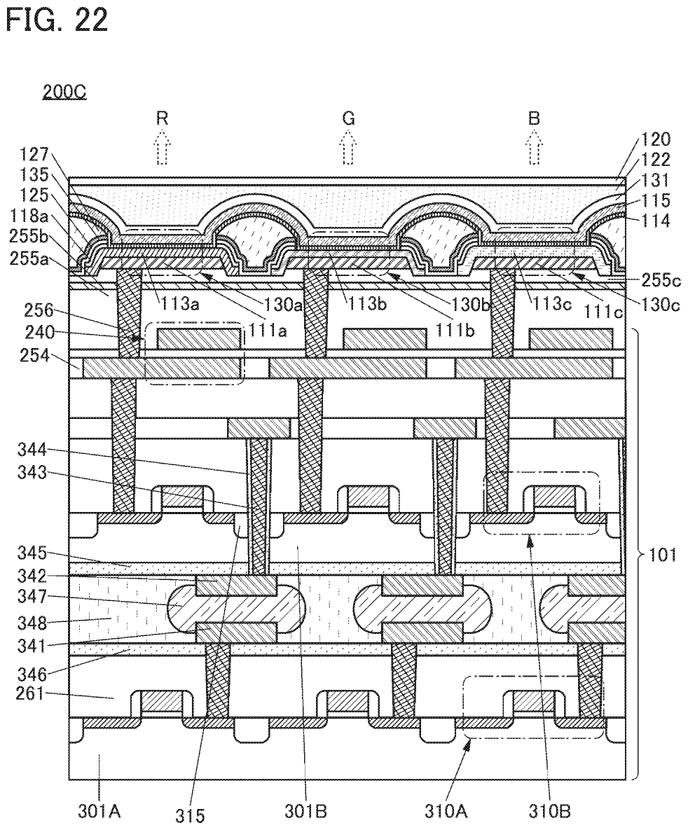

The display device 200C illustrated in FIG. 22 has a structure where the conductive layer 341 and the conductive layer 342 are bonded to each other through a bump 347.

As illustrated in FIG. 22, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layer 345 and the insulating layer 346. In the case where the bump 347 is provided, the insulating layer 335 and the insulating layer 336 may be omitted.

### [Display Device 200D]

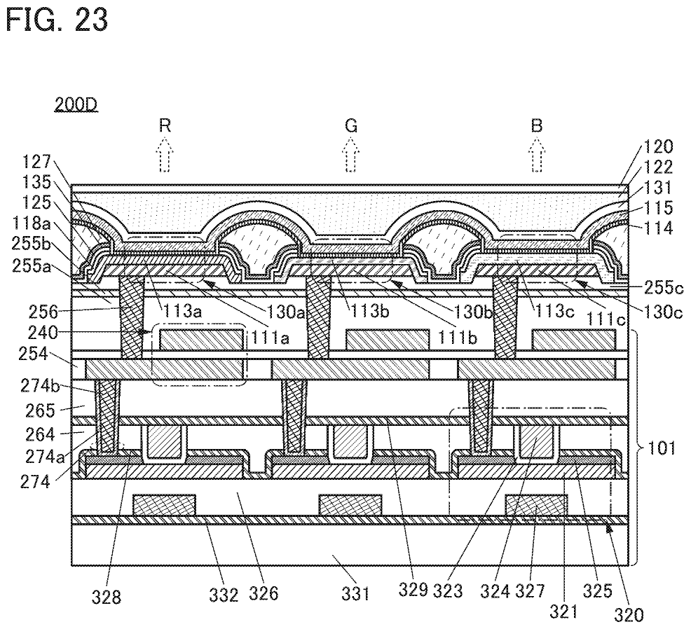

The display device 200D illustrated in FIG. 23 differs from the display device 200A mainly in a structure of a transistor.

A transistor 320 is a transistor that contains a metal oxide (also referred to as an oxide semiconductor) in a semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 19A and FIG. 19B.

An insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. For the insulating layer 332, for example, a film in which hydrogen or oxygen is less likely to diffuse than in a silicon oxide film, such as an aluminum oxide film, a hafnium oxide film, or a silicon nitride film, can be used

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. A metal oxide film exhibiting semiconductor characteristics is preferably used as the semiconductor layer 321. The pair of conductive layers 325 is provided on and in contact with the semiconductor layer 321, and functions as a source electrode and a drain electrode.

An insulating layer 328 is provided to cover top and side surfaces of the pair of conductive layers 325, a side surface of the semiconductor layer 321, and the like, and an insulating layer 264 is provided over the insulating layer 328. The insulating layer 328 functions as a barrier layer that prevents diffusion of impurities such as water or hydrogen from, for example, the insulating layer 264 into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the top surface of the semiconductor layer 321 and the conductive layer 324 are embedded in the opening portion. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are level or substantially level with each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water or hydrogen from, for example, the insulating layer 265 and the like into the transistor 320. As the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, the insulating layer 264, and the insulating layer 328. Here, the plug 274 preferably includes a conductive layer 274a that covers the side surfaces of openings formed in the insulating layer 265, the insulating layer 329, the insulating layer 264, and the insulating layer 328 and part of the top surface of the conductive layer 325, and a conductive layer 274b in contact with the top surface of the conductive layer 274a. For the conductive layer 274a, a conductive material in which hydrogen and oxygen are less likely to diffuse is preferably used.

### [Display Device 200E]

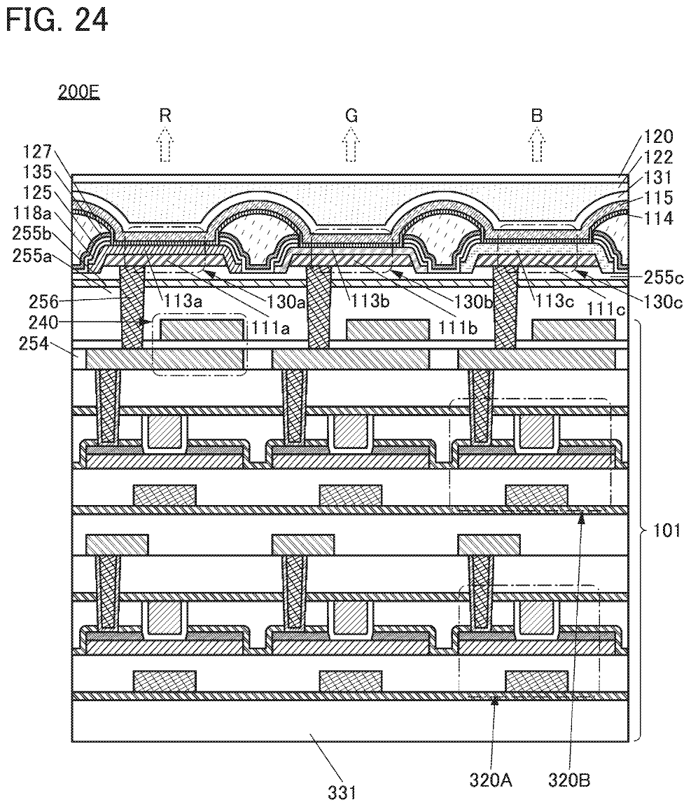

The display device 200E illustrated in FIG. 24 has a structure in which a transistor 320A and a transistor 320B each including an oxide semiconductor in a semiconductor where a channel is formed are stacked.

The description of the display device 200D can be referred to for the transistor 320A, the transistor 320B, and the components around them.

Although the structure where two transistors including an oxide semiconductor are stacked is described, the present invention is not limited thereto. For example, three or more transistors may be stacked.

### [Display Device 200F]

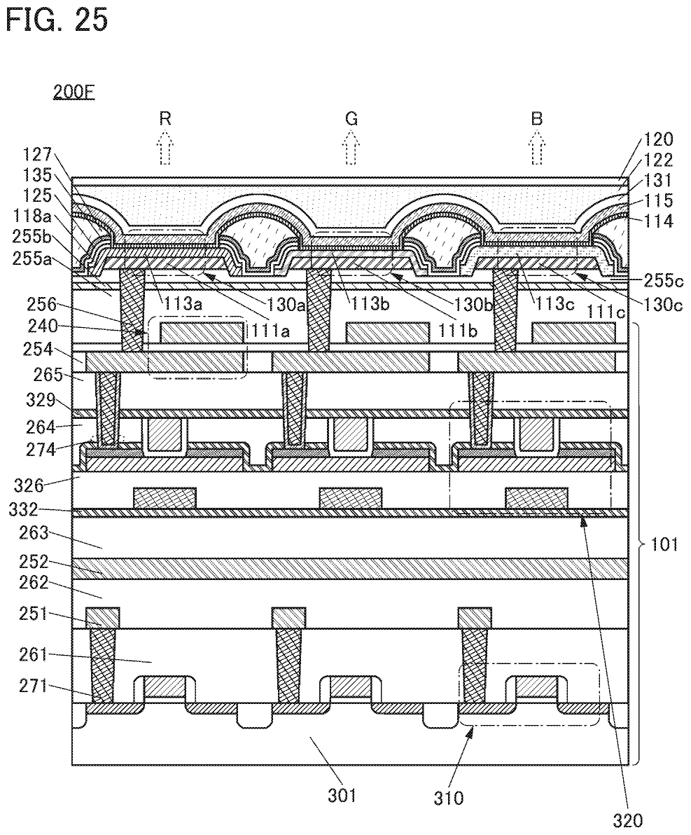

The display device 200F illustrated in FIG. 25 has a structure in which the transistor 310 having a channel formed in the substrate 301 and the transistor 320 including a metal oxide in a semiconductor layer where a channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. In addition, the transistor 310 can be used as a transistor included in a pixel circuit or a transistor included in a driver circuit for driving the pixel circuit (a gate line driver circuit or a signal line driver circuit). Furthermore, the transistor 310 and the transistor 320 can be used as transistors included in a variety of circuits such as an arithmetic circuit and a memory circuit.

With such a structure, not only the pixel circuit but also, for example, the driver circuit can be formed directly under the light-emitting element 130; thus, the display device can be downsized as compared with the case where the driver circuit is provided around a display region.

At least part of this embodiment can be implemented in appropriate combination with the other embodiments described in this specification.

### Embodiment 3

In this embodiment, structure examples of a display device of one embodiment of the present invention are described.

Accordingly, the display device of this embodiment can be used for display portions of electronic devices such as a digital camera, a digital video camera, a digital photo frame, a mobile phone, a portable game console, a smart phone, a wristwatch terminal, a tablet terminal, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

### [Display Device 400]

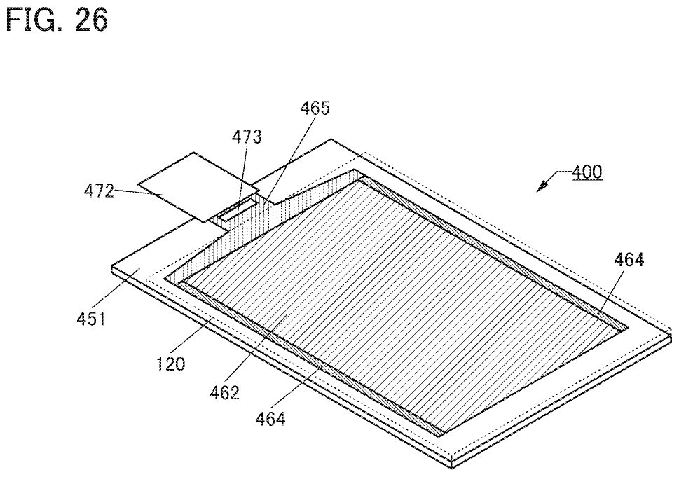

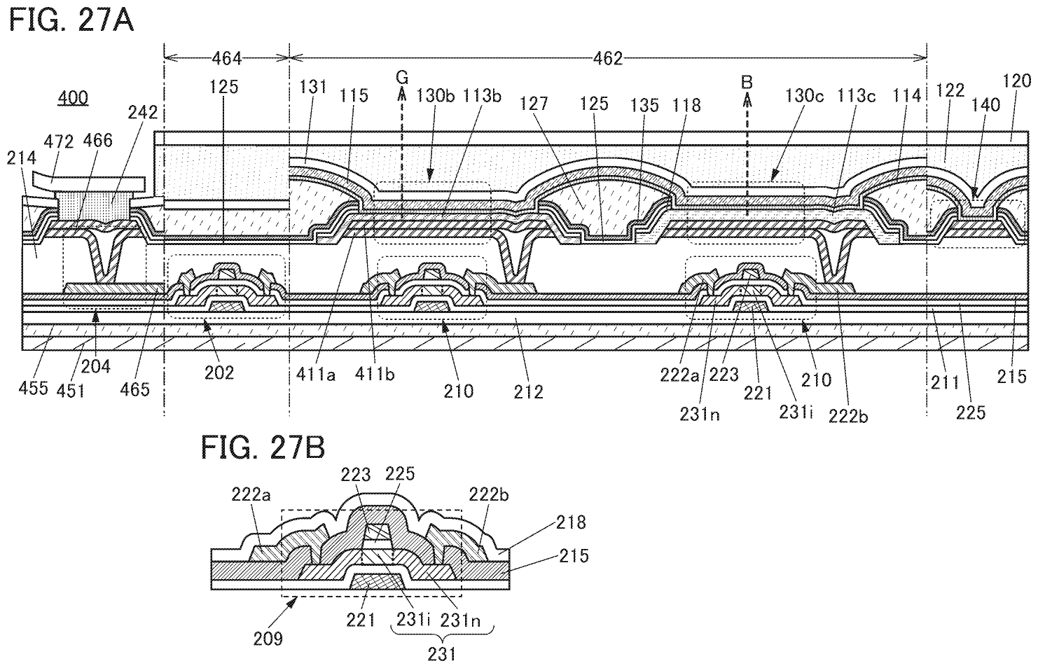

FIG. 26 is a perspective view of a display device 400, and FIG. 27A is a cross-sectional view of the display device 400.

The display device 400 has a structure in which a substrate 120 and a substrate 451 are bonded to each other. In FIG. 26, the substrate 120 is denoted by a dashed line.

The display device 400 includes a display portion 462, a circuit 464, a wiring 465, and the like. FIG. 26 illustrates an example in which an IC 473 and an FPC 472 are integrated on the display device 400. As described above, a display device in which a substrate is equipped with a connector such as an FPC or mounted with an IC is referred to as a display module. Thus, the structure illustrated in FIG. 26 can be regarded as a display module including the display device 400, the IC (integrated circuit), and the FPC.

As the circuit 464, a scan line driver circuit can be used, for example.

The wiring 465 has a function of supplying a signal and power to the display portion 462 and the circuit 464. The signal and electric power are input to the wiring 465 from the outside through the FPC 472 or input to the wiring 465 from the IC 473.

FIG. 26 illustrates an example in which the IC 473 is provided over the substrate 451 by a COG method, a COF (Chip On Film) method, or the like. An IC including a scan line driver circuit, a signal line driver circuit, or the like can be used as the IC 473, for example. Note that the display device 400 and the display module are not necessarily provided with an IC. The IC may be mounted on the FPC by a COF method or the like.

FIG. 27A illustrates an example of cross sections of part of a region including the FPC 472, part of the circuit 464, part of the display portion 462, and part of a region including the connection portion 140 of the display device 400. FIG. 27A specifically illustrates an example of a cross section of a region including, for example, the light-emitting element 130b that emits green light and the light-emitting element 130c that emits blue light in the display portion 462.

The display device 400 illustrated in FIG. 27A includes a transistor 202, a transistor 210, the light-emitting element 130b, the light-emitting element 130c, and the like between the substrate 451 and the substrate 120. Note that the display device 400 includes, for example, the light-emitting element 130a in addition to components illustrated in FIG. 27A.

The light-emitting element described in Embodiment 1 as an example can be used as the light-emitting element 130.

Here, in the case where a pixel of the display device includes three kinds of subpixels including light-emitting elements that emit light of different colors, as the three subpixels, subpixels of three colors of red (R), green (G), and blue (B), subpixels of three colors of yellow (Y), cyan (C), and magenta (M), and the like can be given. In the case where four subpixels are included, the four subpixels can be of four colors of R, G, B, and white (W) or of four colors of R, G, B, and Y, for example.

The substrate 120 and the protective layer 131 are bonded to each other with the adhesive layer 122. The adhesive layer 122 is provided to overlap with the light-emitting element 130, and the display device 400 employs a solid sealing structure.

The light-emitting element 130 includes a conductive layer 411a and a conductive layer 411b as pixel electrodes. The conductive layer 411b can have a property of reflecting visible light and can function as a reflective electrode.

The conductive layer 411a is connected to a conductive layer 222b included in the transistor 210 through an opening provided in an insulating layer 214. The transistor 210 has a function of controlling driving of the light-emitting element 130.

The EL layer 113 is provided to cover the pixel electrode. The mask layer 118 is provided to cover part of the top surface of the EL layer 113, and the insulating layer 125 is provided to cover the top surface of the mask layer 118 and the side surface of the EL layer 113. The light-blocking layer 135 is provided over the insulating layer 125, and the insulating layer 127 is provided over the light-blocking layer 135. The insulating layer 127 is provided to fill the depressed portion of the light-blocking layer 135. The common layer 114 is provided over the EL layer 113 and the insulating layer 127. Furthermore, the common electrode 115 is provided over the common layer 114, and the protective layer 131 is provided over the common electrode 115.

Light from the light-emitting element 130 is emitted toward the substrate 120 side. For the substrate 120, a material having a high visible-light-transmitting property is preferably used.

The transistor 202 and the transistor 210 are formed over the substrate 451. These transistors can be formed using the same material in the same step.

The substrate 451 and an insulating layer 212 are bonded to each other with an adhesive layer 455.

In a manufacturing method of the display device 400, first, a formation substrate provided with the insulating layer 212, the transistors, the light-emitting elements, and the like is bonded to the substrate 120 with the adhesive layer 122. Then, the substrate 451 is attached to a surface exposed by separation of the formation substrate, whereby the components formed over the formation substrate are transferred onto the substrate 451. The substrate 451 and the substrate 120 preferably have flexibility. This can increase the flexibility of the display device 400.

The inorganic insulating film that can be used as the insulating layer 211 and the insulating layer 215 can be used as the insulating layer 212.

A connection portion 204 is provided in a region of the substrate 451 that does not overlap with the substrate 120. In the connection portion 204, the wiring 465 is electrically connected to the FPC 472 through a conductive layer 466 and a connection layer 242. The conductive layer 466 can be obtained by processing the same conductive film as the pixel electrode. Thus, the connection portion 204 and the FPC 472 can be electrically connected to each other through the connection layer 242.

Each of the transistor 202 and the transistor 210 includes a conductive layer 221 functioning as a gate, an insulating layer 211 functioning as a gate insulating layer, a semiconductor layer 231 including a channel formation region 231i and a pair of low-resistance regions 231n, a conductive layer 222a connected to one of the pair of low-resistance regions 231n, the conductive layer 222b connected to the other of the pair of low-resistance regions 231n, an insulating layer 225 functioning as a gate insulating layer, a conductive layer 223 functioning as a gate, and an insulating layer 215 covering the conductive layer 223. The insulating layer 211 is positioned between the conductive layer 221 and the channel formation region 231i. The insulating layer 225 is positioned between the conductive layer 223 and the channel formation region 231i.

The conductive layer 222a and the conductive layer 222b are connected to the low-resistance regions 231n through openings provided in the insulating layer 215. One of the conductive layer 222a and the conductive layer 222b functions as a source, and the other functions as a drain.

FIG. 27A illustrates an example in which the insulating layer 225 covers a top surface and a side surface of the semiconductor layer. The conductive layer 222a and the conductive layer 222b are connected to the corresponding low-resistance regions 231n through openings provided in the insulating layer 225 and the insulating layer 215.

Meanwhile, in a transistor 209 illustrated in FIG. 27B, the insulating layer 225 overlaps with the channel formation region 231i of the semiconductor layer 231 and does not overlap with the low-resistance regions 231n. The structure illustrated in FIG. 27B can be manufactured by processing the insulating layer 225 using the conductive layer 223 as a mask, for example. In FIG. 27B, the insulating layer 215 is provided to cover the insulating layer 225 and the conductive layer 223, and the conductive layer 222a and the conductive layer 222b are connected to the low-resistance regions 231n through the openings in the insulating layer 215. Furthermore, an insulating layer 218 covering the transistor may be provided.

There is no particular limitation on the structure of the transistors included in the display device of this embodiment. For example, a planar transistor, a staggered transistor, an inverted staggered transistor, or the like can be used. In addition, the transistor structure may be either a top-gate structure or a bottom-gate structure. Alternatively, gates may be provided above and below a semiconductor layer in which a channel is formed.

The structure in which the semiconductor layer where a channel is formed is sandwiched between two gates is used for the transistor 202 and the transistor 210. The two gates may be connected to each other and supplied with the same signal to operate the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the semiconductor layer of the transistor, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

It is preferable that a semiconductor layer of a transistor contain a metal oxide. That is, a transistor including a metal oxide in its channel formation region (hereinafter, also referred to as an OS transistor) is preferably used for the display device of this embodiment.

The band gap of a metal oxide used for the semiconductor layer of the transistor is preferably 2 eV or more, further preferably 2.5 eV or more. With the use of a metal oxide having a wide bandgap, the off-state current of the OS transistor can be reduced.

A metal oxide contains preferably at least indium or zinc and further preferably indium and zinc. The metal oxide preferably contains indium, M (M is one or more of gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example.

Alternatively, the semiconductor layer of the transistor may contain silicon. Examples of silicon include amorphous silicon and crystalline silicon (e.g., low-temperature polysilicon and single crystal silicon). In particular, a transistor containing low-temperature polysilicon (LTPS) in a semiconductor layer (such a transistor is referred to as an LTPS transistor below) can be used. The LTPS transistor has high field-effect mobility and excellent frequency characteristics.

With use of the Si transistor such as the LTPS transistor, a circuit required to drive at a high frequency (e.g., a source driver circuit) can be formed on the same substrate as the display portion. This allows simplification of an external circuit mounted on the display device and a reduction in costs of parts and mounting costs.

The OS transistor has much higher field-effect mobility than a transistor containing amorphous silicon. In addition, the OS transistor has an extremely low leakage current between a source and a drain in an off state (hereinafter, also referred to as an off-state current), and electric charge accumulated in a capacitor that is connected in series to the transistor can be held for a long period. Furthermore, the power consumption of the display device can be reduced with the OS transistor.

The off-state current value per micrometer of channel width of an OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current per micrometer of channel width of a Si transistor at room temperature is higher than or equal to 1 fA (1×10⁻¹⁵ A) and lower than or equal to 1 pA (1×10⁻¹² A). That is, the off-state current of the OS transistor is lower than the off-state current of the Si transistor by approximately 10 digits.

To increase the emission luminance of the light-emitting element included in the pixel circuit, the amount of current fed through the light-emitting element needs to be increased. For this, it is necessary to increase the source-drain voltage of a driving transistor included in the pixel circuit. Since the OS transistor has a higher withstand voltage between the source and the drain than a Si transistor, a high voltage can be applied between the source and the drain of the OS transistor. Therefore, when an OS transistor is used as the driving transistor in the pixel circuit, the amount of current flowing through the light-emitting element can be increased, so that the emission luminance of the light-emitting element can be increased.

When transistors operate in a saturation region, a change in source-drain current relative to a change in gate-source voltage can be smaller in an OS transistor than in a Si transistor. Accordingly, when an OS transistor is used as the driving transistor in the pixel circuit, the amount of current flowing between the source and the drain can be set minutely by a change in gate-source voltage; hence, the amount of current flowing through the light-emitting element can be controlled. Accordingly, the number of gray levels in the pixel circuit can be increased.

Regarding saturation characteristics of current flowing when transistors operate in a saturation region, even in the case where the source-drain voltage of an OS transistor increases gradually, more stable constant current (saturation current) can be fed through the OS transistor than through a Si transistor. Thus, by using an OS transistor as the driving transistor, a stable current can be fed through a light-emitting element even when the current-voltage characteristics of an EL element vary, for example. In other words, when the OS transistor operates in the saturation region, the source-drain current hardly changes with an increase in the source-drain voltage; hence, the emission luminance of the light-emitting element can be stable.

As described above, with use of an OS transistor as the driving transistor included in the pixel circuit, it is possible to achieve “inhibition of black floating”, “increase in emission luminance”, “increase in gray level”, “inhibition of variation in characteristics of light-emitting devices”, and the like.

The transistor included in the circuit 464 and the transistor included in the display portion 462 may have the same structure or different structures. A plurality of transistors included in the circuit 464 may have the same structure or two or more kinds of structures. Similarly, a plurality of transistors included in the display portion 462 may have the same structure or two or more kinds of structures.

All of the transistors included in the display portion 462 may be OS transistors or Si transistors. Alternatively, some of the transistors included in the display portion 462 may be OS transistors and the others may be Si transistors.

For example, when both the LTPS transistor and the OS transistor are used in the display portion 462, the display device can have low power consumption and high drive capability. Note that a structure in which the LTPS transistor and the OS transistor are combined is referred to as LTPO in some cases. As a more preferable example, it is preferable to use an OS transistor as a transistor functioning as a switch for controlling electrical continuity between wirings and an LTPS transistor as a transistor for controlling current.

For example, one transistor included in the display portion 462 may function as a transistor for controlling current flowing through the light-emitting element and be also referred to as a driving transistor. One of a source and a drain of the driving transistor is electrically connected to the pixel electrode of the light-emitting element. The LTPS transistor is preferably used as the driving transistor. In this case, the amount of current flowing through the light-emitting element can be increased in the pixel circuit.

In contrast, another transistor included in the display portion 462 may function as a switch for controlling selection or non-selection of a pixel and can also be referred to as a selection transistor. A gate of the selection transistor is electrically connected to a gate line, and one of a source and a drain thereof is electrically connected to a signal line. The OS transistor is preferably used as the selection transistor. Thus, the gray level of the pixel can be maintained even when the frame frequency is extremely reduced (e.g., 1 fps or lower), whereby power consumption can be reduced by stopping the driver in displaying a still image.

As described above, the display device of one embodiment of the present invention can have all of a high aperture ratio, high resolution, high display quality, and low power consumption.

The display device of one embodiment of the present invention has a structure including an OS transistor and the light-emitting element having the MIL (metal mask less) structure. With this structure, the leakage current that might flow through the transistor and the leakage current that might flow between adjacent light-emitting elements (also referred to as a lateral leakage current, a side leakage current, or the like) can become extremely low. With this structure, a viewer can notice any one or more of the image crispness, the image sharpness, a high chroma, and a high contrast ratio in an image displayed on the display device. With the structure where the leakage current that might flow through the transistor and the lateral leakage current between light-emitting elements are extremely low, display with little leakage of light at the time of black display can be achieved, for example.

The structure of the transistors used in the display device may be selected as appropriate depending on the size of the screen of the display device. For example, single crystal Si transistors can be used in the display device with a screen diagonal greater than or equal to 0.1 inches and less than or equal to 3 inches. In addition, LTPS transistors can be used in the display device with a screen diagonal greater than or equal to 0.1 inches and less than or equal to 30 inches, preferably greater than or equal to 1 inch and less than or equal to 30 inches. Furthermore, LTPO (a structure in which an LTPS transistor and an OS transistor are combined) can be used in the display device with a screen diagonal greater than or equal to 0.1 inches and less than or equal to 50 inches, preferably greater than or equal to 1 inch and less than or equal to 50 inches. In addition, OS transistors can be used in the display device with a screen diagonal greater than or equal to 0.1 inches and less than or equal to 200 inches, preferably greater than or equal to 50 inches and less than or equal to 100 inches.

Note that with single crystal Si transistors, a size increase is extremely difficult because of the size of a single crystal Si substrate. Furthermore, since a laser crystallization apparatus is used in the manufacturing process, LTPS transistors are unlikely to respond to a size increase (typically to a screen diagonal size greater than 30 inches). By contrast, since the manufacturing process does not necessarily require, for example, a laser crystallization apparatus or can be performed at a relatively low process temperature (typically, lower than or equal to 450° C.), OS transistors are applicable to a display device with a relatively large area (typically, a diagonal size greater than or equal to 50 inches and less than or equal to 100 inches). In addition, LTPO is applicable to a display device with a size midway between the case of using LTPS transistors and the case of using OS transistors (typically, a diagonal size greater than or equal to 1 inch and less than or equal to 50 inches).

A material through which impurities such as water and hydrogen do not easily diffuse is preferably used for at least one of the insulating layers that cover the transistors. Thus, such an insulating layer can function as a barrier layer. Such a structure can effectively inhibit diffusion of impurities into the transistors from the outside and increase the reliability of the display device.

An inorganic insulating film is preferably used as each of the insulating layer 211, the insulating layer 212, the insulating layer 215, the insulating layer 218, and the insulating layer 225. As the inorganic insulating film, a silicon nitride film, a silicon oxynitride film, a silicon oxide film, a silicon nitride oxide film, an aluminum oxide film, an aluminum nitride film, or the like can be used. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above inorganic insulating films may also be used.

An organic insulating film is suitable for the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

A variety of optical members can be arranged along the inner or outer surface of the substrate 120. Examples of the optical members include a light-blocking layer, a polarizing plate, a retardation plate, a light diffusion layer (e.g., a diffusion film), an anti-reflective layer, a microlens array, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be arranged on the outer surface of the substrate 120.

Providing the protective layer 131 covering the light-emitting elements 130 inhibits entry of impurities such as water into the light-emitting elements 130, leading to an increase in the reliability of the light-emitting elements.

FIG. 27A illustrates the connection portion 140. In the connection portion 140, the common electrode 115 is electrically connected to a wiring. FIG. 27A illustrates an example in which the wiring has the same stacked-layer structure as the pixel electrode.

For each of the substrate 451 and the substrate 120, glass, quartz, ceramics, sapphire, a resin, a metal, an alloy, a semiconductor, or the like can be used. The substrate on the side from which light from the light-emitting element is extracted is formed using a material which transmits the light. When the substrate 451 and the substrate 120 are formed using a flexible material, the flexibility of the display device can be increased. Furthermore, a polarizing plate may be used as the substrate 451 or the substrate 120.

For each of the substrate 451 and the substrate 120, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used for one or both of the substrate 451 and the substrate 120.

For the adhesive layer, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. A two-component-mixture-type resin may be used. An adhesive sheet may be used, for example.

As the connection layer 242, an anisotropic conductive film (ACF), an anisotropic conductive paste (ACP), or the like can be used.

As materials that can be used for conductive layers such as a variety of wirings and electrodes that constitute a display device, in addition to a gate, a source, and a drain of a transistor, metals such as aluminum, titanium, chromium, nickel, copper, yttrium, zirconium, molybdenum, silver, tantalum, or tungsten, an alloy containing the metal as its main component, and the like can be given. A film containing any of these materials can be used in a single layer or as a stacked-layer structure.

As a light-transmitting conductive material, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Further alternatively, a nitride of the metal material (e.g., titanium nitride) may be used, for example. Note that in the case of using the metal material or the alloy material (or the nitride thereof), the material is made thin enough to have a light-transmitting property. Alternatively, stacked films of any of the above materials can be used for the conductive layers. For example, a stacked film of indium tin oxide and an alloy of silver and magnesium is preferably used, in which case the conductivity can be increased. These materials can also be used for the conductive layers such as a variety of wirings and electrodes included in a display device, and conductive layers (conductive layers functioning as a pixel electrode or a common electrode) included in the light-emitting element.

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

At least part of this embodiment can be implemented in appropriate combination with the other embodiments described in this specification.

### Embodiment 4

In this embodiment, light-emitting elements that can be used in a display device of one embodiment of the present invention will be described.

The light-emitting elements can be roughly classified into a single structure and a tandem structure. A light-emitting element having a single structure includes one light-emitting unit between a pair of electrodes, and the light-emitting unit preferably includes one or more light-emitting layers. To obtain white light emission by using two light-emitting layers, two light-emitting layers are selected such that the light-emitting layers emit light of complementary colors. For example, when the emission color of a first light-emitting layer and the emission color of a second light-emitting layer are complementary colors, the light-emitting element can be configured to emit white light as a whole. To obtain white light emission by using three or more light-emitting layers, the light-emitting element is configured to emit white light as a whole by combining emission colors of the three or more light-emitting layers.

A light-emitting element having a tandem structure includes a plurality of light-emitting units between a pair of electrodes. Each light-emitting unit includes one or more light-emitting layers. When light-emitting layers that emit light of the same color are used in each light-emitting unit, luminance per predetermined current can be increased, and the light-emitting element can have higher reliability than that with a single structure. To obtain white light emission in a tandem structure, the structure in which white light emission can be obtained by combining light from light-emitting layers of a plurality of light-emitting units is employed. Note that a combination of emission colors for obtaining white light emission is similar to that in the case of a single structure. Note that in the light-emitting element having the tandem structure, an intermediate layer such as a charge-generation layer is suitably provided between the plurality of light-emitting units.

When a white-light-emitting element and a light-emitting element having an SBS structure are compared, the light-emitting element having the SBS structure consumes lower power than the white-light-emitting element. Meanwhile, in the white light-emitting element, manufacturing cost can be reduced and manufacturing yield can be increased because the manufacturing process of the white light-emitting element is simpler than that of the light-emitting element having the SBS structure.

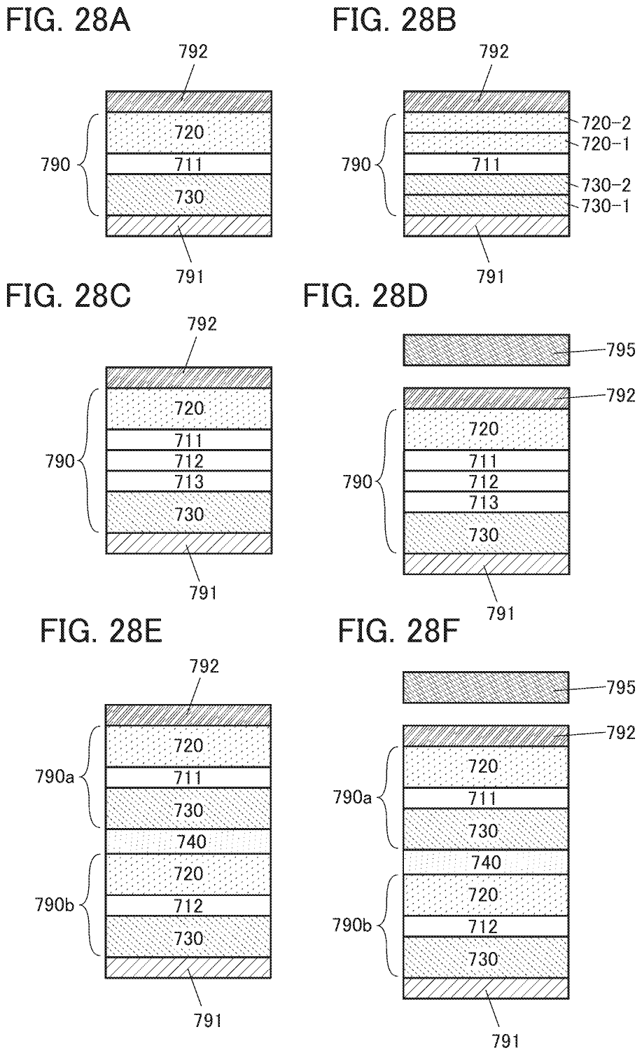

FIG. 28A to FIG. 28F are cross-sectional views each illustrating a structure example of a light-emitting element. As illustrated in FIG. 28A, the light-emitting element includes an EL layer 790 between a pair of electrodes (a lower electrode 791 and an upper electrode 792). The EL layer 790 can be formed of a plurality of layers such as a layer 720, a light-emitting layer 711, a layer 730, and the like. The layer 720 can include, for example, a layer containing a substance having a high electron-injection property (an electron-injection layer) and a layer containing a substance having a high electron-transport property (an electron-transport layer). The light-emitting layer 711 contains a light-emitting compound, for example. The layer 730 can include, for example, a layer containing a substance with a high hole-injection property (a hole-injection layer) and a layer containing a substance with a high hole-transport property (a hole-transport layer).

The structure including the layer 720, the light-emitting layer 711, and the layer 730, which is provided between a pair of electrodes, can function as a single light-emitting unit, and the structure in FIG. 28A is referred to as a single structure in this specification.

Specifically, the light-emitting element illustrated in FIG. 28B includes, over the lower electrode 791, a layer 730-1, a layer 730-2, the light-emitting layer 711, a layer 720-1, a layer 720-2, and the upper electrode 792. For example, the lower electrode 791 is an anode, and the upper electrode 792 is a cathode. In this case, the layer 730-1 functions as a hole-injection layer, the layer 730-2 functions as a hole-transport layer, the layer 720-1 functions as an electron-transport layer, and the layer 720-2 functions as an electron-injection layer. Meanwhile, when the lower electrode 791 is a cathode and the upper electrode 792 is an anode, the layer 730-1 functions as an electron-injection layer, the layer 730-2 functions as an electron-transport layer, the layer 720-1 functions as a hole-transport layer, and the layer 720-2 functions as a hole-injection layer. With such a layer structure, carriers can be efficiently injected to the light-emitting layer 711, and the efficiency of the recombination of carriers in the light-emitting layer 711 can be enhanced.

Note that structures in which a plurality of light-emitting layers (the light-emitting layer 711, the light-emitting layer 712, and the light-emitting layer 713) are provided between the layer 720 and the layer 730 as illustrated in FIG. 28C and FIG. 28D are variations of the single structure.

A structure in which a plurality of light-emitting units (an EL layer 790a and an EL layer 790b) are connected in series with an intermediate layer (a charge-generation layer) 740 therebetween as illustrated in FIG. 28E and FIG. 28F is referred to as a tandem structure in this specification. A tandem structure may be referred to as a stack structure. Note that the tandem structure enables a light-emitting element to emit light at high luminance.

In FIG. 28C, light-emitting substances that emit light of the same color, or moreover, the same substance may be used for the light-emitting layer 711, the light-emitting layer 712, and the light-emitting layer 713. The stacked light-emitting layers can increase the luminance.

Alternatively, different light-emitting substances may be used for the light-emitting layer 711, the light-emitting layer 712, and the light-emitting layer 713. White light can be obtained when the light-emitting layer 711, the light-emitting layer 712, and the light-emitting layer 713 emit light of complementary colors. FIG. 28D illustrates an example in which a coloring layer 795 functioning as a color filter is provided. When white light passes through a color filter, light of a desired color can be obtained.

In FIG. 28E, light-emitting substances that emit light of the same color may be used for the light-emitting layer 711 and the light-emitting layer 712. Alternatively, light-emitting substances that emit light of different colors may be used for the light-emitting layer 711 and the light-emitting layer 712. White light can be obtained when the light-emitting layer 711 and the light-emitting layer 712 emit light of complementary colors. FIG. 28F illustrates an example in which the coloring layer 795 is further provided.

In FIG. 28C, FIG. 28D, FIG. 28E, and FIG. 28F, the layer 720 and the layer 730 may each have a layered structure of two or more layers as illustrated in FIG. 28B.

In FIG. 28D, light-emitting substance that emits light of the same color may be used for the light-emitting layer 711, the light-emitting layer 712, and the light-emitting layer 713. Similarly, in FIG. 28F, the same light-emitting substance that emits light of the same color may be used for the light-emitting layer 711 and the light-emitting layer 712. Here, when a color conversion layer is used instead of the coloring layer 795, light of a desired color different from the emission color of the light-emitting substance can be obtained. For example, a blue-light-emitting substance is used for each light-emitting layer and blue light passes through the color conversion layer, whereby light with a wavelength longer than that of blue light (e.g., red light or green light) can be obtained. For the color conversion layer, a fluorescent material, a phosphorescent material, quantum dots, or the like can be used.

The emission color of the light-emitting element can be red, green, blue, cyan, magenta, yellow, white, or the like depending on the material contained in the EL layer 790. Furthermore, the color purity can be further increased when the light-emitting element has a microcavity structure.

In the light-emitting element that emits white light, a light-emitting layer may contain two or more kinds of light-emitting substances, or two or more light-emitting layers containing different light-emitting substances may be stacked. In such a case, the light-emitting substances are selected such that the light-emitting substances emit light of complementary colors.

At least part of this embodiment can be implemented in appropriate combination with the other embodiments described in this specification.

### Embodiment 5

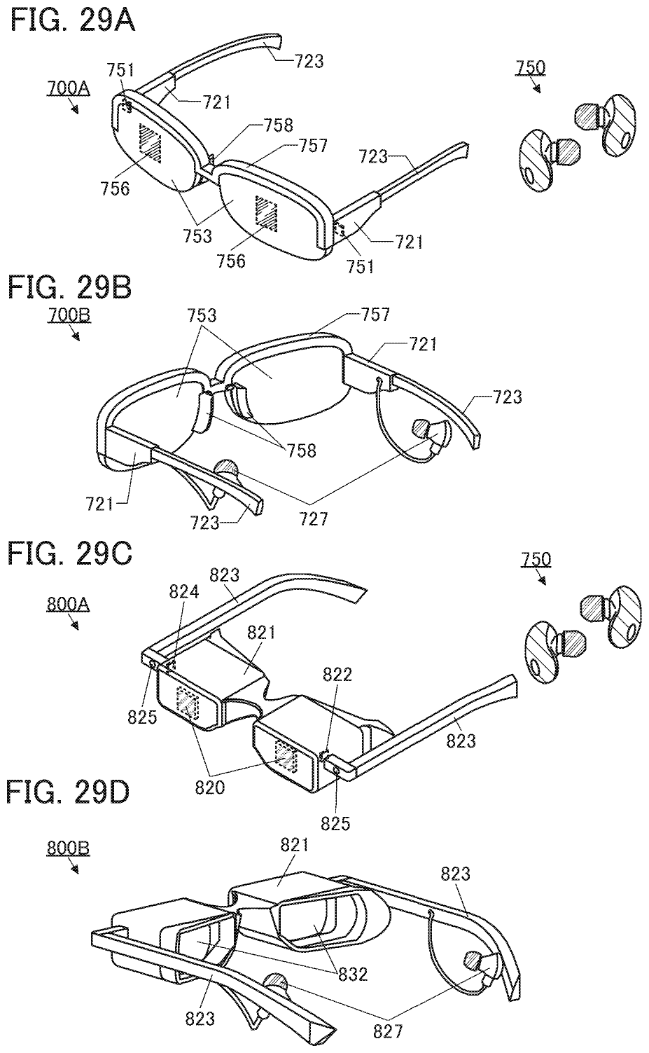

In this embodiment, electronic devices of one embodiment of the present invention will be described with reference to FIG. 29 to FIG. 31.

Electronic devices of this embodiment are each provided with the display device of one embodiment of the present invention in a display portion. The display device of one embodiment of the present invention is highly reliable. The display device of one embodiment of the present invention can be easily increased in resolution and definition and can achieve high display quality. Thus, the display device of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer, digital signage, and a large game machine such as a pachinko machine.

In particular, the display device of one embodiment of the present invention can have high resolution, and thus can be suitably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. With the use of the display device having one or both of such high definition and high resolution, the electronic device can provide higher realistic sensation, sense of depth, and the like in personal use such as portable use and home use. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device of this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device of this embodiment can have a variety of functions. For example, the electronic device of this embodiment can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices will be described with reference to FIG. 29A to FIG. 29D. These wearable devices have one or both of a function of displaying AR contents and a function of displaying VR contents. Note that these wearable devices may have a function of displaying SR or MR contents, in addition to AR and VR contents. The electronic device having a function of displaying contents of at least one of AR, VR, SR, MR, and the like enables the user to feel a higher sense of immersion.

An electronic device 700A illustrated in FIG. 29A and an electronic device 700B illustrated in FIG. 29B each include a pair of display devices 751, a pair of housings 721, a communication portion (not illustrated), a pair of mounting portions 723, a control portion (not illustrated), an image capturing portion (not illustrated), a pair of optical members 753, a frame 757, and a pair of nose pads 758.

The display device of one embodiment of the present invention can be used for the display device 751. Thus, the electronic device can have high reliability and perform ultrahigh-resolution display.

The electronic device 700A and the electronic device 700B can each project images displayed on the display devices 751 onto display regions 756 of the optical members 753. Since the optical members 753 have a light-transmitting property, the user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be detected and an image corresponding to the orientation can be displayed on the display regions 756.

The communication portion includes a wireless communication device, and for example, a video signal can be supplied by the wireless communication device. Instead of or in addition to the wireless communication device, a connector that can be connected to a cable for supplying a video signal and a power supply potential may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, processing such as pausing or restarting a video can be executed by a tap operation, and processing such as fast-forwarding or fast-rewinding can be executed by a slide operation. When the touch sensor module is provided in each of the two housings 721, the range of the operation can be increased.

Various touch sensors can be used for the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element (also referred to as a photoelectric conversion device) can be used as a light-receiving element (also referred to as a light-receiving device). One or both of an inorganic semiconductor and an organic semiconductor can be used for an active layer of the photoelectric conversion element.

An electronic device 800A illustrated in FIG. 29C and an electronic device 800B illustrated in FIG. 29D each include a pair of display portions 820, a housing 821, a communication portion 822, a pair of mounting portions 823, a control portion 824, a pair of image capturing portions 825, and a pair of lenses 832.

The display device of one embodiment of the present invention can be used for the display portion 820. Thus, the electronic device can have high reliability and perform ultrahigh-resolution display. The ultrahigh-resolution display can provide a high sense of immersion to the user.

The display portions 820 are positioned inside the housing 821 so as to be seen through the lenses 832. When the pair of display portions 820 display different images, three-dimensional display using parallax can also be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the mounting portions 823. FIG. 29C and the like illustrate examples where the mounting portion 823 has a shape like a temple of glasses; however, one embodiment of the present invention is not limited thereto. The mounting portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portion 825 is provided is described here, a range sensor capable of measuring a distance between the user and an object (hereinafter also referred to as a detecting portion) just needs to be provided. In other words, the image capturing portion 825 is one embodiment of the detecting portion. As the detecting portion, an image sensor or a range image sensor such as LIDAR (Light Detection and Ranging) can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, at least one of the display portion 820, the housing 821, and the mounting portion 823 can include the vibration mechanism. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying, for example, a video signal from a video output device, power for charging a battery provided in the electronic device, and the like can be connected.

The electronic device of one embodiment of the present invention may have a function of performing wireless communication with earphones 750. The earphones 750 include a communication portion (not illustrated) and has a wireless communication function. The earphones 750 can receive information (e.g., audio data) from the electronic device with the wireless communication function. For example, the electronic device 700A in FIG. 29A has a function of transmitting information to the earphones 750 with the wireless communication function. As another example, the electronic device 800A in FIG. 29C has a function of transmitting information to the earphones 750 with the wireless communication function.

The electronic device may include an earphone portion. The electronic device 700B in FIG. 29B includes earphone portions 727. For example, the earphone portion 727 can be connected to the control portion by wire. Part of a wiring that connects the earphone portion 727 and the control portion may be positioned inside the housing 721 or the mounting portion 723.

Similarly, the electronic device 800B in FIG. 29D includes earphone portions 827. For example, the earphone portion 827 can be connected to the control portion 824 by wire. Part of a wiring that connects the earphone portion 827 and the control portion 824 may be positioned inside the housing 821 or the mounting portion 823. Alternatively, the earphone portions 827 and the mounting portions 823 may include magnets. This is preferred because the earphone portions 827 can be fixed to the mounting portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

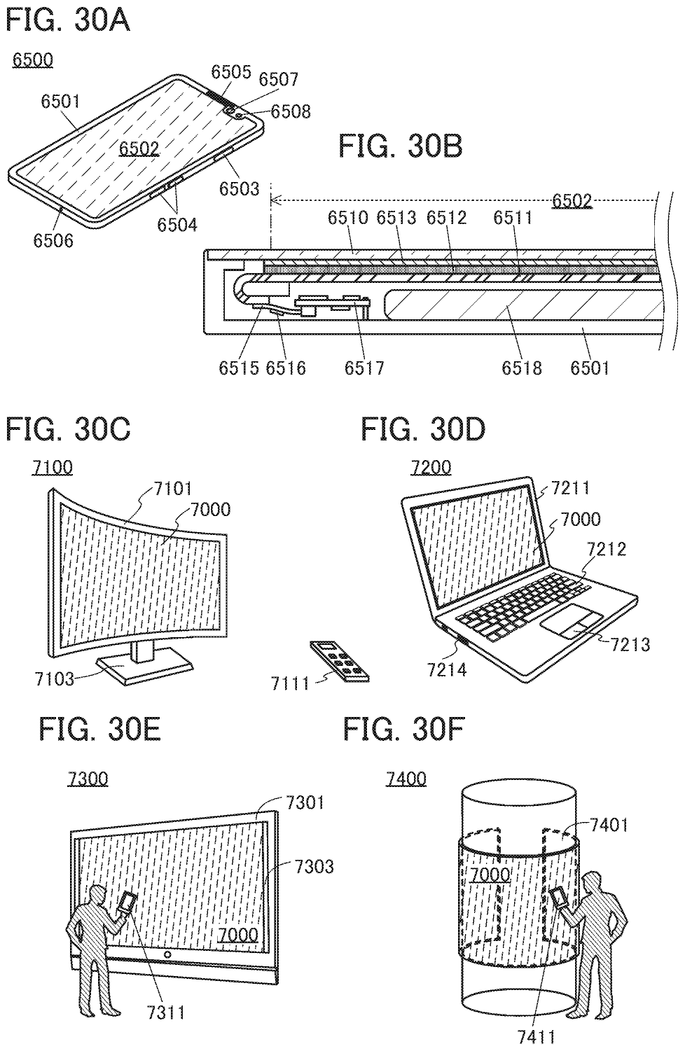

An electronic device 6500 illustrated in FIG. 30A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used for the display portion 6502.

FIG. 30B is a schematic cross-sectional view including an end portion of the housing 6501 on the microphone 6506 side.

A protection member 6510 having a light-transmitting property is provided on the display surface side of the housing 6501. A display device 6511, an optical member 6512, a touch sensor panel 6513, a printed circuit board 6517, a battery 6518, and the like are provided in a space surrounded by the housing 6501 and the protection member 6510.

The display device 6511, the optical member 6512, and the touch sensor panel 6513 are fixed to the protection member 6510 with an adhesive layer (not illustrated).

Part of the display device 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display device 6511. Thus, an extremely lightweight electronic device can be achieved. Since the display device 6511 is extremely thin, the battery 6518 with high capacity can be mounted while an increase in the thickness of the electronic device is suppressed. Moreover, part of the display device 6511 is folded back so that a connection portion with the FPC 6515 is placed on the back side of the pixel portion, whereby an electronic device with a narrow bezel can be achieved.

FIG. 30C illustrates an example of a television device. In a television device 7100, a display portion 7000 is incorporated in a housing 7101. Here, the housing 7101 is supported by a stand 7103.

Operation of the television device 7100 illustrated in FIG. 30C can be performed with an operation switch provided in the housing 7101 and a separate remote controller 7111. Alternatively, the display portion 7000 may be provided with a touch sensor, and the television device 7100 may be operated by touch on the display portion 7000 with, for example, a finger. The remote controller 7111 may include a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 30D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

FIG. 30E and FIG. 30F illustrate examples of digital signage.

Digital signage 7300 illustrated in FIG. 30E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 30F is digital signage 7400 attached to a cylindrical pillar 7401. The digital signage 7400 includes the display portion 7000 provided along a curved surface of the pillar 7401.

A larger area of the display portion 7000 can increase the amount of data that can be provided at a time. The larger display portion 7000 attracts more attention, so that the effectiveness of the advertisement can be increased, for example.

The use of a touch panel in the display portion 7000 is preferable because in addition to display of an image or a moving image on the display portion 7000, intuitive operation by a user is possible. Moreover, for an application for providing information such as route information or traffic information, usability can be enhanced by intuitive operation.

As illustrated in FIG. 30E and FIG. 30F, it is preferable that the digital signage 7300 or the digital signage 7400 can work with an information terminal 7311 or an information terminal 7411 a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched. Here, each of the information terminal 7311 and the information terminal 7411 can be a smartphone, for example.

Furthermore, it is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

The display device of one embodiment of the present invention can be used for the display portion 7000 in FIG. 30C to FIG. 30F.

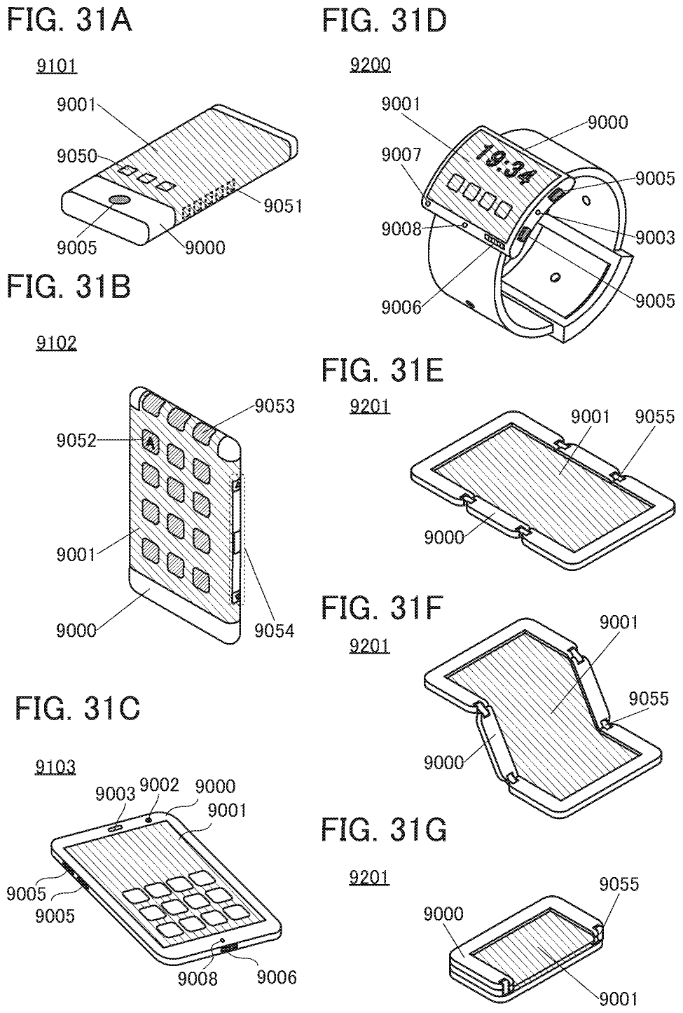

Electronic devices illustrated in FIG. 31A to FIG. 31G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, an odor, or infrared rays), a microphone 9008, and the like.

The electronic devices illustrated in FIG. 31A to FIG. 31G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with, for example, a camera and have a function of capturing a still image or a moving image, a function of storing the captured image in a storage medium (an external storage medium or a storage medium incorporated in the camera), a function of displaying the captured image on the display portion, and the like.

The electronic devices illustrated in FIG. 31A to FIG. 31G will be described in detail below.

FIG. 31A is a perspective view illustrating a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 31A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail or an SNS message, the date, the time, remaining battery, and the radio field intensity. Alternatively, for example, the icon 9050 may be displayed at the position where the information 9051 is displayed.

FIG. 31B is a perspective view illustrating a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. Thus, the user can see the display without taking out the portable information terminal 9102 from the pocket and decide whether to answer the call, for example.

FIG. 31C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 31D is a perspective view illustrating a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 31E to FIG. 31G are perspective views illustrating a foldable portable information terminal 9201. FIG. 31E is a perspective view of an opened state of the portable information terminal 9201, FIG. 31G is a perspective view of a folded state thereof, and FIG. 31F is a perspective view of a state in the middle of change from one of FIG. 31E and FIG. 31G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

When the display device of one embodiment of the present invention is used in the above electronic device, a highly reliable electronic device can be provided.

At least part of this embodiment can be implemented in appropriate combination with the other embodiments described in this specification.

### REFERENCE NUMERALS

100: display device, 101: layer, 103: pixel, 110a: subpixel, 110b: subpixel, 110c: subpixel, 110: subpixel, 111a: pixel electrode, 111b: pixel electrode, 111c: pixel electrode, 111: pixel electrode, 113a: EL layer, 113A: EL film, 113b: EL layer, 113B: EL film, 113c: EL layer, 113C: EL film, 113d: EL layer, 113: EL layer, 114: common layer, 115: common electrode, 116: protruding portion, 117: insulating layer, 118a: mask layer, 118A: mask film, 118b: mask layer, 118B: mask film, 118c: mask layer, 118C: mask film, 118: mask layer, 119a: mask layer, 119A: mask film, 119b: mask layer, 119B: mask film, 119c: mask layer, 119C: mask film, 119: mask layer, 120: substrate, 122: adhesive layer, 123: conductive layer, 124a: pixel, 124b: pixel, 125A: insulating film, 125: insulating layer, 127A: insulating film, 127B: insulating layer, 127C: insulating layer, 127: insulating layer, 130a: light-emitting element, 130b: light-emitting element, 130c: light-emitting element, 130d: light-emitting element, 130: light-emitting element, 131: protective layer, 133: depression portion, 135A: light-blocking film, 135: light-blocking layer, 137a: tapered portion, 137b: tapered portion, 137c: tapered portion, 137: tapered portion, 139a: region, 139b: region, 140: connection portion, 150: pixel, 160a: light-emitting unit, 160b: light-emitting unit, 160c: light-emitting unit, 160: light-emitting unit, 161: protective layer, 163a: coloring layer, 163b: coloring layer, 163c: coloring layer, 163: coloring layer, 190a: resist mask, 190b: resist mask, 190c: resist mask, 200A: display device, 200B: display device, 200C: display device, 200D: display device, 200E: display device, 200F: display device, 202: transistor, 204: connection portion, 209: transistor, 210: transistor, 211: insulating layer, 212: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 255c: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320A: transistor, 320B: transistor, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 400: display device, 411a: conductive layer, 411b: conductive layer, 451: substrate, 455: adhesive layer, 462: display portion, 464: circuit, 465: wiring, 466: conductive layer, 472: FPC, 473: IC, 700A: electronic device, 700B: electronic device, 711: light-emitting layer, 712: light-emitting layer, 713: light-emitting layer, 720: layer, 721: housing, 723: mounting portion, 727: earphone portion, 730: layer, 750: earphone, 751: display device, 753: optical member, 756: display region, 757: frame, 758: nose pad, 790a: EL layer, 790b: EL layer, 790: EL layer, 791: lower portion electrode, 792: upper portion electrode, 795: coloring layer, 800A: electronic device, 800B: electronic device, 820: display portion, 821: housing, 822: communication portion, 823: mounting portion, 824: control circuit, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display device, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display device, comprising:
a first light-emitting element, a second light-emitting element adjacent to the first light-emitting element, a first insulating layer provided between the first light-emitting element and the second light-emitting element, a light-blocking layer over the first insulating layer, and a second insulating layer over the light-blocking layer,
wherein the first light-emitting element comprises a first pixel electrode, a first EL layer over the first pixel electrode, and a common electrode over the first EL layer,
wherein the second light-emitting element comprises a second pixel electrode, a second EL layer over the second pixel electrode, the common electrode over the second EL layer, and
wherein the common electrode is placed over the second insulating layer.

2. The display device according to claim 1,
wherein the first insulating layer comprises an inorganic material, and
wherein the second insulating layer comprises an organic material.

3. The display device according to claim 2,
wherein the first insulating layer comprises aluminum oxide.

4. The display device according to claim 3,
wherein the second insulating layer comprises an acrylic resin.

5. The display device according to claim 1,
wherein a side surface of the first pixel electrode and a side surface of the second pixel electrode each have a tapered shape in a cross-sectional view of the display device,
wherein the first EL layer covers the side surface of the first pixel electrode, wherein the second EL layer covers the side surface of the second pixel electrode,
wherein the first EL layer comprises a first tapered portion between the side surface of the first pixel electrode and the first insulating layer, and
wherein the second EL layer comprises a second tapered portion between the side surface of the second pixel electrode and the first insulating layer.

6. The display device according to claim 5,
wherein a taper angle of the first tapered portion and a taper angle of the second tapered portion are each less than 90°.

7. The display device according to claim 1,
wherein the first insulating layer comprises a region in contact with the first EL layer and the second EL layer.

8. The display device according to claim 1,
wherein the first light-emitting element comprises a common layer placed between the first EL layer and the common electrode,
wherein the second light-emitting element comprises the common layer placed between the second EL layer and the common electrode,
wherein the common layer is placed between the second insulating layer and the common electrode, and
wherein the common layer comprises at least one of a hole-injection layer, a hole-transport layer, a hole-blocking layer, an electron-blocking layer, an electron-transport layer, and an electron-injection layer.

9. A display module comprising:
the display device according to claim 1; and
at least one of a connector and an integrated circuit.

10. An electronic device comprising:
the display module according to claim 9; and
at least one of a battery, a camera, a speaker, and a microphone.

11. A method for manufacturing a display device, comprising the steps of:
forming a first pixel electrode and a second pixel electrode;
forming a first EL film to cover the first pixel electrode and the second pixel electrode;
forming a first mask film over the first EL film;
forming a first EL layer over the first pixel electrode and a first mask layer over the first EL layer by processing the first EL film and the first mask film;
forming a second EL film to cover the first mask layer and the second pixel electrode,
forming a second mask film over the second EL film;
forming a second EL layer over the second pixel electrode and a second mask layer over the second EL layer by processing the second EL film and the second mask film;
forming an inorganic insulating film to cover the first EL layer, the second EL layer, the first mask layer, and the second mask layer;
forming a light-blocking film over the inorganic insulating film, applying a photosensitive organic insulating film over the light-blocking film;
irradiating part of the organic insulating film with light;
forming an organic insulating layer between the first EL layer and the second EL layer by removing the part of the organic insulating film;
forming a light-blocking layer under the organic insulating layer by removing part of the light-blocking film;
forming an inorganic insulating layer under the light-blocking layer by removing part of the inorganic insulating film; and
forming a common electrode over the first EL layer, the second EL layer, and the organic insulating layer.

12. The method for manufacturing a display device according to claim 11,
wherein the light comprises ultraviolet light.

13. The method for manufacturing a display device according to claim 11,
wherein each of the first pixel electrode and the second pixel electrode is formed to comprise a side surface with a tapered shape in a cross-sectional view of the display device,
wherein the first EL layer is formed to cover a side surface of the first pixel electrode and comprise a first tapered portion between the side surface of the first pixel electrode and the first mask layer, and
wherein the second EL layer is formed to cover a side surface of the second pixel electrode and comprise a second tapered portion between the side surface of the second pixel electrode and the second mask layer.

14. The method for manufacturing a display device according to claim 13,
wherein the first EL layer is formed to have a taper angle of the first tapered portion of less than 90°, and
wherein the second EL layer is formed to have a taper angle of the second tapered portion of less than 90°.

15. The method for manufacturing a display device according to claim 11,
wherein the first EL layer and the second EL layer are formed by a photolithography method.

16. The method for manufacturing a display device according to claim 11,
wherein a distance of a region between the first EL layer and the second EL layer is less than or equal to 8 μm.

17. The method for manufacturing a display device according to claim 11,
wherein the inorganic insulating film is formed by an ALD method.

18. The method for manufacturing a display device according to claim 11,
wherein the organic insulating film is formed using a photosensitive acrylic resin.

19. The method for manufacturing a display device according to claim 11,
wherein the inorganic insulating layer is formed to comprise a region in contact with the first EL layer and the second EL layer.

20. The method for manufacturing a display device according to claim 11, further comprising the steps of:
forming a common layer comprising at least one of a hole-injection layer, a hole-transport layer, a hole-blocking layer, an electron-blocking layer, an electron-transport layer, and an electron-injection layer after forming the inorganic insulating layer and before forming the common electrode; and
forming the common electrode over the common layer.
